(19) United States
(12) Patent Application Publication
(10) Pub. No.: US 2016/0218012 A1
(43) Pub. Date: Jul. 28, 2016

(54) METHOD OF FORMING FINE PATTERN, METHOD OF MANUFACTURING SEMICONDUCTOR DEVICE, SUBSTRATE PROCESSING APPARATUS AND RECORDING MEDIUM

(71) Applicant: HITACHI KOKUSAI ELECTRIC INC., Tokyo (JP)

(72) Inventors: Satoshi SHIMAMOTO, Toyama-shi (JP); Toshiyuki KIKUCHI, Toyama-shi (JP); Jiro YUGAMI, Toyama-shi (JP); Yoshiro HIROSE, Toyama-shi (JP); Yuichi WADA, Toyama-shi (JP); Kenji KANAYAMA, Toyama-shi (JP); Hiroshi ASHIHARA, Toyama-shi (JP); Kenji KAMEDA, Toyama-shi (JP)

(73) Assignee: HITACHI KOKUSAI ELECTRIC INC., Tokyo (JP)

(21) Appl. No.: 15/026,414

(22) PCT Filed: Sep. 29, 2014
(86) PCT No.: PCT/JP2014/075869

§ 371 Date: Mar. 31, 2016

(30) Foreign Application Priority Data
Oct. 22, 2013 (JP) 2013-219584
Nov. 29, 2013 (JP) 2013-248054
Apr. 30, 2014 (JP) 2014-093751

(51) Int. Cl. H01L 21/3065; H01J 37/32

(52) U.S. Cl. CPC H01L 21/3065; H01J 37/32009; H01J 37/3244; H01J 2237/334

(57) ABSTRACT

A fine pattern-forming method includes: a core pattern-forming step of forming a core pattern of a predetermined line width at a substrate surface side; a sidewall-forming step of forming a sidewall on the core pattern formed in the core pattern-forming step; and a core pattern removing step of removing the core pattern in a state where the sidewall is left, by using an etching gas after the sidewall-forming step, and is configured such that, in the core pattern removing step, a film deposited at a substrate back side in the core pattern-forming step is removed in parallel to the removal of the core pattern.

### TECHNICAL FIELD

The present disclosure relates to a technique of forming fine patterns by using an etching process, a semiconductor device manufacturing method by using this technique, a substrate processing apparatus and a recording medium.

### BACKGROUND ART

Patterns are miniaturized for semiconductor devices to realize a higher degree of integration. To realize fine patterns, various methods which use an etching process (see, for example, Patent Literature 1) have been studied. By effectively using these methods, it is possible to form a pattern having extra fine grooves and columns.

In recent years, an element dimension of a transistor is reduced along with scaling of the transistor. Therefore, a flat transistor structure which has been conventionally used cannot be expected to improve performance of the transistor due to a miniaturization limitation. As a method of overcoming this limitation, for example, a transistor of a 3D structure which is referred to as Fin-FETs has been put to practical use. A pattern of a Si-Fin of this Fin-FET requires a fine pitch less than a resolution limitation dimension of a leading edge ArF immersion lithography technique after a 22 nm generation. Further, a pattern pitch of a gate electrode is also required to meet a fine pitch less than the same resolution limitation dimension after a 14 nm generation.

As such a fine pattern-forming technique, a self-align double patterning technique (referred to as the “SADP method” below) of forming sidewalls at sidewalls of a core pattern formed by lithography and dry etching, performing processing by using these sidewalls as masks and thereby forming a dimension less than a resolution limitation is used.

As a general SADP method, a following process is used. For example, a SiO₂ film (silicon oxide film), a Si₃N₄ film (silicon nitride film), an amorphous Si film, a carbon hardmask (CHM) and a Si antireflection film are stacked on a Si (silicon) substrate in this order to form a multilayer film. Further, a photoresist is applied to this multilayer film, and then is exposed by a lithography technique to form a resist pattern of a line width equal to or more than a resolution limitation. Subsequently, the Si antireflection film and the CHM film are processed by dry etching to the same line width as that of the resist pattern.

Next, the amorphous Si film which is an underlayer film is patterned by using the patterned CHM film as a mask to forma core pattern having the same line width as that of the resist on the amorphous Si film. Next, the SiO₂ film is formed on this core pattern, and a sidewall of a line width less than a resolution limitation dimension is formed by using SiO₂. Further, after the sidewall is formed, the Si core pattern is removed by etching.

Processing of removing the Si core pattern needs a high etching selectivity so as not to etch the SiO₂ film which is a sidewall material or an underlayer film such as the Si₃N₄ film. So far, a Si core pattern has been generally removed by dry etching by using reactive ions. However, it is difficult to secure a selectivity for both of the SiO₂ film and the Si₃N₄ film in a process of etching the Si core pattern.

Further, a minimum processing dimension of semiconductor devices such as a recent LSI, DRAM (Dynamic Random Access Memory) and flash memory is smaller than a width of 30 nm. Wet etching which is one process of such a semiconductor device manufacturing process causes, for example, a pattern collapse due to a surface tension of a liquid used upon the wet etching. Therefore, it is becoming difficult to realize miniaturization and improvement in a manufacturing throughput while keeping quality of semiconductor devices.

Thus, a conventional dry etching technique (an etching technique which uses reactive ions) and wet etching technique cannot support miniaturization of such next-generation semiconductor devices.

### CITATION LIST

### Patent Literature

Patent Literature 1: JP 2011-44493 A

### SUMMARY OF INVENTION

An object of the present disclosure is to provide a technique of forming fine patterns by using an etching technique which is suitable to a next-generation semiconductor device, a semiconductor device manufacturing method which uses this technique, and a substrate processing apparatus

According to one embodiment of the present disclosure, there is provided a fine pattern-forming method including:

a core pattern-forming step of forming a core pattern of a predetermined line width at a substrate surface side;

a sidewall-forming step of forming a sidewall on the core pattern formed in the core pattern-forming step; and

a core pattern removing step of removing the core pattern in a state where the sidewall is left, by using an etching gas after the sidewall-forming step, and,

in the core pattern removing step, a film deposited at a substrate back side in the core pattern-forming step is removed in parallel to the removal of the core pattern.

According to a configuration of the present disclosure, it is possible to provide an etching technique which is suitable to a next generation semiconductor device.

### BRIEF DESCRIPTION OF DRAWINGS

FIG. 1 illustrates a schematic horizontal cross-sectional view of a substrate processing apparatus according to an embodiment of the present disclosure.

FIG. 2 illustrates a schematic vertical cross-sectional view of the substrate processing apparatus according to the embodiment of the present disclosure.

FIG. 3 illustrates a vertical cross-sectional view of a first processing unit of the substrate processing apparatus according to the embodiment of the present disclosure.

FIG. 4 illustrates a vertical cross-sectional view of a susceptor of the first processing unit.

FIG. 5 illustrates a vertical cross-sectional view of a second processing unit of the substrate processing apparatus according to the embodiment of the present disclosure.

FIG. 6 illustrates a structure diagram of a controller according to the embodiment of the present disclosure.

FIG. 7 illustrates a view of a processing flow of a substrate processing method according to the embodiment of the present disclosure.

FIG. 8 illustrates a view illustrating a substrate surface side at a first stage of fine pattern-forming processing according to the embodiment of the present disclosure.

FIG. 9 illustrates a view illustrating a substrate back side at the first stage.

FIG. 10 illustrates a view illustrating a second stage of the fine pattern-forming processing according to the embodiment of the present disclosure.

FIG. 11 illustrates a view illustrating a third stage of the fine pattern-forming processing according to the embodiment of the present disclosure.

FIG. 12 illustrates a view illustrating a fourth stage of the fine pattern-forming processing according to the embodiment of the present disclosure.

FIG. 13 illustrates a view illustrating a fifth stage of the fine pattern-forming processing according to the embodiment of the present disclosure.

FIG. 14 illustrates a view illustrating a sixth stage of the fine pattern-forming processing according to the embodiment of the present disclosure.

FIG. 15 illustrates a view illustrating a substrate back side at the sixth stage.

FIG. 16 illustrates a view illustrating a seventh stage of the fine pattern-forming processing according to the embodiment of the present disclosure.

FIG. 17 illustrates a view illustrating an eighth stage of the fine pattern-forming processing according to the embodiment of the present disclosure.

FIG. 18 illustrates a view illustrating a ninth stage of the fine pattern-forming processing according to the embodiment of the present disclosure.

FIG. 19 illustrates a view illustrating a tenth stage of the fine pattern-forming processing according to the embodiment of the present disclosure.

FIG. 20 illustrates a view illustrating a processing flow of the substrate processing apparatus according to the embodiment of the present disclosure.

FIG. 21 illustrates a view illustrating a processing flow of the substrate processing apparatus according to the embodiment of the present disclosure.

FIG. 22 illustrates a view illustrating a processing flow of the substrate processing apparatus according to the embodiment of the present disclosure.

FIG. 23 illustrates a view for explaining the fine pattern-forming processing according to the embodiment of the present disclosure.

FIG. 24 illustrates a view for explaining the fine pattern-forming processing according to the embodiment of the present disclosure.

FIG. 25 illustrates a view for explaining the fine pattern-forming processing according to the embodiment of the present disclosure.

FIG. 26 illustrates a view for explaining the fine pattern-forming processing according to the embodiment of the present disclosure.

FIG. 27 illustrates a view for explaining the fine pattern-forming processing according to the embodiment of the present disclosure.

FIG. 28 illustrates a view illustrating a state before a silicon film or the like at the substrate back side is removed according to the embodiment of the present disclosure.

FIG. 29 illustrates a view illustrating a state after a silicon film or the like at the substrate back side is removed according to the embodiment of the present disclosure.

FIG. 30A illustrates a cross-sectional view of a transistor in a channel length direction before etching processing according to the embodiment of the present disclosure.

FIG. 30B illustrates a cross-sectional view of a Fin-FET transistor in a channel width direction before the etching processing according to the embodiment of the present disclosure.

FIG. 30C illustrates a three-dimensional schematic view of the Fin-FET transistor before the etching processing according to the embodiment of the present disclosure.

FIG. 31A illustrates a cross-sectional view of the Fin-FET transistor in the channel length direction after the etching processing according to the embodiment of the present disclosure.

FIG. 31B illustrates a cross-sectional view of the Fin-FET transistor in the channel width direction after the etching processing according to the embodiment of the present disclosure.

FIG. 31C illustrates a three-dimensional schematic view of the Fin-FET transistor after the etching processing according to the embodiment of the present disclosure.

FIG. 32A illustrates a view illustrating a state before a polysilicon film at the substrate back side is removed according to the embodiment of the present disclosure.

FIG. 32B illustrates a view illustrating a state after a polysilicon film at the substrate back side is removed according to the embodiment of the present disclosure.

FIG. 33A illustrates a cross-sectional view of the Fin-FET transistor in the channel width direction before the etching processing according to the embodiment of the present disclosure.

FIG. 33B illustrates a three-dimensional schematic view of the Fin-FET transistor before the etching processing according to the embodiment of the present disclosure.

FIG. 34A illustrates a cross-sectional view of the Fin-FET transistor in the channel width direction after the etching processing according to the embodiment of the present disclosure.

FIG. 34B illustrates a three-dimensional schematic view of the Fin-FET transistor after the etching processing according to the embodiment of the present disclosure.

FIG. 35A illustrates a view illustrating a state before a phosphorated polysilicon film at the substrate back side is removed according to the embodiment of the present disclosure.

FIG. 35B illustrates a view illustrating a state after a phosphorated polysilicon film at the substrate back side is removed according to the embodiment of the present disclosure.

FIG. 36 illustrates a configuration of a substrate processing apparatus according to another embodiment of the present disclosure.

FIG. 37 illustrates a configuration example of a substrate before processing according to the another embodiment of the present disclosure.

FIG. 38 illustrates a structure example of a controller according to the another embodiment of the present disclosure.

FIG. 39 illustrates a flow example of substrate processing process according to the another embodiment of the present disclosure.

FIG. 40A illustrates a schematic vertical cross-sectional view for explaining a resist pattern-forming method.

FIG. 40B illustrates a schematic vertical cross-sectional view for explaining the resist pattern-forming method.

FIG. 40C illustrates a schematic vertical cross-sectional view for explaining the resist pattern-forming method.

FIG. 40D illustrates a schematic vertical cross-sectional view for explaining the resist pattern-forming method.

FIG. 40E illustrates a schematic vertical cross-sectional view for explaining the resist pattern-forming method.

FIG. 40F illustrates a schematic vertical cross-sectional view for explaining the resist pattern-forming method.

FIG. 40G illustrates a schematic vertical cross-sectional view for explaining the resist pattern-forming method.

FIG. 40H illustrates a schematic vertical cross-sectional view for explaining the resist pattern-forming method.

FIG. 40I illustrates a schematic vertical cross-sectional view for explaining the resist pattern-forming method.

FIG. 40J illustrates a schematic vertical cross-sectional view for explaining the resist pattern-forming method.

FIG. 40K illustrates a schematic vertical cross-sectional view for explaining the resist pattern-forming method.

FIG. 40L illustrates a schematic vertical cross-sectional view for explaining the resist pattern-forming method.

FIG. 40M illustrates a schematic vertical cross-sectional view for explaining the resist pattern-forming method.

FIG. 41A illustrates an example of substrate processing according to the embodiment of the present disclosure.

FIG. 41B illustrates another example of substrate processing according to the embodiment of the present disclosure.

FIG. 42 illustrates vapor pressure characteristics of an etching gas according to the embodiment of the present disclosure.

### DETAILED DESCRIPTION

To solve the above problem, the inventors found that it is possible to selectively remove a Si film whose main component is silicon (Si) element with respect to at least oxide silicon (SiO₂), nitride silicon (Si₃N₄), titanium nitride (TiN), amorphous carbon (a-C) and the like in a fixed temperature area by performing dry etching by using an etching gas described below. Further, the inventors found that it is possible to isotopically remove a Si film whose main component is a Si element while maintaining a high selectivity by using the etching gas described below without plasma-activating the etching gas.

In this regard, the Si film whose main component is the Si element (the main component is silicon) is, for example, a film whose Si element is 90% or more. In addition, the “high selectivity” means that an etching rate of a first film (e.g. silicon film) whose main component is, for example, silicon is made higher than that of a second film serving as a film (a silicon oxide film, a silicon oxynitride film or a silicon nitride film) whose silicon content rate is lower than that of the first film. More precisely, the “high selectivity” means to etch the first film without etching the second film.

FIG. 42 illustrates a view related to vapor pressure characteristics of an IF₇ (or IF₅) gas which is one etching gas used in the present embodiment.

FIG. 42 illustrates a condition that an iodine heptafluoride (IF₇) (or iodine pentafluoride (IF₅)) gas obviously becomes a gas under etching processing conditions C according to the present embodiment described below. Under conditions that a pressure is depressurized and a temperature is at 30° C. to 50° C. (or 40° C. to 50° C.), the IF₇ (or IF₅) can maintain a high selectivity with respect to the Si film as described above, and isotopically etch the Si film.

In this regard, the IF₇ gas produces the IF₅ gas as a by-product from a known manufacturing process. However, under conditions such as the etching processing conditions C described below that a pressure is depressurized and the temperature is 30° C. to 50° C. (or 40° C. to 50° C.), etching is performed by using the IF₇ gas, and the IF₅ gas is also a gas as the above-mentioned by-product and, consequently, can easily be purged without adhering onto a substrate.

In addition, it is preferable to heat a substrate temperature to 100° C. or more as illustrated in FIG. 42 to securely remove the IF₅ gas. Accordingly, in consideration of removal of a by-product, it is preferable to raise a temperature in a purging process of removing an etching gas from a processing chamber.

### First Embodiment

### (1) Configuration of Substrate Processing Apparatus

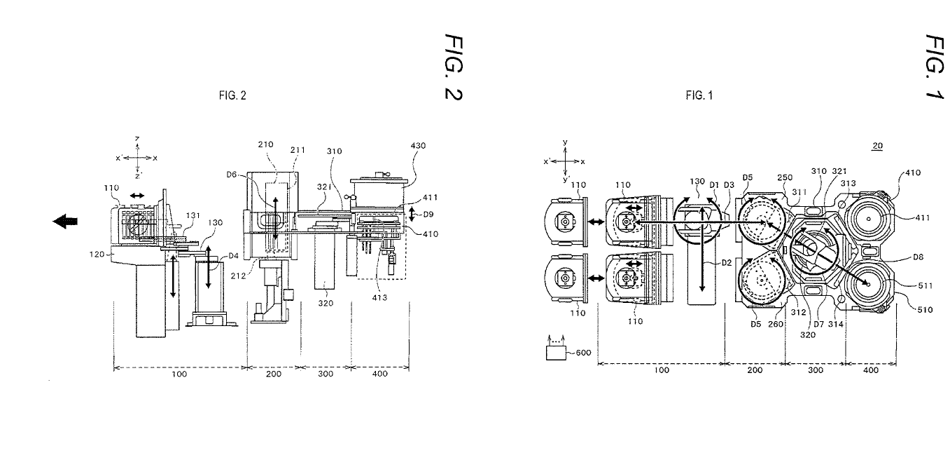

The substrate processing apparatus according to the embodiment of the present disclosure will be described with reference to the drawings below. In the present embodiment, for example, the substrate processing apparatus is configured as a semiconductor manufacturing apparatus configured to perform a processing process of a semiconductor device (IC: Integrated Circuit) manufacturing method. Further, the substrate processing apparatus according to the present embodiment is configured as a single substrate processing apparatus configured to perform etching processing or asking processing on one substrate in one processing chamber. FIG. 1 illustrates a schematic horizontal cross-sectional view of the substrate processing apparatus according to the embodiment of the present disclosure. FIG. 2 illustrates a schematic vertical cross-sectional view of the substrate processing apparatus according to the embodiment of the present disclosure.

As illustrated in FIGS. 1 and 2, a substrate processing apparatus 20 includes an EFEM (Equipment Front End Module) 100, a load lock chamber unit 200, a transfer module unit 300 and a process chamber unit 400 including a processing chamber in which etching processing is performed. In addition, an x direction and a y direction in FIG. 1 will be referred to as a horizontal direction, and a z direction in FIG. 2 will be referred to as a z direction. Further, in the present embodiment, an xy plane is parallel to a horizontal plane, and the z direction is a vertical direction.

The EFEM 100 includes a load port 120 on which a FOUP (Front Opening Unified Pod) 110 is placed, and an air conveyance robot 130 serving as a first conveyance unit configured to convey a wafer 60 serving as a substrate between the FOUP 110 on the load port 120 and load lock chambers 250 and 260.

The FOUP 110 serving as a substrate container can house up to 25 of the wafers 60. The FOUP 110 which has housed unprocessed substrates is placed on the load port 120 by a conveyance means outside the apparatus, and the FOUP 110 which has housed processed substrates are unloaded from the load port 120 by the conveyance means outside the apparatus.

The air conveyance robot 130 includes five tweezers 131, and can simultaneously convey the five wafers 60. The air conveyance robot 130 can horizontally rotate in an arrow D1 direction on the xy plane in FIG. 1, and can horizontally move in an arrow D2 direction (yy′ direction). Further, each tweezer 131 of the air conveyance robot 130 can elevate in an arrow D4 direction (zz′ direction) in FIG. 2, and can be withdrawn in an arrow D3 direction (xx′ direction) in FIG. 1.

The load lock chamber unit 200 includes the load lock chambers 250 and 260. The load lock chamber 250 includes a buffer unit 210 configured to hold the wafer 60 conveyed from the FOUP 110. The buffer unit 210 includes a boat 211 and an index assembly 212 under the boat 211. The boat 211 and the index assembly 212 under the boat 211 can horizontally rotate in an arrow D5 direction in FIG. 1. This rotation directs a substrate loading/unloading port of the boat 211 to the air conveyance robot 130 or a vacuum conveyance robot 320. The index assembly 212 is an elevation mechanism configured to lift or lower the boat 211.

The load lock chamber 260, and a buffer unit 220, a boat 221 and an index assembly 222 included in the load lock chamber 260 have the same structure and function as those of the load lock chamber 250, the buffer unit 210, the boat 211 and the index assembly 212.

The five wafers 60 can be stacked on the boat 211 in a state where the five wafers 60 of horizontal postures are spaced apart from each other at intervals in the vertical direction (z direction). The load lock chamber 250 is includes a vacuum exhaust device (now illustrated), and can create a vacuum state of a predetermined pressure (i.e., a low pressure state) or an atmospheric pressure state in the load lock chamber 250 based on an instruction from a controller 600 described below.

The transfer module unit 300 includes a transfer module 310 used as a vacuum conveyance chamber, and the above-mentioned load lock chamber 250 (260) is attached to the transfer module 310 via a gate valve 311 (312). The transfer module 310 is provided with the vacuum conveyance robot 320 used as a second conveyance unit. The vacuum conveyance robot 320 conveys the wafer 60 between the load lock chambers 250 and 260 and processing units 410 and 510. In the transfer module unit 300, a vacuum state of a predetermined state is maintained at all times.

The process chamber unit 400 includes the processing unit 410 configured to perform etching processing, and the plasma processing unit 510 configured to perform etching processing and ashing processing. The processing unit 410 (510) is attached to the transfer module 310 via a gate valve 313 (314). In the processing units 410 and 510, a vacuum state of a predetermined pressure is maintained at all times. In this regard, in the present embodiment, the etching processing and the ashing processing are used in combination in the second processing unit 510. However, the embodiment is not limited to this, and different processing units are preferably configured to perform the etching processing and the ashing processing. In addition, respective configurations of these processing unit 410 and processing unit 510 will be described below.

The substrate processing apparatus 20 further includes the controller 600 electrically connected to each component of the substrate processing apparatus 20, i.e., connected by way of an electrical signal. The controller 600 controls an operation of each component. The configuration of the controller 600 will be described below.

In the substrate processing apparatus 20 configured as described above, the wafer 60 is conveyed from the FOUP 110 on the load port 120 to the load lock chamber 250 (260) of the atmospheric pressure state. In this regard, as illustrated in FIG. 2, the air conveyance robot 130 simultaneously inserts the tweezers 131 in the FOUP 110, and places the five wafers on the tweezers 131. In this case, the air conveyance robot 130 lifts and lowers each tweezer 131 of the air conveyance robot 130 to meet a height direction position of the wafer 60 to take out.

After the wafer 60 is placed on the tweezer 131 and taken out from the FOUP 110, the air conveyance robot 130 rotates in the arrow D1 direction, and loads the wafer 60 onto the boat 211 (221) in the buffer unit 210 (220) of the atmospheric pressure state. In this case, the boat 211 (221) operates in the Z direction, so that the boat 211 (221) receives the five wafers 60 from the air conveyance robot 130. After the five wafers 60 are received, the boat 211 (221) is caused to perform in an elevation operation in the Z direction such that a position of the wafer 60 in a lowermost layer of the boat 211 (221) meets a height position of the transfer module unit 300.

Next, after the load lock chamber 250 (260) is placed in a vacuum state of a predetermined pressure, the vacuum conveyance robot 320 moves one wafer 60 of the wafers 60 held on the boat 211 (221) in the load lock chamber 250 (260), onto a susceptor table 411 (511) in the processing unit 410 (510). In this case, the vacuum conveyance robot 320 loads one wafer 60 held on the boat 211 (221) onto a finger 321, takes out the wafer 60 from the boat 211 (221), then rotates in an arrow D7 direction, extends the finger 321 in an arrow D8 direction and moves the wafer 60 onto the susceptor table 411 (511) in the processing unit 410 (510).

To move the wafer 60 from the finger 321 to the susceptor table 411 (511), the wafer 60 is moved onto the susceptor table 411 (511) in collaboration with the finger 321 and lifter pins 413 (513). In more detail, when the finger 321 on which the wafer 60 has been placed moves to a predetermined position on the susceptor table 411 (511), the lifter pins 413 (513) are lifted to support the wafer 60 placed on the finger 321 such that the wafer 60 moves away from the finger 321. After the lifter pins 413 (513) support the wafer 60, the finger 321 contracts in an arrow D8 direction. Subsequently, when the lifter pin 413 (513) lowers, the wafer 60 is placed on the susceptor table 411 (511).

When the wafer 60 for which processing has been terminated is conveyed from the susceptor table 411 (511) to the boat 211 (221) in the load lock chamber 250 (260), the vacuum conveyance robot 320 and the lifter pins 413 (513) perform an operation opposite to the above-mentioned operation of moving the wafer 60 onto the susceptor table 411 (511).

As described above, in the substrate processing apparatus 20, the wafer 60 is conveyed from the FOUP 110 on the load port 120 to the load lock chamber 250 (260) of the atmospheric pressure state. Subsequently, the load lock chamber 250 (260) is vacuumed (vacuum substitution), and the wafer 60 is conveyed from the load lock chamber 250 (260) to the processing unit 410 (510) via the transfer module 310.

Further, the processing unit 410 performs first etching processing (non-plasma processing which does not use plasma), and the wafer 60 having been subjected to the first etching processing is conveyed to the processing unit 510 via the transfer module 310. Furthermore, the processing unit 510 performs second etching processing (plasma processing), and the wafer 60 having been subjected to the second etching processing is conveyed to the processing unit 410 via the transfer module 310. Still further, the processing unit 410 performs third etching processing (non-plasma processing), and the wafer 60 having been subjected to the third etching processing is conveyed to the load lock chamber 250 (260) via the transfer module 310. Subsequently, the wafer 60 in the load lock chamber 250 (260) is returned to the FOUP 110 on the load port 120. Thus, according to the present embodiment, the first etching processing and the third etching processing is non-plasma etching processing.

Alternatively, the wafer 60 which has been subjected to the first etching processing in the processing unit 410 and from which an etching target has been removed can also be conveyed to the load lock chamber 250 (260) via the transfer module 310 and then be returned to FOUP 110 on the load port 120.

Alternatively, the wafer 60 having been conveyed from the lock chamber 250 (260) can be subjected to the second etching processing (plasma processing) in the processing unit 510, and the wafer 60 having been subjected to the second etching processing can also be conveyed to the load lock chamber 250 (260) again via the transfer module 310 and then be returned to FOUP 110 on the load port 120.

Thus, the substrate processing apparatus 20 can perform single processing by using only the processing unit 410, single processing by using only the processing unit 510 and continuous processing by using the processing unit 410 and the processing unit 510.

### First Processing Unit

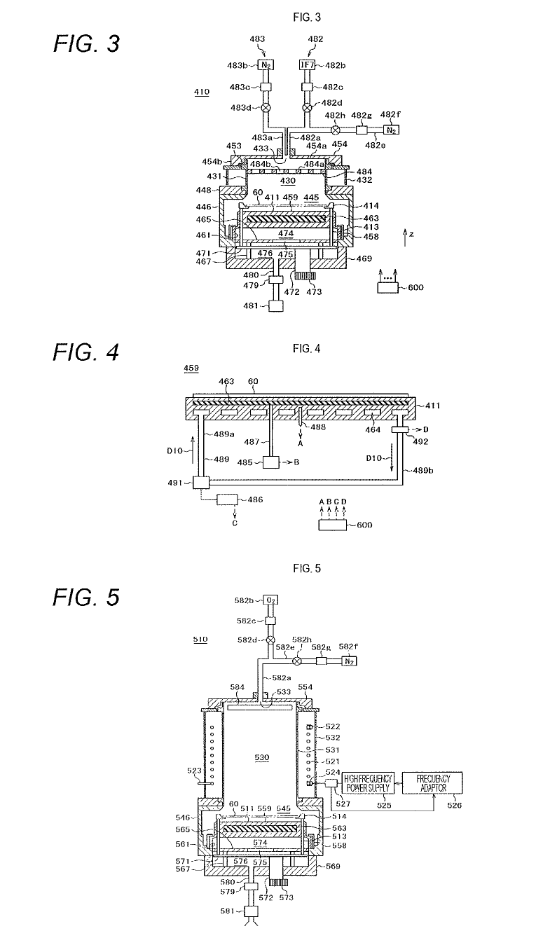

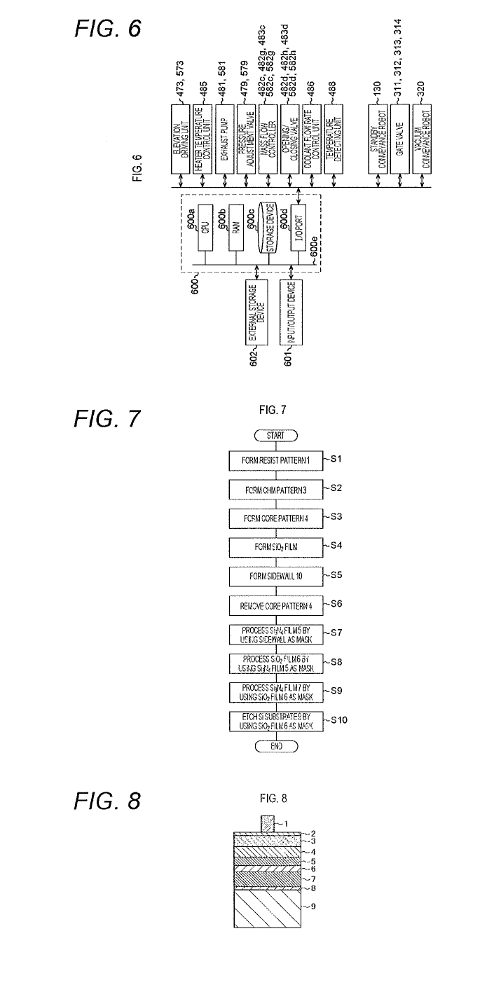

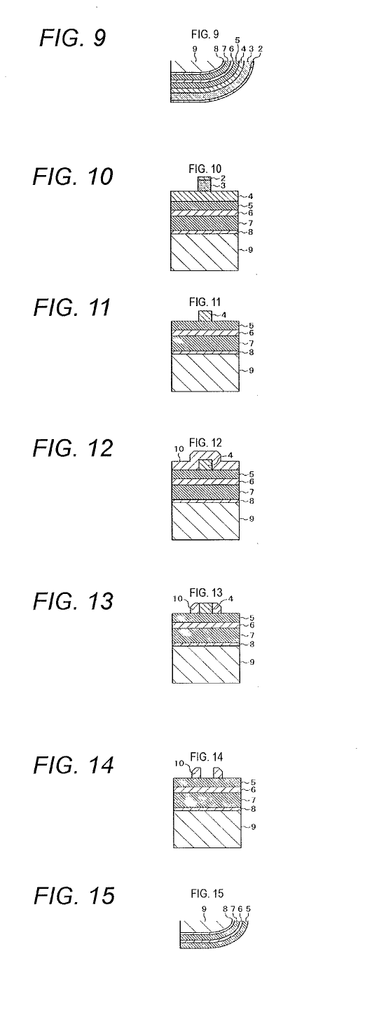

The first processing unit 410 will be described with reference to FIGS. 3 and 4. FIG. 3 illustrates a vertical cross-sectional view of the first processing unit of the substrate processing apparatus according to the present embodiment. FIG. 4 illustrates a vertical cross-sectional view of a susceptor of the first processing unit. The first processing unit 410 is, for example, a processing unit configured to etch a semiconductor substrate without using plasma. As illustrated in FIG. 3, the processing unit 410 includes a gas buffer chamber 430 and a processing chamber 445 configured to hold the wafers 60 such as a semiconductor substrate. The processing unit 410 is configured by disposing the gas buffer chamber 430 above a horizontal base plate 448 serving as a base, and disposing the processing chamber 445 under the base plate 448. Further, the processing container 431 includes at least the gas buffer chamber 430 and the processing chamber 445.

The gas buffer chamber 430 is supplied with a process gas from a gas introduction port 433. An inner wall of the gas buffer chamber 430 is formed of quartz glass or ceramics of a high purity and is formed in a cylindrical shape. The wall is disposed such that an axial line of the cylinder is vertical. At an upper end of the processing container 431, a top plate 454 is provided. The top plate 454 is supported by the inner wall and an upper end of an outer shield. An upper end of the gas buffer chamber 430 is hermetically sealed by the top plate 454.

The top plate 454 includes a cap unit 454a configured to block the upper end of the processing container 431, and a supporting unit 454b configured to support the cap unit 454a. At a nearly center of the cap unit 454a, the gas introduction port 433 is provided. An O-ring 453 is provided between a flange section at a distal end of the processing container 431 (a section which protrudes from the processing container 431 to the outside) and the supporting unit 454b, and is configured to hermetically seal the gas buffer chamber 430.

A sidewall 446 of the processing chamber 445 is formed of quartz glass or ceramics of a high purity and is formed in a cylindrical shape. The sidewall 446 is disposed such that an axial line of the cylinder is vertical. At an upper end of the sidewall 446, an inner wall of the gas buffer chamber 430 is disposed. At a lower end of the sidewall 446, a bottom plate 469 is disposed. The sidewall 446 is hermetically provided at an upper side of the bottom plate 469 to keep the interior of the processing chamber 445 hermetic.

Under the processing chamber 445, a susceptor 459 serving as a substrate placing unit supported by a plurality of (e.g. four) columns 461 is provided. The susceptor 459 includes the susceptor table 411, a heater 463 serving as a substrate heating unit included inside the susceptor 459 and configured to heat the wafer 60 on the susceptor 459, and a susceptor coolant flow path 464 described below.

Under the susceptor 459, an exhaust plate 465 is disposed. The exhaust plate 465 is supported by the bottom plate 469 via a guide shaft 467. An elevation plate 471 is provided to freely lift and lower by using the guide shaft 467 as a guide. The elevation plate 471 supports at least three lifter pins 413.

As illustrated in FIG. 3, the lifter pins 413 pass through the susceptor table 411 of the susceptor 459. Further, at a top of the lifter pins 413, a supporting unit 414 configured to support the wafer 60 is provided. The supporting unit 414 is elongated in a center direction of the susceptor 459. The lifter pins 413 are lifted and lowered to place the wafer 60 on the susceptor table 411, and lift the wafer 60 from the susceptor table 411.

The elevation plate 471 is coupled to an elevation shaft 472 which passes through the bottom plate 469. The elevation shaft 472 is coupled to an elevation driving unit 473. When the elevation driving unit 473 lifts or lowers the elevation shaft 472, the supporting unit 414 is lifted or lowered via the elevation plate 471 and the lifter pins 413.

A baffle ring 458 is provided between the susceptor 459 and the exhaust plate 465. A first exhaust chamber 474 is formed by being surrounded by the baffle ring 458, the susceptor 459 and the exhaust plate 465. In a side surface of the baffle ring 458 of a cylindrical shape, multiple ventilation holes (not illustrated) are uniformly provided. Hence, the first exhaust chamber 474 is partitioned from the processing chamber 445 by the baffle ring 458, and continues to the processing chamber 445 via the ventilation holes.

Further, a second exhaust chamber 476 is formed by being surrounded by the exhaust plate 465 and the bottom plate 469 of a concave shape. Furthermore, an exhaust communication hole 475 is provided in a center section of the exhaust plate 465. Hence, the first exhaust chamber 474 and the second exhaust chamber 476 continue to each other via the exhaust communication hole 475.

### First Exhaust Unit

An exhaust pipe 480 elongated in a gravitational direction, i.e., in a z direction is provided to pass through the bottom plate 469. The second exhaust chamber 476 continues to the exhaust pipe 480. The exhaust pipe 480 is provided with a pressure adjustment valve 479 and an exhaust pump 481 in order from an upstream. Thus, the exhaust pipe 480 is provided under the susceptor 459 and in the gravitational direction. A gas supplied to the processing chamber 445 is easily exhausted without remaining in the processing chamber 445. Consequently, when a maintenance person performs maintenance, it is possible to reduce the degree of risk of contact with a gas. The first exhaust unit which exhausts the gas (atmosphere) in the processing chamber 445 is configured to include at least the exhaust pipe 480 and the pressure adjustment valve 479. In addition, the exhaust pump 481 may be included in the first exhaust unit.

### First and Second Gas Supply Units

The top plate 454 at the upper side of the processing container 431 is connected with a first gas supply unit 482 (first gas supply unit) and a second gas supply unit 483 (second gas supply unit). The first gas supply unit 482 includes a gas supply pipe 482a connected to the gas introduction port 433, and an inert gas supply pipe 482e connected to the gas supply pipe 482a. The gas supply pipe 482a is provided with a first gas source 482b serving as a gas source of a first gas, amass flow controller 482c and an opening/closing valve 482d in order from the upstream. The inert gas supply pipe 482e is provided with an inert gas source 482f serving as a gas source of an inert gas, amass flow controller 482g and an opening/closing valve 482h in order from the upstream.

By controlling the mass flow controller 482c and the opening/closing valve 482d, it is possible to control a flow rate of the first gas. Further, by controlling the mass flow controller 482g and the opening/closing valve 482h, it is possible to control a flow rate of the inert gas. The inert gas is used as a purge gas for purging (removing) a remaining gas in the gas supply pipe 482a, and is further used as a carrier gas of the first gas supplied to the gas supply pipe 482a.

The first gas supply unit 482 is configured to include at least the gas supply pipe 482a, the mass flow controller 482c and the opening/closing valve 482d. In addition, the first gas supply unit 482 may include a purge gas supply pipe 482e, the mass flow controller 482g and the opening/closing valve 482h. The first gas supply unit 482 may further include the first gas source 482b and the inert gas source 482f.

In the present embodiment, the iodine heptafluoride (IF₇) gas is used as the first gas. In addition, for example, one gas selected from a group of consisting of chlorine trifluoride (ClF₃), xenon difluoride (XeF₂), bromine trifluoride (BrF₃), bromine pentafluoride (BrF₅) and iodine pentafluoride (IF₅) can also be used as the first gas. For example, a nitrogen (N₂) gas is used as the inert gas supplied from the inert gas source 482f.

The second gas supply unit 483 is provided adjacent to the gas supply unit 482 on the top plate 454 at the upper side of the processing container 431. The second gas supply unit 483 includes a gas supply pipe 483a connected to the gas introduction port 433. The gas supply pipe 483a is provided with a second gas source 483b serving as a gas source of a second gas, a mass flow controller 483c and an opening/closing valve 483d in order from the upstream.

By controlling the mass flow controller 483c and the opening/closing valve 483d, it is possible to control a flow rate of the second gas. The second gas supply unit 483 is configured to include at least the gas supply pipe 483a, the mass flow controller 483c and the opening/closing valve 483d. In addition, the second gas supply unit 483 may include the second gas source 483b.

The inert gas such as the nitrogen (N₂) is used as the second gas. This inert gas is used as a dilution gas of the first gas or a purge gas for a remaining gas in the processing chamber 445.

In addition, in the present embodiment, a gas introduction port from the first gas supply unit 482 and the second gas supply unit 483 is the common gas introduction port 433. However, the gas introduction port is not limited to this, and gas introduction ports which support the first gas supply unit 482 and the second gas supply unit 483, respectively, may be provided.

By controlling the mass flow controllers 482c and 483c and the pressure adjustment valve 479 and adjusting a gas supply amount or a gas exhaust amount from the processing chamber 445, a pressure in the processing chamber 445 and a partial pressure of an introduced gas are adjusted.

In the gas buffer chamber 430, a porous shower plate 484 is provided. The shower plate 484 includes a plate unit 484a, and a plurality of hole units 484b provided to this plate unit 484a. The gas having been introduced from the gas introduction port 433 hits the plate unit 484a of the shower plate 484, passes through the hole units 484b and is supplied to a surface of the wafer 60. Thus, the gas having been introduced into the gas buffer chamber 430 is uniformly dispersed by the shower plate 484, and is supplied onto the wafer 60.

### First Temperature Control Unit

FIG. 4 illustrates a vertical cross-sectional view of the susceptor 459 of the first processing unit 410. The susceptor table 411 includes the heater 463 and the susceptor coolant flow path 464. The heater 463 and the susceptor coolant flow path 464 are provided in the susceptor table 411 to control a temperature of the wafer 60 placed on the susceptor 459.

The heater 463 is connected to a heater temperature control unit 485 via a heater power supply line 487. A temperature detecting unit 488 which detects temperatures of the susceptor 459 and the wafer 60 placed on the susceptor 459 is provided near the heater 463. The temperature detecting unit 488 is electrically connected to the controller 600. Temperature data detected by the temperature detecting unit 488 is input to the controller 600. The controller 600 instructs the heater temperature control unit 485 to control the amount of power to supply to the heater 463 based on the detected temperature data, and to control the heater 463 to heat the wafer 60 to a desired temperature.

The susceptor coolant flow path 464 is connected to an external susceptor coolant flow path 489. In more detail, a coolant introduction port of the susceptor coolant flow path 464 is connected to an external susceptor coolant flow path 489a. A coolant exhaust port of the susceptor coolant flow path 464 is connected to an external susceptor coolant flow path 489b. In the susceptor coolant flow path 464 and the external susceptor coolant flow path 489, a coolant flows in an arrow D10 direction. The external susceptor coolant flow path 489 is connected to a coolant supply unit 491. The coolant supply unit 491 keeps a temperature of a coolant flowing in the external susceptor coolant flow path 489a within a predetermined value range, and controls a flow rate of the coolant, based on an instruction from a coolant flow rate control unit 486.

The external susceptor coolant flow path 489b at the upstream of the coolant supply unit 491 is provided with a coolant temperature detecting unit 492 configured to detect a temperature of the coolant having flowed in the susceptor coolant flow path 464. The coolant temperature detecting unit 492 and the coolant flow rate control unit 486 are electrically connected to the controller 600. Temperature data detected by the coolant temperature detecting unit 492 is input to the controller 600. The controller 600 instructs the coolant flow rate control unit 486 to control a flow rate of the coolant flowing in the external susceptor coolant flow path 489a based on the detected temperature data to heat the wafer 60 to a desired temperature. The coolant flow rate control unit 486 controls for the coolant supply unit 491 the flow rate of the coolant flowing in the external susceptor coolant flow path 489 based on an instruction from the controller 600.

A first temperature control unit is configured to include at least the heater temperature control unit 485 and the coolant flow rate control unit 486. In addition, the first temperature control unit may include the heater 463 and the susceptor coolant flow path 464. Further, the first temperature control unit may include the coolant supply unit 491, the external susceptor coolant flow path 489, the coolant temperature detecting unit 492 and the heater power supply line 487. Furthermore, the heater 463 and the susceptor coolant flow path 464 will be collectively referred to as a first temperature adjustment mechanism.

### Second Processing Unit

The second processing unit 510 will be described with reference to FIG. 5. FIG. 5 illustrates a vertical cross-sectional view of the second processing unit of the substrate processing apparatus according to the present embodiment. The second processing unit 510 is a high frequency electrodeless discharge type plasma processing unit which can perform etching processing and ashing processing by performing dry processing on a film formed on a semiconductor substrate. As illustrated in FIG. 5, the processing unit 510 includes a plasma generating chamber 530 configured to generate plasma,

a processing chamber 545 configured to hold the wafer 60 such as a semiconductor substrate,

a high frequency power supply 525 configured to supply high frequency power to a plasma source such as a resonance coil 521, and

a frequency adaptor 526 configured to control an oscillation frequency of the high frequency power supply 525.

A reaction container 531 is formed of quartz glass or ceramics of a high purity and is formed in a cylindrical shape. The processing chamber 545 is provided under the reaction container 531. Under the processing chamber 545, a susceptor 559 supported by a plurality of (e.g. four) columns 561 is provided. The susceptor 559 includes the susceptor table 511, and a heater 563 serving as a substrate heating unit provided inside the susceptor 559 and configured to heat the wafer 60 on the susceptor 559. In addition, in the present embodiment, a susceptor coolant flow path is not provided in the susceptor 559. However, the susceptor 559 may be configured to include the same susceptor coolant flow path as the susceptor coolant flow path 464 of the first processing unit illustrated in FIG. 4 to control the flow rate of a coolant as the first processing unit.

### Second Temperature Control Unit

The second temperature control unit controls a temperature of a substrate on the susceptor 559 of the second processing unit, and employs the same configuration as that of the first temperature control unit. That is, the heater 563 is connected to the second temperature control unit via a second heater power supply line. The second temperature detecting unit which detects temperatures of the susceptor 559 and the wafer 60 placed on the susceptor 559 is provided near the heater 563. The second temperature detecting unit is electrically connected to the controller 600. Temperature data detected by the second temperature detecting unit is input to the controller 600. The controller 600 instructs the second temperature control unit to control the amount of power to supply to the heater 563 based on the detected temperature data, and to control the heater 563 to heat the wafer 60 to a desired temperature. In addition, the second temperature control unit may include the heater 563.

Under the susceptor 559, an exhaust plate 565 is disposed. The exhaust plate 565 is supported by a bottom plate 569 via a guide shaft 567. An elevation plate 571 is provided under the exhaust plate 565 to freely lift and lower by using the guide shaft 567 as a guide. The elevation plate 571 supports at least three lifter pins 513. The lifter pin 513 passes through the susceptor 559. At a top of the lifter pins 513, a supporting unit 514 which supports the wafer 60 is provided. The lifter pins 513 are lifted or lowered to place the wafer 60 on the susceptor 559, and lift the wafer 60 from the susceptor 559. An elevation shaft 572 of an elevation driving unit 573 is coupled to an elevation plate 571 passing through the bottom plate 569. When the elevation driving unit 573 lifts or lowers the elevation shaft 572, the supporting unit 514 is lifted or lowered via the elevation plate 571 and the lifter pins 513.

### Second Exhaust Unit

A baffle ring 558 is provided between the susceptor 559 and the exhaust plate 565. The baffle ring 558 of a cylindrical shape is uniformly provided with multiple ventilation holes. The processing chamber 545 and a first exhaust chamber 574 continue to each other via the ventilation holes. An exhaust communication hole 575 is provided to the exhaust plate 565. The first exhaust chamber 574 and a second exhaust chamber 576 continue to each other via the exhaust communication hole 575. An exhaust pipe 580 continues to the second exhaust chamber 576, and the exhaust pipe 580 is provided with a pressure adjustment valve 579 and an exhaust pump 581. The second exhaust unit which exhausts a gas (atmosphere) in the processing chamber 545 is configured to include at least the exhaust pipe 580 and the pressure adjustment valve 579. In addition, the exhaust pump 581 may be included in the second exhaust unit.

### Third Gas Supply Unit

A top plate 554 at an upper side of the reaction container 531 is connected with a third gas supply unit (third gas supply unit) 582. The third gas supply unit 582 includes a gas supply pipe 582a connected to a gas introduction port 533, and an inert gas supply pipe 582e connected to the gas supply pipe 582a. The gas supply pipe 582a is provided with a third gas source 582b serving as a gas source of a third gas (an O₂ gas in the present embodiment), a mass flow controller 582c and an opening/closing valve 582d in order from the upstream. The inert gas supply pipe 582e is provided with an inert gas source 582f serving as a gas source of an inert gas (an N₂ gas in the present embodiment), a mass flow controller 582g and an opening/closing valve 582h in order from the upstream.

By controlling the mass flow controller 582c and the opening/closing valve 582d, it is possible to control a flow rate of the third gas. Further, by controlling the mass flow controller 582g and the opening/closing valve 582h, it is possible to control a flow rate of the inert gas. The inert gas is used as a purge gas for purging (removing) a remaining gas in the gas supply pipe 582a or as purge gas for exhausting an atmosphere in the processing chamber 545, and is further used as a dilution gas of the third gas supplied to the gas supply pipe 582a.

The third gas supply unit 582 is configured to include at least the gas supply pipe 582a, the mass flow controller 582c and the opening/closing valve 582d. In addition, the third gas supply unit 582 may include the purge gas supply pipe 582e, the mass flow controller 582g and the opening/closing valve 582h. The third gas supply unit 582 may further include the third gas source 582b and the inert gas source 582f.

Further, in the reaction container 531, a baffle plate 584 which has a nearly disk shape which allows a process gas to flow along an inner wall of the reaction container 531 and is formed of quartz is provided. In addition, the mass flow controller 582c and the pressure adjustment valve 579 adjust a gas supply amount and an exhaust amount to adjust a pressure in the processing chamber 545.

Both ends of the resonance coil 521 are electrically grounded, and at least one end of the resonance coil 521 is grounded via a movable tab 522. FIG. 5 illustrates the other fixed ground 523. A power feeding unit is configured by a movable tab 524 between the both grounded ends of the resonance coil 521 to finely adjust an impedance of the resonance coil 521.

An outer shield 532 shields leakage of an electromagnetic wave to an outside of the resonance coil 521, and is formed in a cylindrical shape by using a conductive material such as an aluminum alloy, copper or a copper alloy. A RF sensor 527 is installed at an output side of the high frequency power supply 525, and monitors a traveling wave, a reflective wave and the like. Reflective wave power monitored by the RF sensor 527 is input to the frequency adaptor 526. The frequency adaptor 526 controls a frequency to minimize a reflective wave.

For example, after the wafer 60 kept at a room temperature is placed on the susceptor table 511, the process gas serving as an etching gas is supplied from the gas supply pipe 582a to the plasma generating chamber 530. In the present embodiment, an oxygen (O₂) gas is used as the process gas. Further, at least one selective from a group of consisting of hydrogen, water, ammonia, carbon tetrafluoride (CF₄) or the like can be used as the process gas. After the process gas is supplied, power is supplied from the high frequency power supply 525 to the resonance coil 521 to cause free electrons to accelerate by an induction field excited inside the resonance coil 521 and to collide with gas molecules to excite the gas molecules and to generate plasma. Thus, plasma processing such as etching processing and ashing processing is performed by using the gas activated by the plasma.

The first temperature control unit and the second temperature control unit will be collectively referred to as a temperature control unit. The first gas supply unit, the second gas supply unit and the third gas supply unit will be collectively referred to as a gas supply unit. The first exhaust unit and the second exhaust unit will be collectively referred to as an exhaust unit. Hence, the temperature control unit means the first temperature control unit, the second temperature control unit or both of the first and second temperature control units. The same meaning as that of the temperature control unit is applicable to the gas supply unit and the exhaust unit.

In addition, the present embodiment where the first temperature control unit and the second temperature control unit are configured separately from the controller 600 has been described. However, the present embodiment is not limited to this, and the controller 600 may function as the first temperature control unit and the second temperature control unit.

### Controller

### Control Unit

Next, a configuration of the controller 600 will be described. FIG. 6 illustrates a structure diagram of the controller according to the present embodiment. As illustrated in FIG. 6, the controller 600 serving as the control unit (control means) is configured as a computer including a CPU (Central Processing Unit) 600a, a RAM (Random Access Memory) 600b, a storage device 600c and an I/O port 600d. The RAM 600b, the storage device 600c and the I/O port 600d are configured to exchange data with the CPU 600a via an internal bus 600e. The controller 600 is connected with an input/output device 601 configured as a touch panel, for example.

The storage device 600c is configured as a flash memory or a HDD (Hard Disk Drive), for example. In the storage device 600c, a control program of controlling an operation of the substrate processing apparatus 20 and a process recipe in which a procedure and conditions of substrate processing of the substrate processing apparatus 20 described below have been written are stored in readable states. Further, processing conditions are stored per type of an etching gas and an ashing gas serving as a process gas. In this regard, processing conditions refer to conditions for processing a substrate such as temperature zones of a substrate or a susceptor, a pressure of a processing chamber, a partial pressure of a gas, a gas supply amount, a coolant flow rate and a processing time.

In addition, the process recipe is configured to cause the controller 600 to execute a sequence in the substrate processing process of the substrate processing apparatus 20 described below to obtain a predetermined result, and functions as a program. The process recipe and the control program will be collectively referred to as a program. In addition, a word, the program, used in this description means that the program includes the process recipe alone, the control program alone or both of the process recipe and the control program. The RAM 600b is configured as a working memory region (work area) in which the program and data read by the CPU 600a are temporarily held.

The I/O port 600d is connected to the above-mentioned elevation driving units 473 and 573, heater temperature control unit 485, temperature detecting unit 488, pressure adjustment valves 479 and 579, mass flow controllers 482c, 482g, 483c, 582c and 582g, opening/closing valves 482d, 482h, 483d, 582d and 582h, exhaust pumps 481 and 581, air conveyance robot 130, gate valves 311 to 314, vacuum conveyance robot 320 and coolant flow rate control unit 486.

The CPU 600a is configured to read the control program from the storage device 600c to execute, and to read the process recipe from the storage device 600c in response to an input of an operation command or the like from the input/output device 501. Further, the CPU 600a is configured to control an operation of lifting or lowering the lifter pin (e.g. 413) by using the elevation driving unit (e.g. 473),

an operation of heating the wafer 60 by using a heater temperature control unit (e.g. 485),

a pressure adjustment operation by using a pressure adjustment valve (e.g. 479), and

an operation of adjusting a flow rate of a process gas by using the mass flow controller (e.g. 482c) and the opening/closing valve (e.g. 482d) according to contents of the read process recipe.

In addition, the controller 600 is not limited to a computer configured as a dedicated computer, and may be configured as a mainframe computer. For example, by preparing an external storage device 602 in which the above-mentioned program has been stored and installing the program in a mainframe computer by using this external storage device 602, it is possible to configure the controller 600 according to the present embodiment. The external storage device 602 is configured as a semiconductor memory such as magnetic disks such as a magnetic tape, a flexible disk and a hard disk, optical disks such as a CD and a DVD, magneto-optical disks such as an MO, a USB memory (USB Flash Drive) and a memory card. In addition, a means for supplying the program to a computer is not limited to a means for supplying the program via the external storage device 602. For example, the program may be supplied without the external storage device 602 by using a communication means such as the Internet or a dedicated line.

As described above, the storage device 600c and the external storage device 602 are configured as computer-readable recording media. The storage device 600c and the external storage device 602 will be collectively referred to simply as recording media below. In addition, a word, the recording medium, used in this description means that the recording medium includes the storage device 600c alone, the external storage device 602 alone or both of the storage device 600c and the external storage device 602.

### (2) Substrate Processing Method

Next, an example of a substrate processing process of performing the substrate processing method according to the present embodiment will be described below with reference to FIGS. 7 to 19. This substrate processing process is performed as a process of forming a fine pattern and one process of the semiconductor device manufacturing method. FIG. 7 illustrates a view of a processing flow of the substrate processing method according to the embodiment of the present disclosure. FIGS. 8, 10 to 14 and 16 to 19 illustrate views illustrating first to tenth stages of the fine pattern-forming processing according to the embodiment of the present disclosure, respectively. Further, FIGS. 9 and 15 illustrate views illustrating a substrate back side in the stages in FIGS. 8 and 14.

In addition, the substrate processing apparatus 20 according to the present embodiment performs at least step S6 (core pattern removing process) in FIG. 7.

First, as indicated by step S1 in FIG. 7, a resist pattern 1 of a desired line width is formed on a Si film 2. This line width is a line width of a resolution limitation of an exposure device or more. In more detail, as illustrated in FIG. 8, a SiO₂ film 8, a Si₃N₄ film 7, a SiO₂ film 6, a Si₃N₄ film 5, an amorphous Si film 4, a carbon hardmask (CHM) film 3 serving as a hardmask including carbon, and the Si film 2 serving as an antireflection film are formed in this order at a surface side of a Si substrate 9 to form a multilayer film. Further, a photoresist is applied to this multilayer film, is exposed by a lithography technique and then is developed to form the resist pattern 1. Thus, a multilayer resist film is formed.

The SiO₂ film 8 is a thermal oxide film whose film thickness is about 3 to 10 nm, and is formed on the Si substrate 9 at, for example, an oxidation temperature of 600 to 1100° C. An object of the SiO₂ film 8 is to protect a surface of the Si substrate 9 in a process of removing the Si₃N₄ film 7 by heat phosphoric acid. The Si₃N₄ film 7 has a film thickness of about 30 to 50 nm, and is formed on the SiO₂ film 8 at a temperature of 500 to 900° C. by a CVD (Chemical Vapor Deposition) method. The Si₃N₄ film 7 is a stopper film upon a CMP process of forming a groove 21 of the Si substrate 9 illustrated in FIG. 19, and planarizing the SiO₂ film buried in the groove 21.

The SiO₂ film 6 has a film thickness of about 30 to 50 nm, and is formed on the Si₃N₄ film 7 at a temperature of 500 to 900° C. by the CVD method. By dry-etching the underlayer Si₃N₄ film 7, the SiO₂ film 8 and the Si substrate 9 thereunder, the SiO₂ film 6 becomes a hardmask for forming the groove 21 of the Si substrate 9 illustrated in FIG. 19.

The Si₃N₄ film 5 has a film thickness of about 5 to 20 nm, and is formed on the SiO₂ film 6 at a temperature of 500 to 900° C. by the CVD method. The Si₃N₄ film 5 is a film used to transfer a SiO₂ film pattern of a sidewall used in a SADP process. The SiO₂ film of the sidewall formed at a low temperature has a low dry etching resistance. Therefore, it is difficult to process the thick Si₃N₄ film 7 by using the SiO₂ film of the sidewall as a mask. Hence, a process (step S7 described below) of transferring the SiO₂ film pattern of the sidewall to the thin Si₃N₄ film 5 once is used.

The amorphous Si film 4 has a film thickness of about 40 to 60 nm, and is formed on the Si₃N₄ film 5 at a temperature of 400 to 550° C. by the CVD method. The CHM film 3 is an amorphous carbon film, has a film thickness of about 100 to 500 nm, and is formed on the amorphous Si film 4 at a temperature of 200 to 550° C. by the CVD method. The amorphous Si film 2 has a film thickness of about 2 to 10 nm, and is formed on the CHM film 3 at a temperature of 400 to 550° C. by the CVD method. The amorphous Si film 2 functions as an antireflection film when exposure is performed by a lithography technique.

When the films 8 to 2 are stacked on the surface side of the Si substrate 9, the films 8 to 2 are stacked in this order at a back side of the Si substrate 9 as illustrated in FIG. 9. Even when the back side of the Si substrate 9 is supported by a flat susceptor, the above-mentioned stacked films 8 to 2 are formed at least a surrounding section of the back side of the Si substrate 9. The stacked films 4 to 2 among these stacked films 8 to 2 are soft films which are relatively easily delaminated. Therefore, there is an undesirable concern that the stacked films 4 to 2 are delaminated and produce particles in a process performed after the substrate processing process. Hence, the stacked films 4 to 2 are removed in step S6 in FIG. 7 described below.

Next, a CHM pattern having the same line width as that of the resist pattern 1 is formed as indicated by step S2 in FIG. 7. In more detail, as illustrated in FIG. 10, by using the patterned resist 1 as a mask, the underlayer amorphous Si film 2 is processed by known dry etching processing which uses, for example, a Cl₂ gas, and then, the CHM film 3 is processed by known dry etching processing which uses, for example, an O₂ gas. Subsequently, the resist 1 is removed by the known asking processing which uses, for example, an O₂ gas. In addition, etching performed on the Si film 2 is anisotropic etching performed on a surface of the Si substrate 9 in the vertical direction. Therefore, the amorphous Si film 2 at the back side of the Si substrate 9 is not removed.

Next, the core pattern 4 having the same line width as that of the CHM film 3 is formed as indicated by step S3 in FIG. 7. In more detail, as illustrated in FIG. 11, by using the CHM film 3 as a mask, the underlayer amorphous Si film 4 is processed by known dry etching processing which uses, for example, a Cl₂ gas or a CF₂Cl₂ gas, and then the core pattern 4 having the same line width as that of the resist pattern 1 is formed by using this amorphous Si film 4. Subsequently, the CHM film 3 is removed by the known dry etching processing which uses, for example, an O₂ gas. In this case, the Si film 2 at the back side of the Si substrate 9 is not removed, and therefore the CHM film 3 at the back side of the Si substrate 9 is not removed.

As described above, the core pattern-forming process includes an exposure/development process and a dry etching process. Further, in the exposure/development process, a resist film is exposed to forma pattern of a predetermined line width, and then is developed to form the resist pattern 1. In the dry etching process, by using the resist pattern 1 as a mask, the antireflection film (Si film 2) and the hardmask film (CHM film 3) are etched to form the core pattern 4.

Further, at a stage at which formation of the core pattern 4 has been terminated, at the back side of the Si substrate 9, there are a back side core material film serving as a film formed of the same material as that of the core pattern 4 at the surface side of the Si substrate 9, a back side hardmask film formed on the back side core material film, and a back side antireflection film formed on the back side hardmask film. The back side core material film is formed simultaneously along with the core pattern 4 at the surface side of the Si substrate 9. The back side hardmask film is formed simultaneously along with the CHM film 3 at the surface side of the Si substrate 9. The back side antireflection film is formed simultaneously along with the antireflection Si film 2 at the surface side of the Si substrate 9.

Next, as indicated by step S4 in FIG. 7, a SiO₂ film 10 is formed on the core pattern 4 and the Si₃N₄ film 5. In more detail, as illustrated in FIG. 12, in an atmosphere of a low temperature such as 0 to 400° C. and, more preferably, 0 to 100° C., and a low pressure (e.g. 399 Pa), the SiO₂ film 10 is deposited and formed by alternately supplying an amino silane gas or a chloro silane gas and a H₂O gas. When the amino silane gas and the H₂O gas are supplied, pyridine is simultaneously supplied by using the amino silane gas and the H₂O gas as catalysts. Further, N₂ purge in a processing space is inserted during the alternate supply. That is, N₂ purge is performed when gases to be alternately supplied are switched.

In addition, a reason that the SiO₂ film 10 is formed at a low temperature of 100° C. or less or 400° C. or less in the SADP process is to obtain a sidewall film of a low film stress. A high film stress of the sidewall film causes an inclination or a collapse of the sidewall left after the core pattern 4 is removed.

Further, when the SiO₂ film 10 is formed at the surface side of the Si substrate 9, the SiO₂ film 10 is deposited and formed at the back side at the surrounding section of the Si substrate 9, too. In this regard, the SiO₂ film 10 at the back side of the surrounding section of the Si substrate 9 is removed in step S5 in FIG. 7 described below.

Next, as indicated by step S5 in FIG. 7, the SiO₂ film 10 is processed to form the sidewall. In more detail, as illustrated in FIG. 13, the SiO₂ film 10 is processed by known dry etching processing which uses, for example, a mixed gas of a CF₄ gas and a H₂ gas. In this case, the line width of the sidewall 10 is a line width narrower than that of the resist pattern 1, i.e., a line pattern less than a resolution limitation. Thus, the sidewall film 10 left at the substrate surface side and having the line width less than the resolution limitation of lithography is formed. In this case, even when the back side of the Si substrate 9 is supported by a flat susceptor, the mixed gas reaches at least the surrounding section of the back side of the Si substrate 9. Therefore, the SiO₂ film 10 deposited at the back side of the surrounding section of the Si substrate 9 is removed.

Next, as indicated by step S6 in FIG. 7, processing of removing the Si core pattern 4 is performed. In more detail, as illustrated in FIG. 14, the Si film 4 sandwiched between the sidewalls 10 is removed by dry etching processing without removing the sidewalls 10, i.e., in a state where the sidewalls 10 are left. This core pattern removal processing is a feature of the present disclosure.

In the present embodiment, the processing unit 410 illustrated in FIG. 3 performs etching processing under following processing conditions C1 by using an IF7 gas as an etching gas of the core pattern removal processing. The processing conditions C1 include that a substrate temperature is within a range from a room temperature (30° C. in this case) to 50° C. and, more preferably, the room temperature to 40° C., a pressure in the processing chamber 445 is 100 Pa to 1000 Pa and, more preferably, 200 to 500 Pa, a flow rate of the IF7 gas is 0.5 slm to 4 slm and, more preferably, 0.5 slm to 1 slm and a flow rate of a N₂ gas which is a carrier gas is within a range of 0 slm to 1 slm. Further, a duration of time to supply the IF₇ gas needs to be a duration of time to remove the Si film 4. If an etching time becomes long more or less, the IF₇ gas has a unique selectivity and there is no worry that over etching is performed. Therefore, the etching time is determined according to a film thickness of the etching target film 4, too, and is not limited herein.

When the IF₇ gas is used, it is possible to improve an etching rate of Si by performing etching at 50° C. or less, and secure a high selectivity with respect to the underlayer Si₃N₄ film 5. Further, at 40° C. or less, it is possible to secure a much higher selectivity. Furthermore, when the pressure is 100 Pa to 1000 Pa, it is possible to secure a high selectivity, and, when the pressure is 200 to 500 Pa, it is possible to secure a much higher selectivity. Still further, when the flow rate of the IF₇ gas is 0.5 slm to 4 slm, it is possible to secure a high selectivity and, when the flow rate is 0.5 slm to 1 slm, it is possible to secure a much higher selectivity. Moreover, to secure a high selectivity, it is preferable to supply the IF₇ gas alone without supplying other gases other than the etching gas such as the carrier gas.

Thus, it is possible to highly selectively etch the Si core pattern 4 with respect to the SiO₂ film 10 serving as the sidewall film, and highly selectively etch Si with respect to the underlayer Si₃N₄ film 5, too. That is, it is possible to highly selectively etch and remove Si of the core pattern 4 while suppressing etching of the SiO₂ film 10 and the Si₃N₄ film 5. Further, in this case, by performing etching at a temperature of 50° C. or less, it is possible to prevent the SiO₂ film 10 formed at a low temperature of 100° C. or less or 400° C. or less from changing due to a temperature.

Preferably, in the core pattern removal processing, (a) first etching processing which does not use plasma produced by an IF₇ gas, (b) second etching processing which uses plasma produced by, for example, an O₂ gas and (c) third etching processing which does not use plasma produced by the IF₇ gas are performed in this order. In the present embodiment, (a) the first etching processing which uses the IF₇ gas is performed by using the processing unit 410 illustrated in FIG. 3. Then, (b) the second etching processing which uses the O₂ gas is performed by using the processing unit 510. Subsequently, (c) the third etching processing which uses the IF₇ gas is performed by using the processing unit 410. The processing conditions of (a) and (c) are the same as the above-mentioned processing conditions C1.

In (a) the first etching processing which uses the IF₇ gas, the Si core pattern 4 at the surface of the Si substrate 9 and the Si film 2 at the back surface are removed, and the surface of the Si substrate 9 is only the SiO₂ film 10 of the sidewall and the underlayer Si₃N₄ film 5. Next, the CHM film 3 at the back surface is removed by (b) the plasma processing (second etching processing) which uses the O₂ gas. This O₂ plasma processing is performed under a condition that there is not such oxidizing power for oxidizing the surface of the underlayer Si₃N₄ film 5. The condition that there is no oxidizing power is realized at a low pressure by reducing a flow rate of the O₂ gas. Hence, a reaction does not occur on the surface of the Si substrate 9, and the CHM film 3 on the back surface of the Si substrate 9 is removed. Further, in (c) the third etching processing which uses the IF₇ gas, the Si film 4 under the CHM film 3 on the back surface of the Si substrate 9 is removed. As described above, the IF₇ gas makes it possible to remove the Si film 4 on the back surface of the Si substrate 9 while highly selectively suppressing etching of the SiO₂ film 10 and the Si₃N₄ film 5. Meanwhile, in (b) the plasma processing which uses the O₂ gas, the SiO₂ film 10 of the sidewall on the surface of the Si substrate 9 is hardened in some cases. In such a case, the SiO₂ film 10 of the sidewall on the surface of the Si substrate 9 has quality improved by O₂ plasma processing, and has an improved dry etching resistance.

By so doing, as illustrated in FIG. 15, it is possible to remove a stacked film of the Si film 2, the CHM film 3 and the Si film 4 at the substrate back side in parallel to removal of the Si core pattern 4 at the substrate surface side. At least, it is possible to remove the Si film 4 deposited at the substrate back side upon formation of the Si core pattern 4 at the substrate surface side. In more detail, it is possible to remove the Si film 2 (back side antireflection film) at the substrate back side by performing the processing (a), remove the CHM film 3 (back side hardmask film) at the substrate back side by performing the processing (b), and remove a film (back side core material film) formed of the same material as that of the Si core pattern 4 at the substrate surface side by performing the processing (c). Thus, in the process of removing the Si core pattern 4, the back side antireflection film, the back side hardmask film and the core material film are removed.

In addition, as described above, the CHM film 3 serving as an amorphous carbon film in particular is susceptible to a high temperature annealing process, an oxidation process and an O₂ asher process performed in a subsequent process of the substrate processing process, and therefore needs to be removed to suppress particles caused by delamination of a film at the substrate back side in a subsequent process. The Si film 2 and the Si film 4 are conductive films and cause problems of particles in some cases, and therefore need to be removed. Further, a problem that a contaminant is mixed in the Si substrate in a state where Si is exposed occurs at the back side of the substrate. Therefore, it is preferable to cover the substrate back side with an insulating film. Hence, the films 5 to 8 are left at the substrate back side.

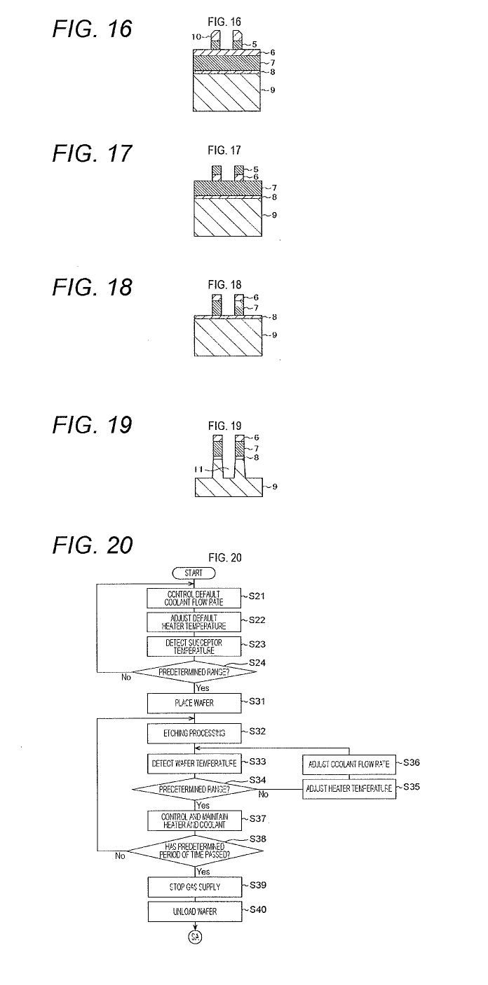

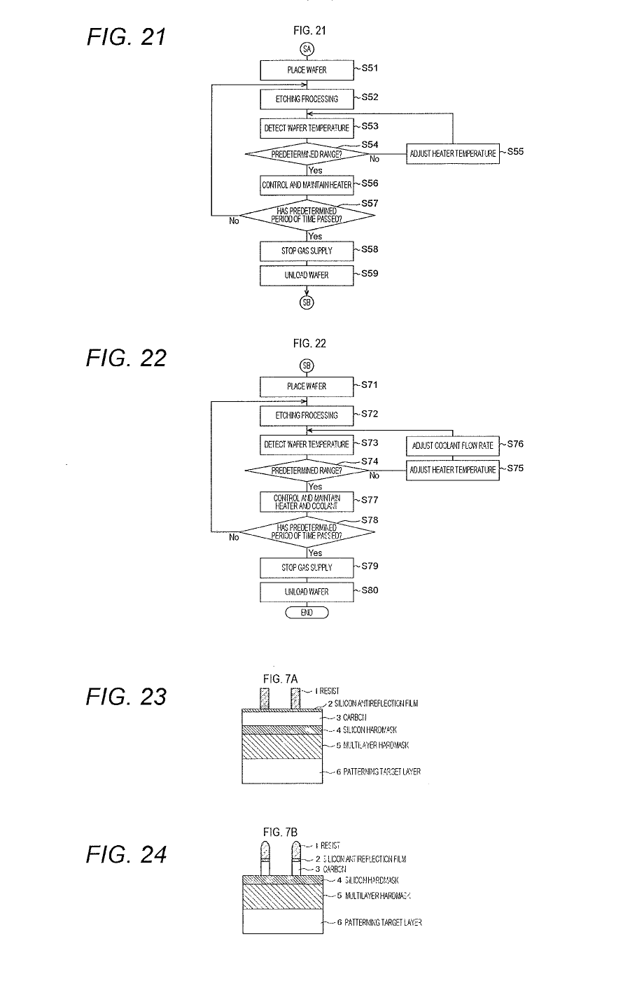

Next, as indicated by step S7 in FIG. 7, the underlayer Si₃N₄ film 5 is processed by using as masks the SiO₂ films 10 serving as the sidewalls. In more detail, as illustrated in FIG. 16, the Si₃N₄ film 5 is processed by known dry etching processing which uses, for example, a Cl₂ gas to form a pattern of the Si₃N₄ films 5 having the same line width as those of the sidewalls.

Next, as indicated by step S8 in FIG. 7, the underlayer SiO₂ film 6 is processed by using the patterned Si₃N₄ films 5 as masks. In more detail, as illustrated in FIG. 17, the SiO₂ film 6 is processed by known dry etching processing which uses, for example, a mixed gas of a CF₄ gas and a H₂ gas to form a pattern of the SiO₂ films 6 having the same line width as those of the Si₃N₄ films 5.

Next, as indicated by step S9 in FIG. 7, the underlayer Si₃N₄ film 7 is processed by using the patterned SiO₂ films 6 as masks. In more detail, as illustrated in FIG. 18, the Si₃N₄ film 7 is processed by known dry etching processing which uses, for example, a Cl₂ gas to form a pattern of the Si₃N₄ films 7 having the same line width as those of the SiO₂ films 6.

Next, as indicated by step S10 in FIG. 7, the underlayer SiO₂ film 8 and the Si substrate 9 are processed by using the patterned SiO₂ films 6 as masks. In more detail, as illustrated in FIG. 19, the SiO₂ film 8 and the Si substrate 9 are processed by known dry etching processing which uses, for example, a Cl₂ gas or a mixed gas of a Cl₂ gas and a CFH₃ gas to form patterns of the SiO₂ films 8 and the Si substrate 9 having the same line width as those of the SiO₂ films 6. As a result, a Si line pattern or a space pattern having a line width less than a lithography resolution limitation is formed.

In the present embodiment, as illustrated in FIG. 19, on the pattern of the Si substrate 9 on which the groove 21 has been formed, the patterned SiO₂ films 6, Si₃N₄ films 7 and SiO₂ films 8 are left. The SiO₂ films 6 can secure the highest etching selectivity of Si, and are left as the masks on a surface when the groove 21 of the Si substrate 9 is processed. As described above, after the groove 21 of the Si substrate 9 is buried by an oxide film based film in the process subsequent to the substrate processing according to the present embodiment, the Si₃N₄ films 7 become stopper films in a CMP process of planarizing the surface. As described above, the object of the SiO₂ films 8 is to protect the surface of the Si substrate 9 when the Si₃N₄ films 7 are removed by heat phosphoric acid.

### (3) Substrate Processing Method of Substrate Processing Apparatus According to Present Embodiment

Next, an example of the substrate processing process of the substrate processing apparatus 20 according to the present embodiment will be described below. In this substrate processing process, above-mentioned core pattern removal process S6 is performed, and core pattern removal process S6 is performed by using the first processing unit 410 and the second processing unit 510. This substrate processing process is performed as, for example, one process of the semiconductor manufacturing process of manufacturing a semiconductor device on a substrate. In this substrate processing process, an operation of each component of the substrate processing apparatus 20 is controlled by the controller 600. S21 to S80 described below will be referred to as the substrate processing process of the substrate processing apparatus 20 according to the present embodiment.

### Default Coolant Flow Rate Controlling Process S21

In the first processing unit 410, the coolant flow rate control unit 486 controls the coolant supply unit 491, and circulates a coolant which has been adjusted to a flow rate and a temperature set in advance, in the external susceptor coolant flow path 489a, the susceptor coolant flow path 464, and the external susceptor coolant flow path 489b in a direction of an arrow 489c.

### Default Heater Temperature Adjustment Process S22

In the first processing unit 410, the heater temperature control unit 485 supplies default power set in advance, to the heater 463, and causes the heater 463 to heat the susceptor table 411 to a desired temperature. In the second processing unit 510, too, the heater temperature control unit of the second processing unit 510 performs the same control as that of the heater temperature control unit 485 of the first processing unit 410.

### Susceptor Temperature Detecting Process S23

After default coolant flow rate controlling process S21 and default heater temperature adjustment process S22, the temperature detecting unit 488 of the first processing unit 410 detects a temperature of the susceptor 459. In the second processing unit 510, too, the temperature detecting unit of the second processing unit 510 detects a temperature of the susceptor 559. Information of the detected temperature of the susceptor is input to the controller 600.

### Susceptor Temperature Determining Process S24

When the controller 600 determines that the detected temperature data (temperatures of the susceptor 459 and the susceptor 559) is within a predetermined temperature range, i.e., in case of “Yes”, the controller 600 moves to next substrate placing process S31.

When the detected temperature data is information different from the predetermined temperature range, i.e., in case of “No”, default coolant flow rate controlling process S21 and default heater temperature adjustment process S22, and subsequent susceptor temperature detecting process S23 are repeated until the temperature reaches a predetermined temperature.

S21 to S24 are preparation stages prior to processing of a wafer, and S21 to S24 will be referred to as a default process.

### First Processing Process

Next, the first processing process configured by following S31 to S40 and including first etching processing process S32 is performed.

### Wafer Placing Process S31

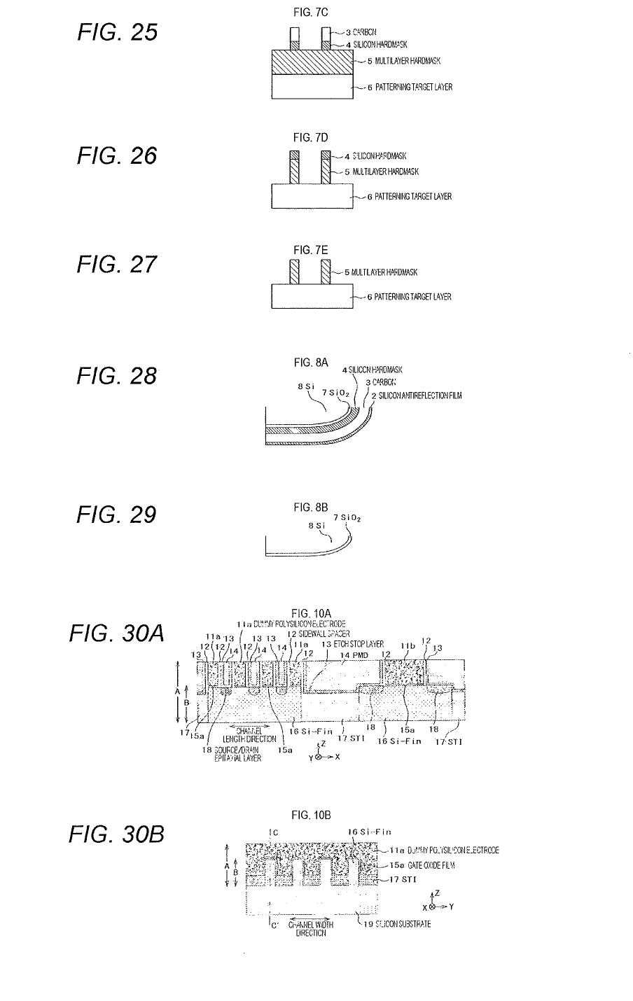

After the susceptor temperature enters the predetermined temperature range, the vacuum conveyance robot 320 conveys the wafer 60 to the processing chamber 445. More specifically, the finger 321 of the vacuum conveyance robot 320 on which the wafer 60 has been loaded enters the processing chamber 445, and the finger 321 places the wafer 60 on the lifted lifter pins 413. Subsequently, when the lifter pins 413 on which the wafer 60 has been placed are lowered, the wafer 60 is placed on the susceptor table 411. This wafer 60 has been subjected to above-mentioned step S1 to S5. At a surface side of the wafer 60, the core pattern and the sidewalls are formed as illustrated in FIG. 13. At the back side of the wafer 60, as illustrated in FIG. 9, the SiO₂ film 8, the Si₃N₄ film 7, the SiO₂ film 6, the Si₃N₄ film 5, the amorphous Si film 4, the CHM film 3 and the Si film 2 are formed. Further, in a second embodiment described below, too, at the surface side of this wafer 60, the silicon hardmasks 4 are formed on multilayer hardmasks 25 as illustrated in FIG. 26. At the back side of the wafer 60, the silicon hardmask 4 is formed on the multilayer hardmask 25, the carbon film 3 is formed on the silicon hardmask 4, and the silicon antireflection film 2 is formed on the carbon film 3.

### First Etching Processing Process S32

When the wafer 60 having been subjected to steps S1 to S5 is placed on the susceptor table 411, the wafer 60 is heated to the predetermined temperature range described below by the temperature control unit and is maintained. In this regard, the predetermined temperature range refers to a temperature range in which an etching gas can maintain a high selectivity without gaining strong energy (e.g. high frequency power) from an outside. In case of iodine heptafluoride, for example, the temperature range is 30° C. or more and 50° C. or less and is more preferably 30° C. or more and 40° C. or less. In this case, a lower limit of the temperature is determined by taking into account control performance of the temperature and the temperature which is not liquefied.

In addition, the “high selectivity” means that an etching rate of a first film (e.g. silicon film) whose main component is, for example, silicon is made higher than that of a second film which is film (a silicon oxide film, a silicon oxynitride film or a silicon nitride film) whose silicon content rate is lower than that of the first film. More precisely, the “high selectivity” means to etch the first film without etching the second film. By so doing, it is possible to etch the core pattern 4 while preventing etching of the sidewall.

Next, the second gas supply unit 483 is controlled to supply a nitrogen gas as a dilution gas to the processing chamber 445. In parallel to this supply, the first gas supply unit 482 is controlled to supply an etching gas (IF₇ gas) from the gas introduction port 433 into the processing chamber 445. The supplied etching gas hits the plate unit 484a of the shower plate 484, and is supplied to the wafer 60 in a diffused state via the hole units 484b. By diffusing the etching gas, the gas is uniformly supplied onto the wafer 60, so that it is possible to uniformly etch the plane of the wafer.

In this case, the first gas supply unit 482 sets a flow rate of an IF₇ gas from the first gas source 482b, to a predetermined gas flow rate between 0.5 slm and 4 slm and, more preferably, to 1 slm. A flow rate of a N₂ gas (carrier gas) from the inert gas source 482f is set to a predetermined gas flow rate between 0 slm and 1 slm. A flow rate of the N₂ gas (dilution gas) from the second gas supply unit 483 is set to a predetermined gas flow rate between 0.1 slm and 3 slm and, more preferably, to 0.5 slm. A pressure in the processing chamber 445 is set to, for example, a predetermined pressure between 100 Pa and 1000 Pa and, more preferably, between 200 Pa and 500 Pa.

By the way, the above-mentioned etching gas has a property of generating heat when the etching gas contacts a silicon film and makes a reaction. It is considered that the generated reaction heat conducts to a metal film or a substrate due to thermal conduction, and, as a result, deterioration of characteristics of the metal film and a warp of the substrate occur. Further, it is also considered that the temperature of the wafer 60 goes out of the predetermined temperature range, and the etching gas loses a high selectivity.

A concentration of an etching gas and an etching rate have a proportional relationship and, further, the etching rate and a reaction heat amount have a proportional relationship. Therefore, when the concentration of the etching gas is increased and the etching rate is raised, the above-mentioned phenomenon becomes more remarkable.

Hence, a dilution gas is supplied to the processing chamber 445 along with the etching gas to decrease the concentration of the etching gas and prevent an excessive rise in the temperature due to the reaction heat. A dilution gas supply amount is preferably made larger than, for example, an etching gas supply amount.

In addition, supply of the dilution gas and the etching gas is started substantially simultaneously, yet is not limited to this. More preferably, after the dilution gas is supplied, the etching gas is supplied. In this case, the etching gas is preferably a gas which includes heavier substances such as halogen than the dilution gas and enables etching without obtaining strong energy from an outside. If the gas including halogen, and the dilution gas are simultaneously supplied, the gas including halogen reaches a substrate earlier than the dilution gas. That is, the etching gas of a higher concentration reaches the substrate earlier than the dilution gas. In this case, it is considered that etching is performed rapidly, and therefore the temperature rapidly rises and a high etching selectivity is lost. To prevent these rise and loss, it is desirable to supply the etching gas after supplying the dilution gas.

More desirably, the etching gas is supplied after a pressure in a processing chamber stabilizes in a state where the processing chamber is filled with a dilution gas atmosphere. This is effective in case where a dilution gas amount is sufficiently larger than an etching gas amount and is effective for a process or the like of controlling an etching depth. Etching is performed in a stable pressure state, so that it is possible to stabilize the etching rate. As a result, it is easy to control the etching depth.

Further, in the present embodiment, while the etching gas contacts the wafer, the wafer 60 is maintained within a desired temperature range to achieve one of maintenance of a high etching rate, prevention of characteristics deterioration of a film which consists the substrate, prevention of a warp of the substrate, and maintenance of a high etching selectivity or a combination of these.

### Wafer Temperature Detecting Process S33

As described above, while the etching gas contacts the wafer 60, the wafer 60 is heated by reaction heat. In this regard, the temperature detecting unit 488 detects the temperature of the wafer 60 heated by the reaction heat.

### Wafer Temperature Determining Process S34

Temperature data detected in wafer temperature detecting process S33 is input to the controller 600. The controller 600 determines whether or not the temperature data is within a range of a predetermined temperature. When the temperature data is within the predetermined temperature range, i.e., in case of “Yes”, the flow moves to a heater/coolant control-maintaining process in S37. When the detected temperature data is not within the predetermined temperature range, i.e., in case of “No”, the flow moves to processes (S35 and S36) of adjusting a temperature control unit such that a wafer temperature is a desired temperature.

### Heater Temperature Adjustment Process S35

When it is determined in wafer temperature determining process S34 that the wafer temperature is not within the desired temperature range, the heater temperature control unit 485 controls a power supply amount for the heater 463. In case of the present embodiment, the reaction heat raises the temperature of the wafer 60 to a temperature higher than an upper limit of the predetermined temperature range. Therefore, the temperature of the heater 463 is lowered to maintain the temperature of the wafer 60 at a predetermined temperature.

### Coolant Flow Rate Adjustment Process S36

When it is determined that the wafer temperature is not within the predetermined temperature range, the coolant flow rate control unit 486 controls a flow rate and a temperature of the coolant. In case of the present embodiment, the reaction heat raises the temperature of the wafer 60 to a temperature higher than an upper limit of the predetermined temperature range. Therefore, the flow rate of the coolant is increased or a temperature of the coolant is lowered to maintain the temperature of the wafer 60 at a predetermined temperature. By so doing, efficiency to cool the wafer 60 is enhanced.

The heater 463 and the coolant flow rate are controlled in heater temperature adjustment process S35 and coolant flow rate adjustment process S36 to adjust the wafer 60 to a predetermined temperature range. After the adjustment, the flow moves to wafer temperature detecting process S33. Thus, until the wafer 60 enters the predetermined temperature range, S33 to S36 are repeated.

In addition, in the present embodiment, coolant flow rate adjustment process S36 is performed after heater temperature adjustment process S35. However, the present embodiment is not limited to this. For example, after wafer temperature determining process S34, coolant flow rate adjustment process S36 may be performed and then heater temperature adjustment process S35 may be performed. Alternatively, after wafer temperature determining process S34, coolant flow rate adjustment process S36 and heater temperature adjustment process S35 may be performed in parallel.

Further, in the present embodiment, to lower the temperature of the wafer 60, control is performed to lower the temperature of the heater 463 and increase the coolant flow rate. However, the present embodiment is not limited to this, and the heater 463 and the coolant flow rate may be controlled collaboratively to perform control to eventually lower the temperature of the wafer 60 to the predetermined temperature range.

Further, when the temperature of the wafer 60 is lower than a lower limit of the predetermined temperature range, the heater 463 and the coolant flow rate may be collaboratively controlled to perform control to eventually raise the temperature of the wafer 60.

### Heater/Coolant Control-Maintaining Process S37

When it is determined in wafer temperature determining process S34 that the wafer temperature is within the predetermined temperature range, controlling the heater and controlling the coolant flow rate are maintained, and the temperature of the wafer 60 is maintained to maintain the wafer temperature.

### Processing Time Determining Process S38

Whether or not a predetermined period of time of an etching processing time in S32 has passed, i.e., whether or not the first etching processing with respect to the wafer 60 has been terminated is determined. In case where it is determined that the predetermined period of time has passed, i.e., in case of “Yes”, the flow moves to S39. In case where it is determined that the predetermined period of time has not passed, i.e., in case of “No”, the flow returns to S32 to continue the etching processing.

At a stage at which the first etching processing has been terminated, the entire Si film 4 of the core pattern is removed at the surface side of the wafer 60, and the Si film 2 is removed at the back side of the wafer 60 by the first etching processing. In addition, it is also possible to remove at least part of the Si film 4 of the core pattern in the first etching processing, and remove the rest of the Si film 4 of the core pattern in the second etching processing. Further, in the second embodiment described later, too, the entire silicon hardmask 4 is removed at the surface side of the wafer 60, and the silicon antireflection film 2 is removed at the back side of the wafer 60 by the first etching processing. In addition, it is also possible to remove at least part of the silicon hardmask 4 in the first etching processing, and remove the rest of the silicon hardmask 4 in the third etching processing.

### Gas Supply Stop Process S39

When it is determined in processing time determining process S38 that a predetermined period of time has passed, the first gas supply unit 482 is controlled to stop supplying an etching gas. A purge gas supply system of the first gas supply unit 482 is controlled to exhaust a remaining gas of the gas supply pipe 482a, and the second gas supply unit 483 is controlled to supply an inert gas into the processing chamber 445 and exhaust the atmosphere in the processing chamber 445 such that the etching gas does not remain in the processing chamber 445 after supply of the etching gas is stopped. Thus, the atmosphere in the processing chamber 445 is substituted with an inert gas.

### Wafer Unloading Process S40

After the atmosphere in the processing chamber 445 is substituted with the inert gas, the vacuum conveyance robot 320 unloads the wafer 60 from the processing chamber 445 to the transfer module 310 in a reverse sequence of placing the wafer 60.

### Second Processing Process

Next, the second processing process configured by following S51 to S59 and including second etching processing process S52 is performed.

### Wafer Placing Process S51

Subsequent to wafer unloading process S40, the vacuum conveyance robot 320 conveys the wafer 60 to the processing chamber 545 of the second processing unit 510. More specifically, the finger 321 on which the wafer 60 has been loaded enters the processing chamber 545, and the finger 321 places the wafer 60 on the lifted lifter pins 513. When the lifter pins 513 on which the wafer 60 has been placed are lowered, the wafer 60 is placed on the susceptor table 511.

### Second Etching Processing Process S52

When the wafer 60 is placed on the susceptor table 511, the wafer 60 is heated to the predetermined temperature range by the temperature control unit and is maintained. In this regard, the predetermined temperature range is 0° C. or more and 200° C. or less.

Next, the third gas supply unit 582 is controlled to supply an O₂ gas serving as a process gas from the gas introduction port 533 into the processing chamber 545. The supplied O₂ gas is introduced into the plasma generating chamber 530 in a state where the O₂ gas is diffused via the baffle plate 584. Further, the O₂ gas activated by the plasma generating chamber 530 is supplied to the wafer 60 on the susceptor table 511. An O₂ gas flow rate from the third gas supply unit 582 is set to, for example, 0.25 slm. A pressure in the processing chamber 545 is set to, for example, 200 Pa.

### Wafer Temperature Detecting Process S53

The temperature detecting unit disposed in the susceptor 599 detects a temperature of the wafer 60.

### Wafer Temperature Determining Process S54

Temperature data detected in wafer temperature detecting process S53 is input to the controller 600. The controller 600 determines whether or not the temperature data is within a range of a predetermined temperature. When the temperature data is within the predetermined temperature range, i.e., in case of “Yes”, the flow moves to a heater control-maintaining process in S56. When the detected temperature data is not within the predetermined temperature range, i.e., in case of “No”, the flow moves to a heater temperature adjustment process S55 such that a wafer temperature is a desired temperature.

### Heater Temperature Adjustment Process S55

In heater temperature adjustment process S55, the controller 600 controls a power supply amount to the heater 563 such that the wafer 60 enters the predetermined temperature range. Thus, until the wafer 60 enters the predetermined temperature range, S53 to S55 are repeated.

### Heater Control-Maintaining Process S56

When it is determined in wafer temperature determining process S54 that the wafer temperature is within the predetermined temperature range, controlling the temperature of the heater 563 is maintained and the temperature of the wafer 60 is maintained to maintain the wafer temperature.

### Processing Time Determining Process S57

Whether or not a predetermined period of time of an etching processing time in S52 has passed, i.e., whether or not the etching processing with respect to the wafer 60 has been terminated is determined. In case where it is determined that the predetermined period of time has passed, i.e., in case of “Yes”, the flow moves to S58. In case where it is determined that the predetermined period of time has not passed, i.e., in case of “No”, the flow returns to S52 to continue the etching processing. At a stage at which the etching processing in S52 has been terminated, the CHM film 3 is removed at the back side of the wafer 60 by the etching processing. Meanwhile, the O₂ gas supplied in S52 is supplied under processing conditions that the surface of the underlayer Si₃N₄ film 5 at the surface side of the wafer 60 is not oxidized, and a reaction does not occur on the surface of the Si₃N₄ film 5. Meanwhile, the Si film 10 serving as the sidewall is hardened (hardening) by this activated O₂ gas in some cases. Further, in the second embodiment described later, too, at a stage at which the etching processing in S52 has been terminated, the carbon film 3 is removed at the back side of the wafer 60 by the etching processing. Meanwhile, the O₂ gas supplied in S52 is supplied under processing conditions that the surface of the underlayer multilayer hardmask 5 at the surface side of the wafer 60 is not oxidized, and a reaction does not occur on the surface of the multilayer hardmask 5.

### Gas Supply Stop Process S58

When it is determined in processing time determining process S57 that a predetermined period of time has passed, the third gas supply unit 582 is controlled to stop supplying a process gas and stop supplying power from the high frequency power supply 525 to the resonance coil 521. The third gas supply unit 582 is controlled to supply an inert gas from the inert gas source 582f into the processing chamber 545, and exhausts the atmosphere in the processing chamber 545 such that the process gas does not remain in the processing chamber 545 after the supply of the process gas is stopped. Thus, the atmosphere in the processing chamber 545 is substituted with an inert gas.

### Wafer Unloading Process S59

After the atmosphere in the processing chamber 545 is substituted with the inert gas, the vacuum conveyance robot 320 unloads the wafer 60 from the processing chamber 545 to the transfer module 310 in a reverse sequence of placing the wafer 60.

### Third Processing Process

Next, the third processing process configured by following S71 to S80 and including third etching processing process S72 is performed.

### Wafer Placing Process S71

Subsequent to wafer unloading process S59, the vacuum conveyance robot 320 conveys the wafer 60 to the processing chamber 445. Further, similar to the first processing process, the wafer 60 is placed on the susceptor table 411.

### Third Etching Processing Process S72

When the wafer 60 is placed on the susceptor table 411, the wafer 60 is heated to the predetermined temperature range by the temperature control unit and is maintained. In this regard, the predetermined temperature range is the same as the temperature range upon the above-mentioned first etching processing.

Next, the second gas supply unit 483 is controlled to supply a nitrogen gas as a dilution gas to the processing chamber 445. In parallel to this supply, the first gas supply unit 482 is controlled to supply an IF₇ gas serving as an etching gas from the gas introduction port 433 into the processing chamber 445. The supplied etching gas is supplied to the wafer 60 in a diffused state via the shower plate 484.

A flow rate of the IF₇ gas from the first gas source 482b of the first gas supply unit 482, a flow rate of a N₂ gas (carrier gas) from the inert gas source 482f, a flow rate of the N₂ gas (dilution gas) from the second gas supply unit 483, and a pressure in the processing chamber 445 are set likewise in above-mentioned first etching processing process S32.

### Wafer Temperature Detecting Process S73

The temperature detecting unit 488 detects the temperature of the wafer 60.

### Wafer Temperature Determining Process S74

Temperature data detected in wafer temperature detecting process S33 is input to the controller 600. The controller 600 determines whether or not the temperature data is within a range of a predetermined temperature. When the temperature data is within the predetermined temperature range, i.e., in case of “Yes”, the flow moves to a heater/coolant control-maintaining process in S77. When the detected temperature data is not within the predetermined temperature range, i.e., in case of “No”, the flow moves to processes (S75 and S76) of adjusting a temperature control unit such that a wafer temperature is a desired temperature.

### Heater Temperature Adjustment Process S75

When it is determined in wafer temperature determining process S74 that the wafer temperature is not within the predetermined temperature range, the heater temperature control unit 485 controls a power supply amount for the heater 463 in the same way as that upon the above-mentioned first processing.

### Coolant Flow Rate Adjustment Process S76

When it is determined that the wafer temperature is not within the predetermined temperature range, the coolant flow rate control unit 486 controls a flow rate and a temperature of the coolant in the same way as that upon the above-mentioned first processing.

The heater 463 and the coolant flow rate are controlled in heater temperature adjustment process S75 and coolant flow rate adjustment process S76 to adjust the wafer 60 to a predetermined temperature range. After the adjustment, the flow moves to wafer temperature detecting process S73. Thus, until the wafer 60 enters the predetermined temperature range, S73 to S76 are repeated.

### Heater/Coolant Control-Maintaining Process S77

When it is determined in wafer temperature determining process S74 that the wafer temperature is within the predetermined temperature range, both of the controlling the heater and the controlling the coolant flow rate are maintained and the temperature of the wafer 60 is maintained, to maintain the wafer temperature.

### Processing Time Determining Process S78

Whether or not a predetermined period of time of a third etching processing time in S72 has passed is determined. In case where it is determined that the predetermined period of time has passed, i.e., in case of “Yes”, the flow moves to S79. In case where it is determined that the predetermined period of time has not passed, i.e., in case of “No”, the flow returns to S72 to continue the etching processing. At a stage at which the third etching processing has been terminated, the Si film 4 of the core pattern is removed at the surface side of the wafer 60, and the amorphous Si film 4 is removed at the back side of the wafer 60 by the third etching processing.

### Gas Supply Stop Process S79

When it is determined in processing time determining process S78 that a predetermined period of time has passed, it is determined that the etching processing of the wafer 60 has been terminated, and the first gas supply unit 482 is controlled to stop supplying an etching gas. A purge gas supply system of the first gas supply unit 482 is controlled to exhaust a remaining gas of the gas supply pipe 482a such that the etching gas does not remain in the processing chamber 445 after supply of the etching gas is stopped. The second gas supply unit 483 is controlled to supply an inert gas into the processing chamber 445 and exhaust the atmosphere in the processing chamber 445. Thus, the atmosphere in the processing chamber 445 is substituted with the inert gas.

Wafer Unloading Process S80

After the atmosphere in the processing chamber 445 is substituted with the inert gas, the vacuum conveyance robot 320 unloads the wafer 60 in the processing chamber 445 to the transfer module 310 in a reverse sequence of placing the wafer 60. Subsequently, the vacuum conveyance robot 320 conveys the wafer 60 in the transfer module 310, to the buffer unit 210 of the load lock chamber unit 200. Next, the air conveyance robot 130 conveys the wafer 60 in the buffer unit 210 to the FOUP 110 on the load port 120.

### Effects According to Present Embodiment

Effects provided by the above-mentioned embodiment include at least one or more effects of the following effects (1) to (4). (1) In the core pattern removal process, it is possible to etch a Si core pattern at a high selectivity with respect to a silicon oxide film (SiO₂ film) and a silicon nitride film (Si₃N₄ film) which are films other than the Si core pattern. More specifically, it is possible to highly selectively etch the Si core pattern 4 with respect to the SiO₂ film 10 serving as the sidewall film and the underlayer Si₃N₄ film 5. (2) In the core pattern removal process, by performing the first etching processing which does not use plasma, the second etching processing which uses plasma, and the third etching processing which does not use plasma in order, it is possible to remove the Si core pattern, the CHM film and the Si antireflection film formed at the substrate back side. Consequently, it is possible to prevent production of particles caused by the Si core pattern film, the CHM film and the Si antireflection film formed at the substrate back side. (3) A substrate temperature in the first and third etching processing is 30 to 50° C., so that it is possible to highly selectively etch the Si core pattern 4. Further, the substrate temperature is preferably 40 to 50° C., so that it is possible to more highly selectively etch the Si core pattern 4. (4) According to the second etching processing which uses plasma, the processing condition that a silicon nitride film (Si₃N₄ film) is not oxidized is applied, so that it is possible to remove only the CHM film 3 on the substrate back surface. A condition that a silicon oxide film (SiO₂ film) is hardened is preferable. In this case, the SiO₂ film 10 serving as the sidewall film has quality improved by plasma, and has an improved dry etching resistance.

### Second Embodiment

Next, an example of a substrate processing process of performing a substrate processing method according to the present embodiment (second embodiment) will be described below with reference to FIGS. 23 to 29. This substrate processing process is performed as a process of forming a fine pattern and one process of the semiconductor device manufacturing method. FIGS. 23 to 27 illustrate views for explaining fine pattern-forming processing according to the second embodiment of the present disclosure, and illustrate views illustrating a process of making a fine pattern by using, for example, ArF immersion lithography and dry etching. Further, the process (silicon hardmask removal process) in FIG. 27 is a characteristic part of the present disclosure, and is an example of a process of performing gas etching having a high selectivity with respect to silicon, i.e., having a high etching rate. In addition, a substrate processing apparatus 20 according to the present embodiment performs at least the process in FIG. 27. The substrate processing method according to the present embodiment is the same as that of the first embodiment. Hence, explanation of the second embodiment with reference to FIGS. 9A to 9C will be skipped.

FIG. 23 illustrates a view illustrating that, at a substrate surface side, a carbon film 3 is formed on a silicon hardmask 4, a silicon antireflection film 2 is formed on the carbon film 3, a resist 1 is applied onto the silicon antireflection film 2, and the resist 1 is patterned by using the ArF immersion lithography and the dry etching and then is subjected to slimming processing. In more detail, as illustrated in FIG. 23, at a surface side of a silicon substrate, a patterning target layer 26, a multilayer hardmask 25, the silicon hardmask 4 serving as an etching target film, the carbon film 3 and the silicon antireflection film 2 are stacked in this order and formed. Further, a photoresist is applied to this stacked film, is exposed by a lithography technique and then is developed to form the resist 1 pattern processed to a predetermined line width.

When the silicon hardmask 4, the carbon film 3 and the silicon antireflection film 2 are stacked at the surface side of the silicon substrate, the silicon hardmask 4, the carbon film 3 and the silicon antireflection film 2 are stacked in this order at a back side of the silicon substrate, too. Even when the back side of the silicon substrate is supported by a flat susceptor, the above-mentioned stacked films 4 to 2 are formed at least a surrounding section of the back side of the silicon substrate. The stacked films 4 to 2 are soft films which are relatively easily delaminated. Therefore, there is an undesirable concern that the stacked films 4 to 2 are delaminated and produce particles in a process performed after the substrate processing process. Therefore, it is necessary to remove the stacked films 4 to 2.

The silicon hardmask 4 has a film thickness of about 40 to 60 nm, and is formed on the multilayer hardmask 25 at, for example, a temperature of 400 to 550° C. by a CVD method. The carbon film 3 is, for example, a CVD carbon film (a carbon-containing film formed by the CVD method) or a spin-on carbon film, has a film thickness of about 100 to 500 nm and is formed on the silicon hardmask 4 at, for example, a temperature of 200 to 550° C. by the CVD method. The silicon antireflection film 2 has a film thickness of about 2 to 10 nm, and is formed on the carbon film 3 at, for example, a temperature of 400 to 550° C. by the CVD method. The silicon antireflection film 2 functions as an antireflection film when exposure is performed by the lithography technique.

In this example, to process the patterning target film 26, for example, the silicon hardmask 4 is used. Hence, the silicon hardmask 4 is formed under the carbon film 3. The multilayer hardmask 25 consisted by a plurality of layers of hardmasks is formed under the silicon hardmask 4. For the multilayer hardmask 25, for example, a SiO₂ film, a Si₃N₄ film, a TiN film and the like are used. Silicon content rates of the silicon hardmask 4 and the silicon antireflection film 2 are higher than silicon content rates of the carbon film 3 and the multilayer hardmask 25.

In addition, a film thickness of the silicon antireflection film 2 may be the same as a film thickness of the silicon hardmask 4 (e.g. about 40 nm). Thus, when the resist 1 is patterned, it is possible to prevent overetching. Further, a film thickness of the carbon film 3 may be the same as a film thickness of the multilayer hardmask 25 (e.g. about 500 nm). Thus, when the silicon hardmask 4 is patterned, it is possible to prevent overetching.

FIG. 24 illustrates a state after the silicon antireflection film 2 and the carbon film 3 are dry-etched by using the patterned resist 1 as a mask. In this case, by using the patterned resist 1 as a mask, the underlayer silicon antireflection film 2 is processed by known dry etching processing which uses, for example, a Cl₂ gas, and then the carbon film 3 is processed by known dry etching processing which uses, for example, an O₂ gas. Subsequently, the resist 1 is removed by the known asking processing which uses, for example, the O₂ gas.

In addition, etching performed on the silicon antireflection film 2 at the surface side of the silicon substrate is anisotropic etching performed on the surface of the silicon substrate in a vertical direction. Therefore, the silicon antireflection film 2 at the back side of the silicon substrate is not removed.

Next, the silicon film 4 serving as the hardmask is patterned as illustrated in FIG. 25. In more detail, by using the pattern of the carbon film 3 as a mask, the silicon hardmask 4 serving as the underlayer film of the carbon film 3 is processed by known dry etching processing which uses, for example, a Cl₂ gas or a CF₂Cl₂ gas. Subsequently, the carbon film 3 is removed by the known dry etching processing which uses, for example, an O₂ gas. In this case, the silicon antireflection film 2 at the back side of the silicon substrate is not removed, and therefore the carbon film 3 the back side of the silicon substrate is not removed.

In more detail, as illustrated in FIG. 26, by using the pattern of the silicon hardmasks 4 as a mask, the multilayer hardmask 25 serving as the underlayer film of the silicon hardmask 4 is processed by known dry etching processing which uses, for example, a Cl₂ gas or a CF₂Cl₂ gas.

Next, as illustrated in FIG. 27, the silicon hardmask 4 is removed by dry etching. In a process of removing this silicon hardmask 4, completely removing only the silicon film 4 without scraping the multilayer hardmask 25 is demanded. A reason for this demand is that a shape of the multilayer hardmask 25 influences a final process for the patterning target layer 26. In this process, gas etching which uses a gas having a high etching rate with respect to silicon (i.e., silicon hardmask 4) is performed, and only the silicon film (i.e., the silicon hardmask 4) is removed without etching films (i.e., multilayer hardmask 25) other than silicon.

In the present embodiment, a processing unit 410 illustrated in FIG. 3 uses an IF₇ gas as an etching gas for processing of removing the silicon hardmask 4. In addition, a processing condition different from those of the first embodiment is only a duration of time to supply the IF₇ gas, and other processing conditions such as a substrate temperature, a pressure in a processing chamber, an IF₇ gas flow rate and a carrier gas flow rate are the same conditions, respectively, and therefore will not be described. Further, the duration of time to supply the IF₇ gas needs to be a duration of time to remove the silicon hardmask 4. If an etching time becomes long more or less, the IF₇ gas has a unique selectivity and there is no worry that over etching is performed. Therefore, the etching time is optionally determined according to a film thickness of the silicon hardmask 4 that is an etching target film.

When the IF₇ gas is used, it is possible to improve an etching rate of silicon by performing etching at 50° C. or less, and secure a high selectivity with respect to the underlayer multilayer hardmask 25. Further, at 40° C. or less, it is possible to secure a much higher selectivity. Furthermore, when the pressure is 100 Pa to 1000 Pa, it is possible to secure a high selectivity, and, when the pressure is 200 to 500 Pa, it is possible to secure a much higher selectivity. Still further, when the flow rate is 0.5 slm to 4 slm, it is possible to secure a high selectivity and, when the flow rate is 0.5 slm to 1 slm, it is possible to secure a much higher selectivity.

By highly selectively etching the silicon hardmask 4 at the substrate surface side with respect to the multilayer hardmask 25 consisted by a SiO₂ film, a Si₃N₄ film, a TiN film and the like, i.e., the multilayer hardmask 25 having a lower silicon content rate than that of the silicon film, it is possible to obtain the state in FIG. 27. That is, it is possible to highly selectively etch and remove the silicon hardmask 4 at the substrate surface side while preventing etching of the multilayer hardmask 25. Further, in this case, by performing etching at a temperature of 50° C. or less, it is possible to prevent the multilayer hardmask 25 formed at a low temperature of 100° C. or less or 400° C. or less and consisted by a SiO₂ film and the like from changing due to a temperature.

Preferably, in processing of removing the silicon hardmask 4 at the substrate surface side, (a) first etching processing which does not use plasma produced by an IF₇ gas, (b) second etching processing which uses plasma produced by, for example, an O₂ gas and (c) third etching processing which does not use plasma produced by the IF₇ gas are performed in this order similar to the first embodiment.

In the present embodiment, too, (a) the first etching processing which uses the IF₇ gas is performed by using the processing unit 410 illustrated in FIG. 3 to remove the silicon hardmask 4 at the surface side of the silicon substrate and the silicon antireflection film 2 at the back side. Next, (b) the second etching processing which uses the O₂ gas is performed by using a processing unit 510 to remove the carbon film 3 at the back side of the silicon substrate. Subsequently, (c) the third etching processing which uses the IF₇ gas is performed by using the processing unit 410 to remove the silicon hardmasks 4 at the surface side and the back side of the silicon substrate. That is, in the first and second embodiments, films deposited at the back side of the silicon substrate are the same as the silicon antireflection film 2, the carbon film 3 and the silicon hardmask 4. Therefore, the processing conditions of (a) and (c) are the same as the above-mentioned processing conditions C1 described in the first embodiment.

By so doing, similar to the first embodiment, in parallel to removal of the silicon hardmask 4 at the substrate surface side, it is possible to remove a stacked film of the silicon antireflection film 2, the carbon film 3 and the silicon hardmask 4 at the substrate back side. At least, it is possible to remove the silicon hardmask 4 deposited at the substrate back side upon formation of the silicon hardmask 4 at the substrate surface side. In more detail, in parallel to removal of the silicon hardmask 4 at the substrate surface side, a film formed of the same material as that of the silicon antireflection film 2 at the substrate back side is removed by performing the processing (a), a film formed of the same material as that of the carbon film 3 at the substrate back side is removed by performing the processing (b), and a film formed of the same material as that of the silicon hardmask 4 at the substrate back side by performing the processing (c).

In addition, as to the films such as the silicon antireflection film 2, the carbon film 3 and the silicon hardmask 4 deposited at the back side of the silicon substrate, similar to the first embodiment, the carbon film 3 is susceptible to a high temperature annealing process, an oxidation process and an O₂ asher process performed in a subsequent process of the substrate processing process. Therefore, the carbon film 3 needs to be removed to suppress particles caused by delamination of a film at the substrate back side in a subsequent process. The silicon antireflection film 2 and the silicon hardmask 4 are conductive films and causes problem of particles, and therefore need to be removed.

FIG. 28 illustrates a view illustrating a state before the silicon antireflection film 2, the carbon film 3 and the silicon hardmask 4 at the substrate back side are removed according to the second embodiment of the present disclosure. In an example in FIG. 28, at the substrate back side and on a silicon substrate 28, a SiO₂ film 27 is formed by thermal oxidation or the like. There is also a case where a multilayer hardmask is formed on the silicon substrate 28 (the example in FIG. 23). However, FIG. 28 illustrates a case where the SiO₂ film 27 is formed instead of the multilayer hardmask.

FIG. 29 illustrates a view illustrating a state after the silicon antireflection film 2, the carbon film 3 and the silicon hardmask 4 at the substrate back side are removed according to the second embodiment of the present disclosure. Thus, simultaneously, it is possible to remove the silicon hardmask 4 at a wafer surface side, and remove the stacked film of the silicon film (silicon hardmask 4), the carbon film and the silicon film (silicon antireflection film 2) at a wafer back side.

Effects provided by the above-mentioned second embodiment include at least one or more effects of the following effects (1) to (4). (1) In a silicon hardmask removal process, it is possible to etch the silicon hardmask 4 at a high selectivity with respect to the multilayer hardmask 25 having a lower silicon content rate than that of the silicon hardmask. (2) In the silicon hardmask removal process, by performing the first etching processing, the second etching processing, and the third etching processing in order, it is possible to remove the silicon hardmask film 4, the carbon film 3 and the silicon antireflection film 2 formed at the substrate back side. (3) A substrate temperature in the first and third etching processing is 30 to 50° C., so that it is possible to highly selectively etch the silicon hardmask 4 serving as a Si etching target film. Further, the substrate temperature is preferably 40 to 50° C., so that it is possible to more highly selectively etch the silicon hardmask 4. (4) According to the second etching processing which uses plasma, the processing condition that a silicon nitride film (Si₃N₄ film) is not oxidized is applied, so that it is possible to remove only the carbon film 3 on the substrate back surface. A condition that a silicon oxide film (SiO₂ film) is hardened is preferable.

Further, in the second embodiment, a second processing unit which performs plasma processing is configured to include a plasma generating chamber. However, the second embodiment is not limited to this, and the second processing unit may also be configured to perform remote plasma type etching processing which does not bring plasma in the processing chamber, and etching processing which does not use plasma such as etching processing which uses an O₃ gas (ozone gas).

Further, the etching processing which does not use plasma can also be performed by a first processing unit, too, and, in this case, the second processing unit is unnecessary. In this case, the IF₇ gas is introduced into the processing chamber to perform etching processing which uses the IF₇ gas and then substitute the IF₇ gas with an inert gas in the processing chamber. Subsequently, an O₃ gas is introduced into the processing chamber to perform etching processing which uses the O₃ gas and then substitute the O₃ gas with an inert gas in the processing chamber. Subsequently, the etching processing which uses the IF₇ gas is performed. Further, the first embodiment can be expected to provide an effect of improving quality of a SiO₂ film serving as a sidewall film by using the O₃ gas.

### Third Embodiment

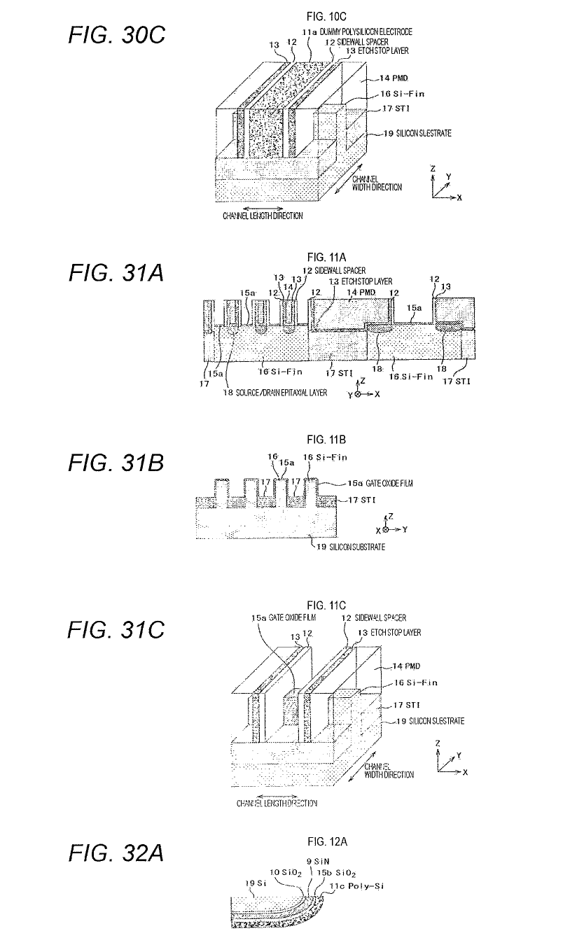

A substrate processing method according to the third embodiment will be described with reference to FIGS. 30A to 32B. FIG. 30A illustrates a cross-sectional view of a Fin-FET transistor in a channel length direction before etching processing according to the third embodiment of the present disclosure, and illustrates an example of a state of just before dummy polysilicon gate electrodes 11a and 11b are removed in a gate last process. After the dummy polysilicon gate electrodes 11a and 11b are removed, a metal gate electrode is formed. The etching processing according to the third embodiment is performed by using an IF₇ gas similar to, for example, the first embodiment and the second embodiment under the same processing conditions C1 as those of the first embodiment and the second embodiment in a processing unit 410 illustrated in FIG. 3.

FIG. 30B illustrates a cross-sectional view of the Fin-FET transistor in a channel width direction before the etching processing according to the third embodiment of the present disclosure. Ranges A and B in FIG. 30B correspond to ranges A and B in FIG. 30A, respectively. FIG. 30A is a C-C′ cross-sectional view of FIG. 30B. FIG. 30C illustrates a three-dimensional schematic view of the Fin-FET transistor before the etching processing according to the third embodiment of the present disclosure.

FIG. 30A illustrates the dummy polysilicon electrodes 11a and 11b. In the channel length direction (X direction in FIG. 30A) of a gate electrode, a length of each dummy polysilicon electrode 11a is about 20 nm, and a length of the dummy polysilicon electrode 11b is about 150 nm. Sidewall spacers 12 are formed to support sidewalls of the dummy polysilicon electrodes 11a and 11b. There are also provided etching stop layers 13, PMDs (Pre Metal Dielectric) 14, gate oxide films 15a, Si-Fins 16, STIs (Shallow Trench Isolation) 17, source/drain epitaxial layers 18 and a silicon substrate 19.

Thus, at a substrate surface side and in groove sections in which the gate oxide films 15a are formed at bottom sections and in which the gate electrode is buried, the dummy polysilicon gate electrodes 11a and 11b (polysilicon films) serving as silicon films are filled and formed. Each groove section is a step section and a concave portion. A plurality of groove sections are provided in the channel length direction, and channel length direction lengths of a plurality of groove sections are different from each other.

For each gate oxide film 15a which is an underlayer oxide film of the dummy polysilicon electrodes 11a and 11b, for example, a SiO₂ film, a HfO₂ film, an Al₂O₃ film or the like is used. For each sidewall spacer 12, a SiO₂ film, a Si₃N₄ film, a SiCN film, a SiOCN film, a SiOC film or the like is used. Silicon content rates of the dummy polysilicon electrodes 11a and 11b are higher than silicon content rates of each gate oxide film 15a and each sidewall spacer 12.

In the example in FIG. 30A, there are the thin dummy polysilicon gate electrodes 11a whose gate lengths are 20 nm or less, and the thick dummy polysilicon gate electrode 11b whose gate length is 150 nm or more, and both of the polysilicons need to be removed simultaneously. Generally, an etching rate differs according to the amount of an etching target film. To simultaneously etch patterns of different widths, a high selectivity is required, which makes it possible to highly selectively etch only polysilicon of an underlayer film and a sidewall film such that the patterns of the narrow widths are not overetched.

Further, polysilicon at a bottom of a Fin step section needs to be sufficiently etched and removed in the Fin-FET of the 3D structure. That is, it is necessary to sufficiently remove the polysilicon film filled in a plurality of groove sections covered by the gate oxide films 15a. An etching selectivity for highly selectively etching only polysilicon with respect to the underlayer oxide films 15a and the sidewall spacers 12 such that, while each Fin step section is etched to the bottom, a Fin upper section is not overetched, i.e., each underlayer oxide film 15a and each sidewall spacer 12 at the Fin upper section are not etched.

FIG. 31A illustrates a cross-sectional view of a Fin-FET transistor in the channel length direction after etching processing according to the third embodiment of the present disclosure, and illustrates a state where the dummy polysilicon electrodes 11a and 11b have been removed in FIG. 30A. The etching processing is performed by, for example, using an IF₇ gas similar to the first embodiment under the same processing conditions C1 as those of the first embodiment and the second embodiment in a processing unit 410 illustrated in FIG. 3.

FIG. 31B illustrates a cross-sectional view of a Fin-FET transistor in the channel width direction after the etching processing according to the third embodiment of the present disclosure, and illustrates a state where the dummy polysilicon electrode 11a has been removed in FIG. 30B. FIG. 31C illustrates a three-dimensional schematic view of the Fin-FET transistor after the etching processing according to the third embodiment of the present disclosure.

Thus, by gas-etching only silicon at a high etching rate, it is possible to suppress an etching residue of polysilicon, and remove only the dummy polysilicon gate electrodes 11a and 11b in a state where shapes of the underlayer oxide films 15a and the sidewall films 12 serving the sidewalls are kept.

Further, after the dummy polysilicon gate electrodes 11a and 11b are removed, a metal-containing film is filled in a plurality of groove sections by known film forming processing to make a metal gate.

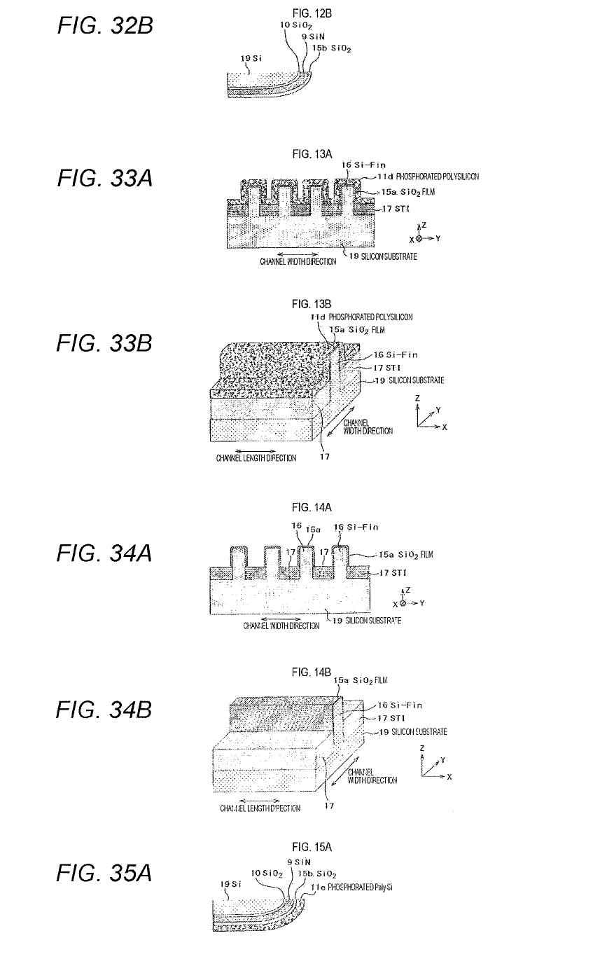

FIG. 32A illustrates a view illustrating a state before a polysilicon film at a substrate back side is removed according to the third embodiment of the present disclosure. A polysilicon (Poly-Si) film 11c at an outermost side of the substrate back side is a polysilicon film which is simultaneously formed upon formation of the dummy polysilicon gate electrodes 11a and 11b at the substrate surface side. An oxide film 15b under the polysilicon film 11c is an oxide film (SiO₂) which is simultaneously formed upon formation of the gate oxide films 15a at the substrate surface side. Thus, the polysilicon film 11c formed of the same material as that of the polysilicon film 11a and 11b at the substrate surface side, and the oxide film 15b formed of the same material as that of each gate oxide film 15a at the substrate surface side are formed at the substrate back side. Hereinafter, the polysilicon films 11a, 11b and 11c which are etching target films will be simply referred to as the polysilicon film 11.

A SiN film 29 under the oxide film 15b, and a SiO₂ film 10 which is in contact with the silicon substrate 19 are formed at a substrate back side, too, as films formed at the substrate surface side in a general STI formation process performed at an initial stage of a CMOS process. The SiN film 29 is a film serving as a hardmask for dry-etching the silicon substrate 19 and forming the grooves in which STI is buried, and is a film serving as a stopper to planarize a buried oxide film (STI 17 in FIG. 11A) by CMP. The SiO₂ film 10 which is in contact with the silicon substrate 19 is a film which is formed at the substrate back side when the surface of the silicon substrate 19 is oxidized before the SiN film 29 is formed.

FIG. 32B illustrates a view illustrating a state after the polysilicon film at the substrate back side is removed according to the third embodiment of the present disclosure. Thus, in the third embodiment, by etching silicon by using a gas having a high etching selectivity, it is possible to simultaneously remove the polysilicons 11a and 11b at the substrate surface side and remove the polysilicon film 11c at the substrate back side.

For example, when part of a substrate back side is supported by columns of a boat as in a vertical type device, and when a polysilicon film is formed at a substrate surface side as illustrated in FIG. 32A, a film-forming gas goes around to the substrate back side and the polysilicon film is formed at the substrate back side, too, in some cases. Further, in case of a single substrate processing apparatus, too, a film-forming gas goes around to a circumferential section of the substrate back side placed on a substrate setting table, and the polysilicon film is formed at the circumferential section at the substrate back side in some cases. In such a case, according to the third embodiment, it is possible to highly selectively remove the polysilicon films formed at the substrate surface side and back side.

Effects provided by the above-mentioned third embodiment include at least one or more effects of the following effects (1) to (3). (1) In the gate last process of the Fin-FET transistor, it is possible to highly selectively remove the polysilicon films 11 formed as dummy gates, with respect to the underlayer gate oxide films 15a and the sidewall spacers 12 having lower silicon content rates than that of the polysilicon films 11. (2) Further, it is possible to highly selectively remove the polysilicon films 11 formed at both of the substrate surface side and back side. (3) A substrate temperature in etching processing is 30 to 50° C., so that it is possible to highly selectively etch the polysilicon films 11 serving as Si etching target films. Further, the substrate temperature is preferably 40 to 50° C., so that it is possible to more highly selectively etch the polysilicon films 11.

### Fourth Embodiment

Performing uniform doping by using ion injection in a silicon Fin in a Fin-FET serving as a 3D transistor is difficult since there is an area of a vertical silicon surface. Hence, a technique which uses solid phase diffusion as an alternative technique has been considered. In the third embodiment, an example of a case where solid phase diffusion is performed by using a phosphorated polysilicon film, and the phosphorated polysilicon film is removed by etching has been described.

A substrate processing method according to the fourth embodiment of the present disclosure will be described with reference to FIGS. 33A to 35B. The etching processing according to the fourth embodiment is performed by, for example, using an IF₇ gas similar to the first embodiment through the third embodiment under the same processing conditions C1 as those of the first embodiment through the third embodiment in a processing unit 410 illustrated in FIG. 3.

FIG. 33A illustrates a cross-sectional view of a Fin-FET transistor in a channel width direction before etching processing according to the fourth embodiment of the present disclosure. FIG. 33B illustrates a three-dimensional schematic view of the Fin-FET transistor after the etching processing according to the fourth embodiment of the present disclosure. A silicon film 11d includes impurities of a group III or a group V and is a phosphorated polysilicon film in the present embodiment. In FIGS. 33A and 33B, the same components as those in FIGS. 30A to 30C will be assigned the same reference numerals. Hereinafter, polysilicon films 11d and 11e which are etching target films and include impurities of the group III or the group V will be referred to simply as a polysilicon film 11.

First, as illustrated in FIGS. 33A and 33B, at a substrate surface side at which a Si-Fin structure has been formed, a silicon Fin 16 is covered with thin oxide films 15a, the phosphorated polysilicon film 11d is formed on the silicon Fin 16, and phosphorus in the phosphorated polysilicon film 11d is diffused in the silicon Fin 16 by annealing processing. Subsequently, phosphorus in the silicon Fin 16 is activated by high temperature annealing processing when necessary, and is further diffused. A silicon content rate of the phosphorated polysilicon film 11d is higher than a silicon content rate of the oxide film 15a.

More specifically, the phosphorated polysilicon film 11d is formed on the SiO₂ films 15a serving as underlayer gate oxide films at one temperature within a temperature range of 400° C. to 700° C. by a CVD method. Next, annealing is performed at one temperature within a range of 900° C. to 1050° C. and in a N₂ gas atmosphere for a time within a range of 1 min to 60 min to diffuse phosphorous from the phosphorated polysilicon 11d into the Si-Fin 16. Further, spike annealing is performed at about 1100° C. by using flash lamp annealing or laser annealing to active phosphorous in the Si-Fin 16.

Next, as illustrated in FIGS. 34A and 34B, the phosphorated polysilicon film 11d is removed. FIG. 34A illustrates a cross-sectional view of the Fin-FET transistor in the channel width direction after the etching processing according to the fourth embodiment of the present disclosure. FIG. 34B illustrates a three-dimensional schematic view of the Fin-FET transistor after the etching processing according to the fourth embodiment of the present disclosure.

In a 3D structure which is typically a Fin-FET, the phosphorated polysilicon 11d in grooves between a Fin needs to be completely removed. To realize the removal, isotropic etching for performing etching in a vertical direction as well as in a horizontal direction is preferably performed. Further, performing etching having a high etching rate with respect to silicon and having a high selectivity with respect to the underlayer SiO₂ films 15a is demanded. Hence, in this etching process, too, the phosphorated polysilicon film 11d is removed by using an etching gas (e.g. IF₇ gas) which enables highly selective isotropic etching.

Thus, by gas-etching only silicon at a high etching rate, it is possible to remove only the phosphorated polysilicon 11d in a state where a shape of each underlayer SiO₂ film 15a is kept without an etching residue of the phosphorated polysilicon.

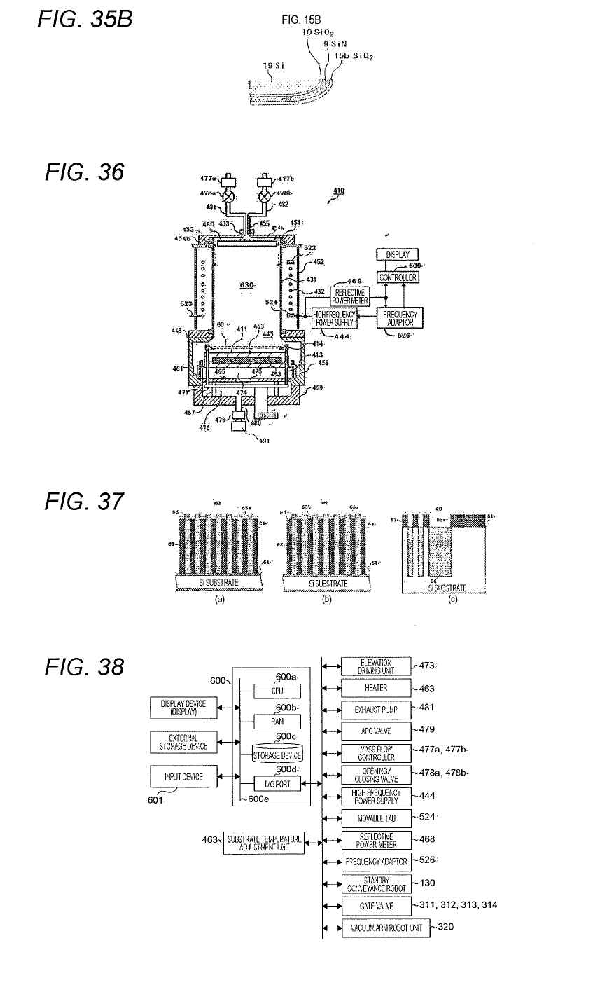

FIG. 35A illustrates a view illustrating a state before a phosphorated polysilicon film at a substrate back side is removed according to the fourth embodiment of the present disclosure. The phosphorated polysilicon film 11e at an outermost side of the substrate back side is a phosphorated polysilicon film which is formed simultaneously upon formation of the phosphorated polysilicon 11d at the substrate surface side and is formed of the same material as that of the phosphorated polysilicon film 11d. An oxide film 15b under the phosphorated polysilicon film 11e is an oxide film (SiO₂ film) which is simultaneously formed upon formation of the gate oxide film 15a at the substrate surface side and is formed of the same material as that of the gate oxide film 15a.

A SiN film 29 under the oxide film 15b, and a SiO₂ film which is in contact with a silicon substrate 19 are formed at a substrate back side, too, as films formed at the substrate surface side in a general STI formation process performed at an initial stage of a CMOS process similar to the third embodiment.

FIG. 35B illustrates a view illustrating a state before a phosphorated polysilicon film at the substrate back side is removed according to the fourth embodiment of the present disclosure. Thus, in the fourth embodiment, by performing etching using a gas having a high etching selectivity with respect to silicon, it is possible to simultaneously remove the phosphorated polysilicon 11d at a wafer surface side and remove the phosphorated polysilicon 11e at a wafer back side. In addition, in the present embodiment (fourth embodiment), phosphorated polysilicon has been used. However, it is also possible to use boronated polysilicon instead of phosphorous.

Further, in a vertical type apparatus or a single substrate processing apparatus, a film-forming gas goes around to a substrate back side or a back side circumferential section of the substrate in some cases. In this case, a phosphorated polysilicon film or a boronated polysilicon film is formed at the substrate back side or the back side circumferential section of the substrate. In such a case, according to the present embodiment (fourth embodiment), similar to the case of the third embodiment, it is possible to highly selectively remove the phosphorated polysilicon film or the boronated polysilicon film formed at the substrate back side when the phosphorated polysilicon film or the boronated polysilicon film formed at the substrate surface side is removed.

Effects provided by the above-mentioned fourth embodiment include at least one or more effects of the following effects (1) to (3). (1) In a gate last process of the Fin-FET transistor, it is possible to highly selectively remove the phosphorated polysilicon film or the boronated polysilicon film formed for ion injection for a silicon Fin, with respect to the underlayer gate oxide film having a lower silicon content rate than that of the phosphorated polysilicon film or the boronated polysilicon film. (2) Further, it is possible to highly selectively remove the phosphorated polysilicon film or the boronated polysilicon film formed at the substrate back side when the phosphorated polysilicon film or the boronated polysilicon film formed at the substrate surface side is removed. (3) A substrate temperature in etching processing is 30 to 50° C., so that it is possible to highly selectively etch the polysilicon film 11 which is a Si etching target film and includes impurities of the group III or the group V. Further, the substrate temperature is preferably 40 to 50° C., so that it is possible to more highly selectively etch the polysilicon film 11 which includes the impurities of the group III or the group V.

### Fifth Embodiment

The fifth embodiment of the present disclosure will be described in more detail below with reference to the drawings.

### (1) Configuration of Substrate Processing Apparatus

First, a configuration of the substrate processing apparatus according to the present embodiment (fifth embodiment) will be described mainly with reference to FIG. 36. FIG. 36 illustrates a schematic configuration diagram of the substrate processing apparatus according to the present embodiment (fifth embodiment), and illustrates a vertical cross section of a processing unit 410. The substrate processing apparatus illustrated in this FIG. 36 adopts a mode that a first processing unit (FIG. 3) and a second processing unit (FIG. 5) in the substrate processing apparatus according to the first embodiment through the fourth embodiment are combined as one processing unit. Hence, in FIG. 36, components having the same functions and the same configurations as those in FIGS. 3 and 5 will be assigned the same reference numerals. (Substrate) A wafer 60 serving as a substrate includes a silicon-containing film 64 and a modification layer 65 above the silicon-containing film 64 as illustrated in FIG. 37, for example. The silicon-containing film 64 is removed in a silicon-containing film removal process described below. The modification layer 65 is a silicon-containing oxide film which is formed by adsorbing or diffusing oxygen on a surface or an upper section of the silicon-containing film, for example.

Features of the present embodiment (fifth embodiment) include features of the first embodiment through the fourth embodiment in particular, and lie in including a modification layer removal process described below and in substrate processing of removing a silicon-containing film by combining the modification layer removal process described below and a silicon-containing film removal process with respect to a substrate in FIG. 37, for example.

### Processing Chamber

A processing container 431 is usually formed of quartz glass or ceramics of a non-metal material and is formed in a cylindrical shape. In this regard, a metal material may be used if there is no inconvenience in particular. An upper end of the processing container 431 is closed by a top plate 454, and a lower end is closed by a horizontal base plate 448 serving as a base and a bottom plate 469 and is hermetically sealed by a pressure adjustment mechanism described below. A space at an upper side of the processing container 431 is a mixing chamber 630 in which gases are mixed. The gas mixing chamber 630 is optimized according to a desired gas flow or a mixing state. Further, a shower plate is provided to the gas mixing chamber 630, and a gas is directly supplied to a processing chamber 445. Furthermore, a space which is at a lower side of a surface of the base plate 448 and in which the wafer 60 is provided is the processing chamber 445. Still further, when a silicon oxide film is removed by using plasma, plasma is generated in a space which is a plasma mixing chamber 630 (equivalent to a plasma generating chamber 530) and opposes to a resonance coil 521 as an exciting unit described below.

### Substrate Supporting Unit

A susceptor 459 is provided on a bottom surface of the processing chamber 445. The susceptor 459 includes a susceptor table 411, and a substrate heating unit 463 which maintains the wafer on a susceptor at a predetermined temperature. Further, the substrate heating unit 463 includes a cooling mechanism which eliminates excessive heat when necessary. Furthermore, the susceptor 459 adopts a structure supported by a plurality of columns 461. A plurality of lifter pins 413 are provided to pass through this susceptor table 411, and a wafer supporting pin 414 serving as a substrate supporting unit is provided above the lifter pins 413. The wafer supporting pin 414 is elongated in a center direction of the susceptor 459. The wafer 60 is placed on the susceptor table 411 or the wafer supporting pin 414. In this case, the wafer supporting pin 414 adopts a structure configured to support an outer circumference section of the wafer 60 and the wafer supporting pin 414 may adopt a structure configured to support a vicinity of a center of the wafer 60 when necessary. By supporting the vicinity of the center of the substrate, it is possible to reduce deflection of a substrate caused when a large diameter substrate whose substrate diameter is 450 mm is supported, and improve processing uniformity. When, for example, the substrate is deflected, a gas flow and a wafer temperature near a deflection section differ from a gas flow and a temperature at sections other than the deflection portion, and the processing uniformity changes. The substrate supporting unit is configured as the wafer supporting pin 414. Depending on cases, the substrate supporting unit may include the susceptor table 411 and the lifter pins 413. The lifter pins 413 are connected to an elevation plate 471 and are configured to be elevated by an elevation driving unit 473 along a guide shaft 467.

### Exhaust Unit

Under the susceptor 459, an exhaust unit is disposed. The exhaust unit includes an APC (Auto Pressure Control) valve 479 which is a pressure adjustment unit (pressing adjustment mechanism), and an exhaust pipe 480. Depending on cases, an exhaust pump 481 may be included in the exhaust unit. A valve opening of the APC valve 479 is configured to be feedback-controlled based on a pressure in the processing chamber 445. The pressure in the processing chamber 445 is measured by a pressure sensor (not illustrated). A fluorine-containing gas used in the present embodiment is heavier than a nitrogen (N₂) gas which is a general purge gas. For example, a specific gravity of an iodine heptafluoride (IF₇) gas which is one of iodine-containing gases at a room temperature is about 2.7, and is about 2.8 times heavier than the nitrogen (N₂) gas. Hence, providing an exhaust port at a bottom section of a processing chamber in which the fluorine-containing gas is likely to stagnate is useful to suppress a residue of the fluorine-containing gas. Further, to encourage exhaust of the fluorine-containing gas, the exhaust unit may be configured to receive supply of the purge gas.

### Baffle Ring

Further, to improve a process gas flow, a baffle ring 458 of a cylindrical shape and an exhaust plate 465 may be provided. Multiple ventilation holes are uniformly provided to a cylindrical side surface of the baffle ring 458, and an exhaust communication hole 475 is provided in a center section of the exhaust plate 465. In a structure that the susceptor 459, the baffle ring 458 and the exhaust plate 465 compose a first exhaust chamber 474, and the exhaust plate 465 and the bottom plate 469 compose a second exhaust chamber 476, the first exhaust chamber 474 and the second exhaust chamber 476 continue to each other via the exhaust communication hole 475. Alternatively, the exhaust pipe 480 continues to the second exhaust chamber 476. By providing the first exhaust chamber 474 and the second exhaust chamber 476, respectively, it is possible to perform uniform exhaust from an entire circumferential direction of the wafer 60, and improve processing uniformity for the wafer 60.

### Gas Supply Unit

A gas supply pipe 455 which supplies a plurality of required process gasses from a gas supply facility which is not illustrated is provided to a gas introduction port 433 on the top plate 454 at the upper section of a processing container 431. The gas supply pipe 455 includes a process gas supply unit configured to supply a halogen element-containing gas as a process gas to the substrate,

a remover supply unit configured to supply a remover (removal gas) as a process gas to the substrate, and

a third supply unit (not illustrated) configured to supply a purging N2 gas, cleaning chlorine fluoride (ClF₃) or the like when necessary. For the remover, for example, a hydrogen fluoride (HF) gas is used as the remover. In addition, an example where a gas is supplied as the remover will be described. However, the present embodiment is not limited to this, and a configuration which enables removal by an etching method of supplying a liquid may be employed. Alternatively, when a modification layer is removed by spattering, a rare gas such as argon may be caused to flow. The gas supply unit is provided with mass flow controllers 477(a) and 477(b) serving as flow rate control units and opening/closing valves 478(a) and 478(b), and can control a gas supply amount. In this regard, units up to the remover supply unit are described, yet third or subsequent gas supply units may be provided. Alternatively, a gas to use may be mixed in advance and be caused to flow to the gas introduction port 433. Further, a baffle plate 460 which is nearly circular and is formed of quartz glass or ceramics is provided to adjust a process gas flow in the processing container 431. Alternatively, a structure which uses a shower plate when necessary may be adopted. The flow rate control unit and the APC valve 479 adjust a supply amount and an exhaust amount, so that pressures in the processing container 431 and the processing chamber 445 are controlled to desired values.

### Exciting Unit

The exciting unit which generates plasma may be provided to remove a modification layer film by using plasma.

To a resonance coil 432 serving as the exciting unit, a winding diameter, a winding pitch and a winding number are set to cause resonation at a mode of a fixed wavelength to form a standing wave of a predetermined wavelength. That is, an electrical length of the resonance coil 432 is set to integer times (one time, two times and . . . ) of one wavelength at a predetermined frequency of power supplied from a high frequency power supply 444 or a length corresponding to a half wavelength or a ¼ length. In case of, for example, 27.12 MHz, a length of one wavelength is about 11 meters. A frequency and a resonance coil length to use may be selected according to a desired plasma generation state and a mechanical dimension of the plasma generating chamber 630.

More specifically, in consideration of power to be applied, a magnetic field intensity to be produced or an appearance of an applied apparatus, the resonance coil 432 is configured to include an effective cross-sectional area of 50 to 300 mm² and a coil diameter of 200 to 500 mm and is wound 2 to 60 times at an outer circumferential side of the processing container 431 such that a magnetic field of about 0.01 to 10 gauss is produced by high frequency power of 800 kHz to 50 MHz and 0.5 to 5 kW. For a material which consists the resonance coil 432, a material formed by a copper pipe, a copper thin plate, an aluminum pipe, an aluminum thin plate, a member in which a copper plate or an aluminum is deposited on a polymer belt or the like is used. The resonance coil 432 is formed of an insulating material in a flat plate shape, and is supported at an upper end surface of the base plate 448 by a plurality of supporting units vertically formed.

While both ends of the resonance coil 432 are electrically grounded, at least one end of the resonance coil 432 is grounded via a movable tab 522 to finely adjust an electrical length of the resonance coil upon initial installation of the apparatus or change of processing conditions. For example, the resonance coil 432 is grounded at a fixed ground place. Further, in order to finely adjust an impedance of the resonance coil 432 upon initial installation of the apparatus or change of the processing conditions, a power feeding unit is configured by a movable tab 524 between both grounded ends of the resonance coil 432.

That is, the resonance coil 432 includes electrically grounded ground sections at both ends, and includes between the ground sections a power feeding unit which supplies power from the high frequency power supply 444. Further, at least one ground section is a position-adjustable variable ground section, and the power feeding unit may be a position-adjustable variable power feeding unit. When the resonance coil 432 includes the variable ground section and the variable power feeding unit, as described below, it is possible to more easily adjust a resonance frequency and a load impedance of the plasma generating chamber 630.

Further, at one end (or both ends) of the resonance coil 432, a waveform adjustment circuit which includes a coil and a shield may be inserted such that a phase current and a reverse phase current flow about an electrical neutrality of the resonance coil 432. Such a waveform adjustment circuit is configured as an open circuit by placing the end section of the resonance coil 432 in an electrically non-contact state or an electrically equivalent state. Further, the end section of the resonance coil 432 is not grounded by a choke serial resistance and may be connected in series to a fixed reference voltage.

An outer shield 452 is provided to shield leakage of an electromagnetic wave to an outside of the resonance coil 432, and form a capacitance component necessary to configure a resonance circuit between the resonance coil 432 and the outer shield 452. The outer shield 452 is generally formed in a cylindrical shape by using a conductive material such as an aluminum alloy, copper or a copper alloy. The outer shield 452 is disposed at an interval of about 5 to 10 mm from an outer circumference of the resonance coil 432. Further, generally, the outer shield 452 is grounded such that potentials are equal to those of the both ends of the resonance coil 432. By the way, to accurately set a resonance frequency of the resonance coil 432, a tab position of one end or both ends of the outer shield 452 may be adjusted, or a trimming capacitance may be inserted between the resonance coil 432 and the outer shield 452. Further, the electrically grounded outer shield 452 and the resonance coil 432 configure a spiral resonator.

As long as the high frequency power supply 444 is a power supply configured to supply power of a voltage and a frequency necessary for the resonance coil 432, a power supply such as a RF generator can be optionally used. For example, a high frequency power supply which can supply power of about 0.5 to 5 kW at a frequency of 80 kHz to 800 MHz is used.

Further, a reflective wave power meter 468 is installed at an output side of the high frequency power supply 444, and reflective wave power detected by the reflective wave power meter 468 is input to the controller 600 used as a control unit. The controller 600 not only controls the high frequency power supply 444 alone but also controls the entire substrate processing apparatus including operations of a substrate conveyance mechanism and a gate valve, for example. A display serving as a display device displays data or the like such as a detection result of a reflective wave of the reflective wave power meter 468 detected by various detecting units provided to the substrate processing apparatus. In addition, the high frequency power supply 444 is provided with a frequency adaptor 526 which controls an oscillating frequency.

In the present embodiment, the exciting unit is configured as the resonance coil 432 yet may include one or more of the high frequency power supply 444, the outer shield 452, the reflective wave power meter 468 and the frequency adaptor 526.

### Substrate Conveyance System

Next, a substrate conveyance system according to the present embodiment adopts the same mode as that of the substrate processing apparatus illustrated in FIGS. 1 and 2, and adopts the same conveyance mode, and therefore will not be described herein.

### Controller

The controller 600 controls each of the above-mentioned part to perform a substrate processing process described below. Parts which overlap parts in FIG. 6 will not be described in some cases.

### Control Unit

As illustrated in FIG. 38, the controller 600 serving as the control unit (control means) is configured as a computer including a CPU (Central Processing Unit) 600a, a RAM (Random Access Memory) 600b, a storage device 600c and an I/O port 600d. The RAM 600b, the storage device 600c and the I/O port 600d are configured to exchange data with the CPU 600a via an internal bus 600e. The controller 600 is connected with an input/output device 601 configured as a touch panel, for example.

The storage device 600c is configured as a flash memory or a HDD (Hard Disk Drive), for example. In the storage device 600c, a control program of controlling an operation of the substrate processing apparatus and a process recipe in which a procedure and conditions of substrate processing described below have been written are stored in readable states.

The I/O port 600d is connected to the above-mentioned elevation driving unit 473, substrate temperature adjustment unit 463, APC valve 479, mass flow controllers 477(a) and 477(b) and opening/closing valves 478(a) and 478 (b), and an exhaust pump 481, an air conveyance robot 130, gate valves 313 and 314, a vacuum arm robot unit 320 and the like. In addition, when the exciting unit is provided, the exciting unit is configured to be connected with the high frequency power supply 444, the movable tab 524, the reflective power meter 468 and the frequency adaptor 526, too.

The CPU 600a is configured to read the control program from the storage device 600c to execute, and to read the process recipe from the storage device 600c in response to an input of an operation command or the like from the input/output device 601. Further, the CPU 600a is configured to control an operation of lifting or lowering the lifter pin 413 by using the elevation driving unit 473,

an operation of heating/cooling the wafer 60 by using the substrate temperature adjustment unit 463,

a pressure adjustment operation by using the APC valve 479, and

an operation of adjusting a flow rate of a process gas by using the mass flow controller 477(a) and 477(b) and the opening/closing valves 478(a) and 478(b) according to contents of the read process recipe.

### (2) Substrate Processing Process

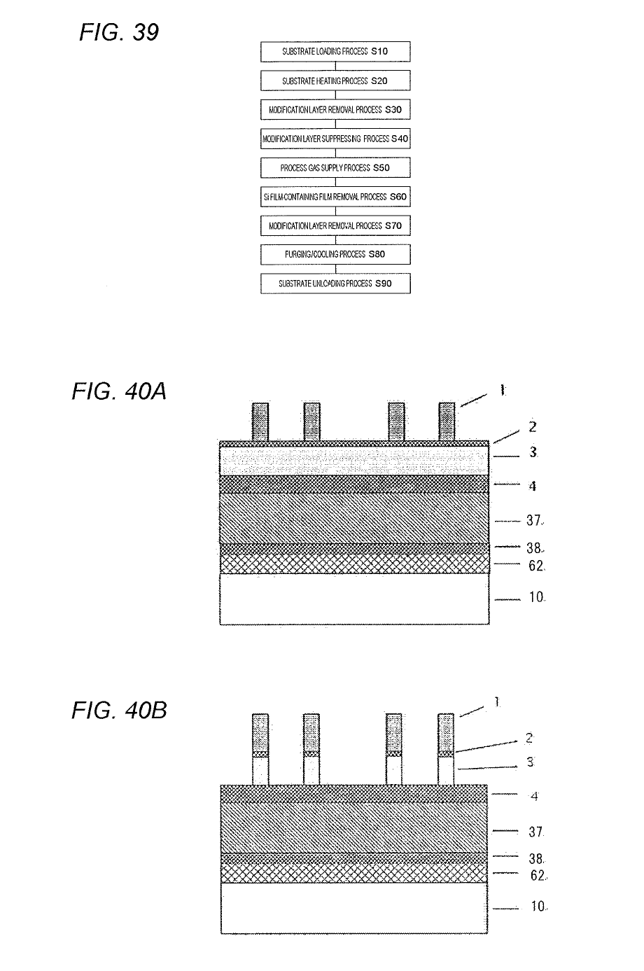

Next, a substrate processing process performed as one process of a semiconductor manufacturing process according to the present embodiment will be described with reference to FIG. 39. This process is performed by the above-mentioned substrate processing apparatus. In addition, in the following description, an operation of each component which constitutes the substrate processing apparatus is controlled by the controller 600. In this regard, the substrate processing process differs from the substrate processing process according to the first embodiment through the fourth embodiment in including a process of supplying an etching gas including halogen elements (preferably including iodine) and selectively etching a Si film, and, in addition, a process of removing a modification layer which prevents infiltration of this etching gas. This process of removing the modification layer may be performed before or after an etching process which uses an etching gas including iodine, and is optionally set according to a device structure formed on an etching target substrate. In addition, it goes without saying that this process of removing the modification layer is applicable even in the substrate processing process according to the first embodiment through the fourth embodiment.

### Substrate Conveying Process S10

First, the wafer 60 is conveyed by the air conveyance robot 130 from a FOUP 110 to a load lock chamber 250. The load lock chamber 250 is vacuum-exhausted, and substitutes an atmosphere or an inert gas atmosphere in an EFEM with a vacuum atmosphere, an inert gas atmosphere or a decompression atmosphere to which an inert gas is supplied. When substitution of the atmosphere is terminated, a gate valve 311 between the load lock chamber 250 and a transfer module 310 is opened, and the wafer 600 is conveyed by the vacuum arm robot unit 320 from the load lock chamber 250 to the transfer module 310. When the wafer 60 is conveyed, the gate valve 311 is closed. Subsequently, the wafer supporting pin 414 on the lifter pin 413 is placed via the gate valve 313 provided between the transfer module 310 and the processing unit 410. When the wafer conveyance mechanism is withdrawn to an outside of the processing chamber 445, the gate valve 313 is closed. When this wafer 60 is conveyed, a conveyance route is purged by the inert gas, and a conveyance is preferably conveyed in a decompression state. By providing an inert gas atmosphere and the decompression state, it is possible to prevent oxidation (oxygen adsorption) of a semiconductor element formed on the wafer 60 and unintentional adsorption of moisture.

### Substrate Heating Process S20

Next, the lifter pin 413 is lowered to place the wafer 60 on the susceptor table 411. The lifter pin 413 is lifted or lowered by the elevation driving unit 473. The substrate temperature adjustment unit 463 provided to the susceptor 459 is heated to a predetermined temperature in advance and heats the wafer 60 to a predetermined wafer temperature. When necessary, a cooling mechanism which exhausts excessive heat (reaction heat) is also used in combination. In this regard, a predetermined wafer temperature is in a temperature zone which sufficiently vaporizes a removal gas or an etching gas described below and is a temperature at which characteristics of a film formed on the wafer 60 do not deteriorate.

### Modification Layer Removal Process S30

Subsequently, the gas supply pipe 455 supplies the removal gas as a predetermined remover to the wafer 60 to remove the modification layer from the wafer 60. In this regard, the modification layer is an oxide film which is formed on a surface of a film whose main component is silicon (and a pattern formed by the silicon film) and contains silicon. The modification layer is formed by a reaction with oxygen included in the atmosphere during movement when, for example, the wafer 60 is moved. Further, water which is used to perform wet etching, cleaning or the like, and oxygen existing in the atmosphere are caused to react to form the modification layer. The film whose main component is silicon includes an amorphous silicon film, a polysilicon film, a P (phosphorous)-doped silicon film, a B (boron)-doped silicon film, an As (arsenic)-doped silicon film, a C (carbon)-doped silicon film and the like. The modification layer is removed by supplying the remover to the wafer 60. For example, the modification layer is removed by supplying the removal gas. For the removal gas, for example, a HF gas is used, and the removal gas is set to a predetermined gas flow rate between 0.1 slm and 10 slm. For example, the predetermined gas flow rate is set to 3 slm. A pressure in the processing chamber is set to, for example, a predetermined pressure between 1 Pa and 1300 Pa. For example, the pressure is set to 100 Pa. The HF gas is effective to remove a silicon oxide film in particular. In this case, the HF gas may be introduced into the processing chamber, or a mixed gas of an iodine heptafluoride (IF₇) gas and a hydrogen (H₂) gas may be introduced into the processing chamber to be plasma-activated and produce a HF gas component. By supplying the IF₇ gas in particular, it is possible to perform preliminary processing of a Si-containing film removal process described below. That is, it is possible to remove an intermediate layer of the modification layer and the silicon-containing film, and more securely remove the silicon-containing film in the silicon-containing film removal process. Further, in this regard, an example where the modification layer is removed by the HF gas has been described. However, the present embodiment is not limited to this. For example, a reducible gas may be configured to be supplied to remove oxygen. The reducible gas is, for example, a hydrogen (H₂) gas. Further, when an oxygen adsorption amount of a cleaning solution with respect to a surface is within an allowable range, the modification layer may be removed by a wet etching method which uses a remover solution (e.g. HF solution) as a remover. Furthermore, by using a gas as a remover one or both of a rare gas such as argon (Ar) and a reducible gas such as a hydrogen gas, or one or both of an activated (plasma activated) rare gas and an activated reducible gas, and supplying the gas to the wafer 60, the modification layer may be removed. By supplying the activated rare gas to the wafer 60, it is possible to remove the modification layer by spattering. Further, by supplying activated hydrogen to the wafer 60, it is possible to reduce the modification layer. By supplying such an activated remover (e.g. activated Ar) to the wafer 60, it is possible to remove the modification layer without damaging other films formed on the wafer 60 compared to a case where the HF gas is used. That is, it is possible to remove a modification layer 65a without undermining a function of a buried film. Further, the modification layer is removed by, for example, supplying a gas including halogen elements. The removal gas and the halogen element-containing gas are gases including two or more of halogen elements among fluorine (F), chloride (Cl), boron (Br) and iodine (I). For example, the removal gas includes at least one selected from a group consisting of iodine pentafluoride (IF₅), iodine heptafluoride (IF₇), bromine trifluoride (BrF₃), bromine pentafluoride (BrF₅), xenon difluoride (XeF₂) and chlorine trifluoride (ClF₃).

After the removal of the modification layer, it is preferable to perform necessary purge processing in preparation for a new next process.

### Modification Layer Suppression Process S40

This process prevents the modification layer from growing again after removal of the modification layer. For example, the wafer 60 is kept in an inert gas atmosphere, a reducible atmosphere and a vacuum atmosphere to prevent production of the modification layer. In the present embodiment, a series of processing is performed in the same processing chamber. Consequently, it is possible to quickly move to the next process without mixing oxygen in the atmosphere of the processing chamber.

### Process Gas Supply Process S50

Subsequently, the gas supply pipe 455 supplies a predetermined process gas. As the process gas, a gas (fluorine-containing gas) serving as an etching gas and including fluorine is supplied. Further, a purging or dilution inert gas may be supplied. In this regard, the fluorine-containing gas is gas including one or more fluorines (F). For example, the fluorine-containing gas includes at least one selected from a group consisting of iodine pentafluoride (IF₅), iodine heptafluoride (IF₇), bromine trifluoride (BrF₃), bromine pentafluoride (BrF₅), xenon difluoride (XeF₂) and chlorine trifluoride (ClF₃). Preferably, a gas (iodine-containing gas) including iodine such as iodine pentafluoride (IF₅), iodine heptafluoride (IF₇) or the like is used, and, more preferably, iodine heptafluoride (IF₇) is used. IF₇ can actively (selectively) remove the silicon-containing film. Further, for example, a nitrogen (N₂) gas is used as an inert gas yet a rare gas such as He, Ne or Ar may be used.

By simultaneously supplying a gas and adjusting an exhaust amount by the APC valve 479, an entire pressure in the processing chamber 445 is maintained at a predetermined pressure within a range of about 1 to 1330 Pa and a partial pressure of IF₇ is maintained at a predetermined pressure within a range of about 1 to 1330 Pa. The predetermined pressures are maintained at, for example, 100 Pa. Respective gas flow rates are set to predetermined flow rates within a range of about 0.1 to 10 SLM. For example, the predetermined gas flow rates are set to 3 SLM. Further, when necessary, the atmospheres in the processing container 431 and the processing chamber 445 are exhausted to supply a predetermined gas. Furthermore, as soon as an IF₇ gas is supplied, etching the silicon-containing film is started, and therefore pressures and gas flow rates are desirably quickly set to predetermined values. In this regard, it goes without saying that the present embodiment is applicable even under the processing conditions C1 according to the first embodiment and the fourth embodiment.

### Silicon-Containing Film Removal Process S60

By maintaining a substrate temperature, a pressure and a gas flow rate at predetermined values for a predetermined period of time, a predetermined amount of the silicon-containing film is selectively removed. Particularly, the IF₇ gas can selectively remove the silicon film at a high etching rate without using plasma at about a room temperature (e.g. a substrate temperature of 30° C. to 50° C.)

In addition, in this case, in a state where the wafer 60 is supported by the wafer supporting pin 414, an etching gas may be supplied. By supplying the etching gas in a state the wafer 60 is supported by the wafer supporting pin 414, it is possible to remove a film (silicon-containing film) whose main component is silicon formed on a back surface of the wafer 60. Further, the wafer 60 may be supported by the wafer supporting pin 414 after the etching gas is supplied to some degree or before the etching gas is supplied.

In this regard, upon comparison between the surface and the back surface of the wafer 60, fine unevenness which consists a semiconductor device is formed on the surface of the wafer 60, and the film whose main component is silicon is formed on the back surface. Depending on a support timing of the wafer supporting pin 414, there is a case where a film which is formed inside the unevenness and whose main component is silicon is excessively removed or a film is left on the back surface even if the film is adequately removed. By differing supply times for the surface and the back surface of the wafer 60, it is possible to uniformly process the surface and the back surface of the wafer 60.

### Modification Layer Removal Process S70

When necessary, the modification layer left after removal of the silicon-containing film is removed. In this regard, the modification layer is an oxide film which is formed on the surface of a film whose main component is silicon and contains silicon. In this case, a HF gas may be introduced into the processing chamber, or a mixed gas of an IF₇ gas and a H₂ gas may be introduced into the processing chamber to be plasma-activated and produce a HF gas component.

By supplying the IF₇ gas, it is possible to remove the silicon-containing film even if the silicon-containing film is left in the above-mentioned silicon-containing film removal process. Further, it is possible to remove the intermediate layer of the silicon-containing film and the modification layer, too. Furthermore, by using a gas as a remover one or both of a rare gas such as argon and a reducible gas such as a hydrogen gas, or one or both of an activated (plasma activated) rare gas and an activated reducible gas, and supplying the gas to the wafer 60, the modification layer may be removed. By supplying the activated rare gas to the wafer 60, it is possible to remove the modification layer by spattering. Further, by supplying activated hydrogen to the wafer 60, it is possible to reduce the modification layer.

By supplying such an activated remover to the wafer 60, it is possible to remove the modification layer without damaging other films formed on the wafer 60. In addition, in this case, after the wafer 60 is supported by the wafer supporting pin 414, a removal gas may be supplied. Further, the wafer 60 may be supported by the wafer supporting pin 414 while the removal gas is supplied. In this case, durations of time to expose a silicon electrode (pattern) on a wafer surface and a wafer back surface to the removal gas are different, and therefore the more removal gas is exposed to the wafer surface.

Further, a reactivity of a HF gas depends on a moisture amount in a reaction chamber atmosphere, too, and therefore it is effective to remove the modification layer by using the plasma-activated and sufficiently active removal gas.

### Purging/Cooling Process S80

After the necessary removal process is terminated, supply of the removal gas is stopped, and atmosphere gases in the processing container 431 and the processing chamber 445 are exhausted. In this case, while a purge inert gas is caused to flow, the atmosphere gases may be exhausted. Further, as described above, a halogen-containing gas is heavier than the purge gas, and therefore the removal gas is likely to remain. Therefore, purging is preferably performed sufficiently to prevent the removal gas from remaining. For example, supplying the purge inert gas and exhausting the atmosphere gases are alternately performed. Consequently, it is possible to prevent the halogen-containing gas from remaining in the processing chamber and from leaking to the outside of the processing chamber. Further, the lifter pin 413 is lifted to move the wafer 60 away from the susceptor table 411 and cool the wafer 60 to such a temperature that the wafer 60 can be conveyed.

### Substrate Unloading Process S90

When the wafer 60 is cooled to such a temperature that the wafer 60 can be conveyed and preparation to unload the wafer 60 from the processing chamber is ready, the wafer 60 is unloaded in a reverse sequence of above-mentioned substrate loading process S10.

In the above-mentioned substrate processing process in particular, when a modification layer in a trench structure is removed from a substrate on which a device adopting the trench structure of a high aspect ratio has been formed at a surface side, it is effective to plasma-activate (activate) a gas and cause the gas to enter the trench.

Effectiveness of the process of removing the modification layer in the present embodiment (fifth embodiment) will be described in more detail.

When the silicon-containing film serving as a removal target in the etching process is covered with the modification layer, if this modification layer is a film which is sufficiently thick and dense, the modification film blocks infiltration of the IF₇ gas, and a silicon removal reaction does not occur. However, it has been found that, when the modification layer is a thin and rough film such as a natural oxide film, the IF₇ transmits through the modification layer and reacts with underlayer silicon, silicon is removed and the modification layer is left as a residue.

A surface of the silicon-containing film in particular is easily naturally oxidized. Unless attention is paid to removal of this natural oxide film, an unintentional residue is produced after the silicon-containing film is removed by the IF₇ gas.

Further, while a substrate can be wet-washed before removal of the silicon-containing film, after removal of the silicon-containing film, a fine structure of a high aspect ratio is exposed, and therefore the substrate cannot be wet-washed in many cases. In this regard, a fine structure of a high aspect ratio is, for example, a pillar structure. In such a case, after removal of the silicon-containing film, there is no way of removing a modification layer if a residue of the modification layer is left. There is a problem that, when, for example, the wafer 60 from which a fine structure of a high aspect ratio has been exposed is wet-washed, a pattern collapses as described. Hence, it is particularly important to remove the modification layer which is a source of a residue before removal of the silicon-containing film.

### (3) Fifth Embodiment

### Gas Etching Including Modification Layer Removal Process

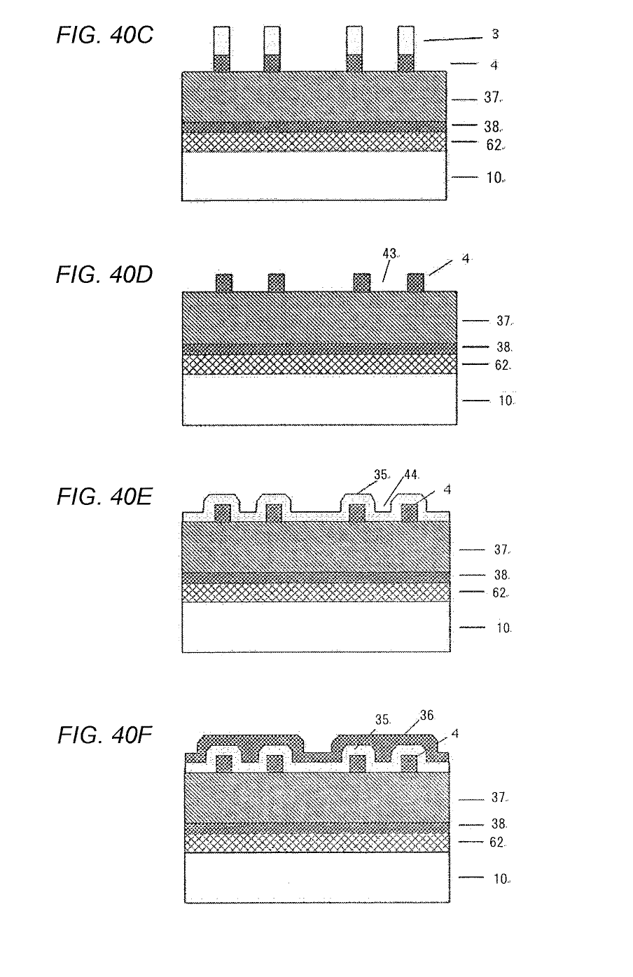

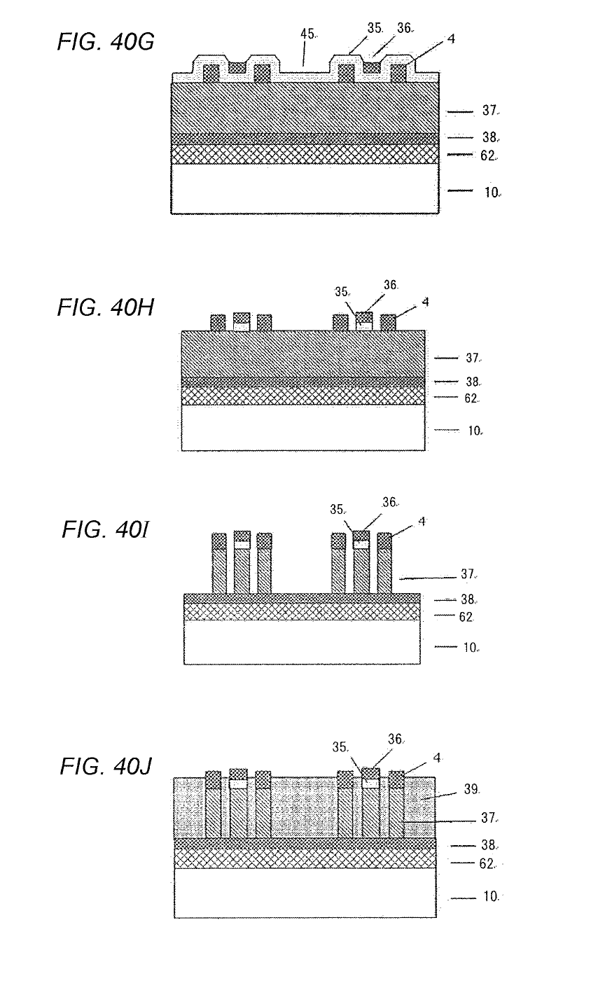

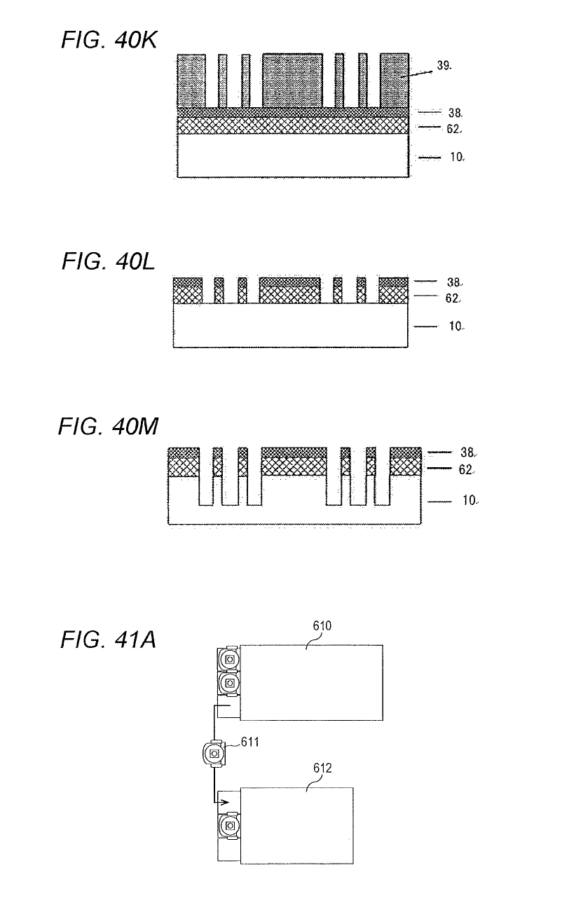

A fine pattern formation flow for a back-end for suitably performing the present embodiment will be described below with reference to FIGS. 40A to 40M. FIGS. 40G and 40J in particular illustrate examples of a process of performing gas etching which has a high etching rate with respect to silicon, and has a high selectivity with respect to, for example, a SiO₂ film, a Si₃N₄ film and a carbon film.

Further, FIGS. 40A to 40M illustrate a negative-tone SADP method of forming a sidewall of a SiO₂ film by using a silicon member as a core, then forming a silicon film, etching back the sidewall of the SiO₂ film and forming a groove pattern less than a lithography resolution limitation. Furthermore, FIGS. 40A to 40M illustrate that a silicon core pattern of the resolution limitation dimension or more to be formed is patterned by using lithography and dry etching, and a multilayer resist film formed by applying a resist on a carbon film and a silicon antireflection film is used. Still further, FIGS. 40A to 40M illustrate an example where negative SADP is performed on a multilayer film formed by stacking a TiN film, a silicon film and a SiO₂ film on a patterning target. This multilayer film is used for a back-end.

Further, FIGS. 40A to 40M illustrate a process flow which is an example which suitably represents the present disclosure, and a combination of underlayer stacked films is not limited in particular.

In the present embodiment, first, as illustrated in FIG. 40A, a resist 1 is patterned and slimmed by lithography. Subsequently, as illustrated in FIG. 40B, by using the patterned resists 1 as masks, an underlayer silicon antireflection film 2 and a carbon hardmask 3 are dry-etched and patterns are transferred thereto. Next, as illustrated in FIG. 40C, after the resists 1 are removed by an ashing, an underlayer silicon film 4 is patterned by using the patterned silicon antireflection films 2 and carbon hardmask films 3 as masks. Next, as illustrated in FIG. 40D, the carbon hardmask layers 3 are removed by an ashing to form a core pattern of the silicon films 4 (protrusions whose main components are silicon). First grooves 43 are formed between the protrusions whose main components are silicon.

Next, as illustrated in FIG. 40E, a SiO₂ film 35 is formed. The SiO₂ film 35 is preferably formed uniformly with a good coverage with respect to the core of the silicon film 4. The SiO₂ film 35 is formed to form second grooves 44. Next, as illustrated in FIG. 40F, a silicon film 36 is formed to cover the SiO₂ film 35. In this case, an area in which a silicon core is densely disposed is formed by burying the silicon film 36 in the grooves between adjacent sidewalls of the SiO₂ film 35. The silicon film 36 is buried in gaps between the adjacent sidewalls, and the gaps are adjusted to a desired dimension according to a core pattern dimension and a pitch of the silicon film 4 and a film thickness of the SiO₂ film 35. More specifically, the silicon film 36 is formed on the SiO₂ film 35 and the silicon film 36 formed on the second grooves 44 is adjusted to have a thick film particularly. Further, the silicon film 36 which is formed on the SiO₂ film 35 and is other than the silicon film 36 formed on the second grooves 44 is preferably adjusted to have the same film thickness.

Next, as illustrated in FIG. 40G, etching conditions are adjusted to etch back the silicon film 36 and leave in the second grooves 44 only the silicon film 36 in an area in which the silicon film 36 is buried. In this case, according to a wide groove pattern (third groove 45), it is necessary to completely remove the sidewall silicon film 36 and the bottom silicon film 36. To remove the silicon film 36, it is necessary to perform isotropic etching. In this case, a groove width has a relationship of a second groove width<a first groove<a third groove width. In this process, gas etching which uses an IF₇ gas is performed as etching including a high etching rate with respect to silicon and having a high selectivity with respect to a SiO₂ film. An example of the IF₇ gas supply conditions for performing etching is that a flow rate is 1 liter (only center conditions are tentatively indicated), a pressure is around 200 to 500 Pa and a temperature is about a room temperature (e.g. 30° C. to 50° C.). In this case, for example, conditions are adjusted to completely remove the silicon film 36 (the sidewall silicon film 36 and the bottom silicon film 36) facing the third groove, the silicon film 36 deposited on the SiO₂ film 35 deposited on the silicon film 4 or the like, and leave only the silicon film 36 formed on the second groove 44. In addition, it goes without saying that the processing conditions C1 according to the first embodiment and the fourth embodiment may also be applied. In this case, the conditions are adjusted based on an etching time, for example.

In this regard, when an etching gas serving as a process gas is supplied, it is preferable to perform processing which uses a remover in advance as described above.

Subsequently, as illustrated in FIG. 40H, the SiO₂ film 35 is dry-etched and the SiO₂ film 35 between core pattern of the silicon film 4 and the silicon film 36 left in the gaps of the SiO₂ film is removed to form a groove pattern. Next, as illustrated in FIG. 40I, an underlayer SiO₂ film 37 is patterned by dry etching by using the pattern formed in FIG. 40H as a mask. FIG. 40I illustrates a case where a silicon film 38 is laid below as etching stoppers of the SiO₂ films 37. Next, for example, carbon-based films 39 are buried in a groove pattern formed by etching the SiO₂ film as illustrated in FIG. 40J. A general resist member may be used instead of a carbon film. It is desirable to apply the film by a spin coating method to bury the carbon-based film from the bottoms of the gaps. Further, etching is performed until the surfaces of the silicon films 4 and 36 which have been patterned by etching back are exposed.

Next, as illustrated in FIG. 40K, the pattern on the surface of the silicon film is removed under etching conditions that the carbon-based films 39 are not scraped. In this case, the silicon films 4 and 36 are etched first. The underlayer SiO₂ film and the carbon-based film 9 are desirably films of a high selectivity, and, for example, gas etching which uses IF₇ is used. IF₇ gas supply conditions are that a flow rate is 1 liter (only center conditions are tentatively indicated), a pressure is around 200 to 500 Pa and a temperature is 30° C. to 50° C. In addition, it goes without saying that the processing conditions C according to the first embodiment and the fourth embodiment may also be applied. In this case, a wafer back surface is exposed, so that the vertical type device can simultaneously remove the wafer back surface and the silicon film. Meanwhile, in case of a single substrate processing apparatus, too, by causing the wafer supporting pin 414 to float the wafer 60 upon supply of the IF₇ gas, and causing an etching gas to go around to the wafer back surface, it is possible to simultaneously remove the silicon film on the wafer back surface. In addition, in this case, after the wafer 60 is supported by the wafer supporting pin 414, a removal gas may be supplied. In this case, durations of time to expose a silicon electrode (pattern) on a wafer surface and a wafer back surface to the removal gas are different, and therefore the more removal gas is exposed to the wafer surface.

Next, the SiO₂ film 37 is etched by switching to SiO₂ film etching and using the underlayer silicon film 38 as an etching stopper. Next, two layers of the silicon film 38 and a TiN film 62 serving as an electrode are subsequently etched as illustrated in FIG. 40L. Further, the carbon-based films 39 are removed by ashing. The ashing in this case is preferably ashing which does not include an oxygen-based gas. Next, grooves are formed in the underlayer SiO₂ film 10 by using the patterned silicon films 8 and the TiN films 62 as masks as illustrated in FIG. 40M. It is possible to form a groove pattern in a copper damascene process in a back-end process at pitches less than a lithography resolution limitation.

Further, in the present embodiment (fifth embodiment), a process of directly removing a target film by using the removal gas or the etching gas has been described. The present embodiment is not limited to this, and a halide chloride gas and a silicon oxide film may be caused to react and produce a reactant, and a film may be removed by heating and vaporizing the reactant.

Further, in the present embodiment (fifth embodiment), the silicon oxide film formed at the upper section of the silicon-containing film has been described as the modification layer. However, the present embodiment is not limited to this. When, for example, plasma processing which uses hydrogen and nitrogen is performed upon resist ashing, a nitride film is formed on a substrate or a surface of a film formed on a substrate. When there is this nitride film, too, the same problem as that described above is likely to occur. By removing the nitride film (modification layer) before removing the silicon-containing film, it is possible to suppress the amount of the remaining nitride film.

Further, according to the present embodiment (fifth embodiment), as described above, an example where a modification layer formed on a silicon film is removed by a remover and the silicon film is removed by the etching gas has been described. However, the present embodiment is not limited to this. For example, when dummy gate electrodes whose main components are silicon are removed, a natural oxide film formed on surfaces of the dummy gate electrodes may be removed by a remover, and then the dummy gate electrodes may be removed by an etching gas. Alternatively, a natural oxide film formed on a surface of an electrode formation mold silicon film may be removed by a remover, and then the mold silicon film may be removed by the etching gas.

Thus, according to the present embodiment (fifth embodiment), even when a natural oxide film is deposited on a semiconductor device formed on a substrate, it is possible to remove a modification layer formed on a silicon film by a remover, expose the silicon film covered by the modification layer to a surface, and remove this silicon film by the etching gas. In the present embodiment in particular, it is possible to use an iodine heptafluoride (IF₇) gas having a remarkably distinct selectivity as an etching gas for a Si film and films other than the Si film.

### (4) Effects According to Present Embodiment

According to the present embodiment, one or a plurality of following effects (a) to (f) is provided.

(a) In gas etching processing of selectively removing a Si film by using an etching gas including fluorine, it is possible to remove in advance the modification layer which hinders a silicon removal reaction.

(b) Further, in gas etching processing of selectively removing a Si film by using an etching gas including fluorine, it is possible to suppress a residue caused by the modification layer which exists in a surface of a removal target silicon-containing film.

(c) Furthermore, it is possible to prevent a residue caused by the modification layer from contaminating the substrate processing apparatus.

(d) Still further, in gas etching processing of selectively removing a Si film by using an etching gas including fluorine, it is possible to suppress a residue caused by the modification layer which exists in a section covered by a removal target silicon-containing film.

(e) Moreover, by removing the modification layer by a removal gas and then removing the silicon-containing film by a fluorine-containing gas, it is possible to remove the silicon-containing film without collapsing electrodes formed on a substrate.

(f) Besides, by performing a process of removing the modification layer after the silicon-containing film removal process, it is possible to remove an oxide film formed on an interface between the silicon-containing film and the electrodes.

It goes without saying that the present disclosure is not limited to the embodiment, and can be variously changed without departing from a spirit of the present disclosure.

Further, in the embodiment, one substrate processing apparatus is configured to perform the first etching processing, the second etching processing and the third etching processing. However, different substrate processing apparatuses can also be configured to perform the first etching processing, the second etching processing and the third etching processing, respectively.

Next, a case where a substrate processing flow illustrated in above-mentioned FIG. 39 is divided per element and performed at different sites will be exemplified as another aspect of the substrate processing flow.

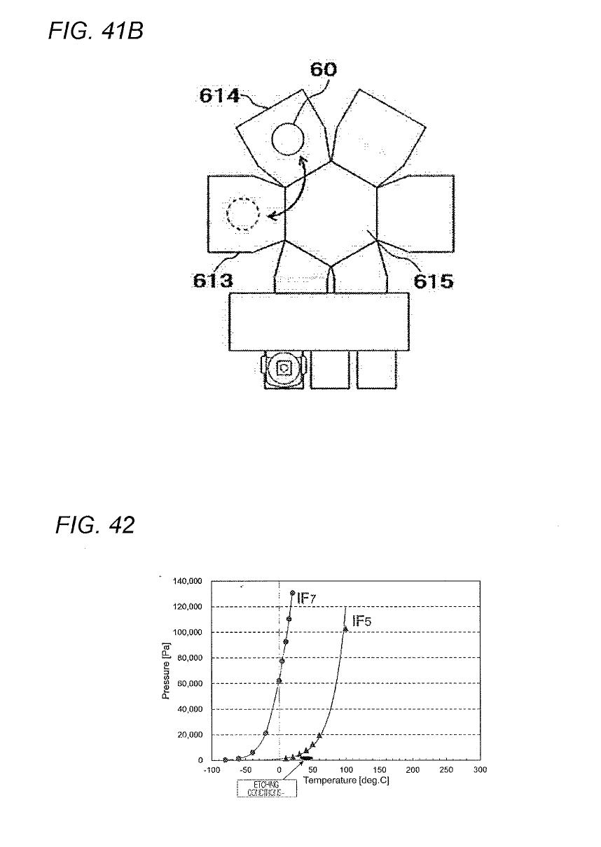

FIG. 41A illustrates another aspect of the substrate processing flow. In this regard, a modification layer removing device 610 performs modification layer removal process S30, and then a silicon-containing film removing device 612 performs silicon-containing film removal process S60. Further, in modification layer suppressing process S40, a substrate is stored in a container 611 of an inert gas atmosphere and is conveyed to suppress production of a new modification layer. A specific example of such a mode is that, for example, a wet washing device removes a modification layer film, and a substrate is conveyed to an apparatus which removes a silicon-containing film by using N₂ purge FOUP (Front Opening Unified Pod). Further, a modification layer removing method is not limited to wet washing and may be a dry process which uses a gas. In this regard, one of ordinary skill in the art can make various improvement, changes and additions to the modification layer removing method and the new modification layer suppressing method within a scope of a technical idea according to the present disclosure.

FIG. 42B illustrates still another aspect of the substrate processing flow. In this regard, FIG. 42B illustrates a case where a modification layer removal reaction chamber 613 and a silicon-containing film removal reaction chamber 614 are coupled by a vacuum conveyance chamber 615 which is purged by an inert gas by using a cluster type substrate processing apparatus to continuously perform a series of processing. In this regard, the reaction chamber 613 performs modification layer removal processes S30 and S70, the vacuum conveyance chamber 615 performs modification layer suppressing process S40, and the reaction chamber 614 performs silicon-containing film removal process S60. In addition, different reactions may perform modification layer removal processes S30 and S70.

In the present embodiment, a wafer temperature has been adjusted by using a heater and a coolant supply path in the first processing unit. The present embodiment is not limited to this, and, as long as an etching gas has a lower liquefaction temperature than a room temperature, the temperature may be adjusted by a coolant without using the heater. Alternatively, a temperature control mechanism which has both cooling and heating functions of adjusting the liquefaction temperature to circulate may be provided.

Further, in the present embodiment, a single substrate processing apparatus has been described as an example. However, the present disclosure is also applicable to a vertical type apparatus, too, which performs processing in a state, for example, where a plurality of substrates of horizontal postures are stacked on a boat and this boat is conveyed into the processing chamber. In the first embodiment, a plurality of substrates for which sidewalls have been formed in above-mentioned step S5 are loaded on the boat and loaded into the processing chamber to perform core pattern removal processing in above-mentioned step S6. Further, when the core pattern removal processing is terminated, the boat is unloaded from the processing chamber, and another processing apparatus performs processing subsequent to above-mentioned step S7. In the second embodiment, a plurality of substrates on which silicon hardmasks illustrated in FIG. 26 according to the second embodiment have been formed, a plurality of substrates on which dummy polysilicon films according to the third embodiment have been formed or phosphorated polysilicon films according to the fourth embodiment have been formed are loaded on the boat and conveyed into the processing chamber to perform the above-mentioned silicon hardmask removal processing according to the second embodiment, dummy polysilicon film removal processing according to the third embodiment or phosphorated polysilicon film removal processing according to the fourth embodiment.

In this case, the vertical type apparatus, too, performs etching processing under the same temperature and pressure conditions as those of the single substrate processing apparatus by using an IF₇ gas as an etching gas of core pattern removal processing. Thus, the vertical type apparatus, too, can highly selectively etch the Si core pattern 4 on the SiO₂ film 10 serving as the sidewall film and the underlayer Si₃N₄ film 5 in the first embodiment.

Preferably, in the first embodiment, for example, the vertical type device, too, performs (d) etching processing which uses an IF₇ gas, (e) etching processing which uses, for example, an O₃ gas (ozone gas) and (f) etching processing which uses the IF₇ gas in the core pattern removal processing in this order. For example, in the second embodiment, (d) etching processing which uses the IF₇ gas, (e) etching processing which uses the O₃ gas (ozone gas) and (f) etching processing which uses the IF₇ gas in the silicon hardmask removal processing according to the second embodiment are performed in this order. In this regard, the above-mentioned processing conditions (d) and (f) have the same temperature and pressure as those in the single substrate processing apparatus. In this case, the IF₇ gas is introduced into the processing chamber to perform first etching processing which uses the IF₇ gas and then substitute the IF₇ gas with an inert gas in the processing chamber. Subsequently, the O₃ gas is introduced into the processing chamber to perform second etching processing which uses the O₃ gas and then substitute the O₃ gas with the inert gas in the processing chamber. Subsequently, the third etching processing which uses the IF₇ gas is performed.

By so doing, the vertical type apparatus, too, can simultaneously remove the Si core pattern 4 at the substrate surface side and remove a stacked film of the Si film 2, the CHM film 3 and the Si film 4 at the back side of the substrate as illustrated in FIG. 15 in the first embodiment, for example. In more detail, it is possible to remove the Si core pattern 4 at the substrate surface side and the Si film 4 at the substrate back side by performing the processing (d), remove the CHM film 3 at the substrate back side by performing the processing (e), and remove a the Si film 2 at the substrate back side by performing the processing (f). According to the second embodiment, for example, it is possible to simultaneously remove a silicon hardmask at the substrate surface side, and remove a stacked film of the silicon antireflection film 2, the carbon film 3 and the silicon hardmask 4 at the substrate back side as illustrated in FIGS. 28 and 29. In more detail, it is possible to remove the silicon hardmask 4 at the substrate surface side and the silicon antireflection film 2 at the substrate back side by performing the processing (d), remove the carbon film 3 at the substrate back side by performing the processing (e), and remove the silicon hardmask 4 at the substrate back side by performing the processing (f).

Further, the present disclosure is applicable to various SADP methods such as formation of an element structure of a DRAM which is one type of semiconductor memories, and a gate electrode of a transistor. Furthermore, the present disclosure is not limited to a structure of a multilayer hardmask which is an underlayer of the SADP process. According to a process type, there may be a case where there are three layers of hardmasks including SiO₂, Si₃N₄ and SiO₂ on a Si substrate, a case where there are two layers of hardmasks of a Si₃N₄ film and a SiO₂ film or other cases.

Further, the present disclosure provides a substrate processing method and a substrate processing apparatus which can selectively remove silicon while removing an unnecessary modification layer by combining

a process of removing the modification layer existing on a surface of a removal target silicon-containing film upon selectively dry etching of a Si film using an etching gas including fluorine,

a process of suppressing production of a new modification layer, and

a process of removing the modification layer existing at a section covered by the removal target silicon-containing film. A scope in which the present disclosure is carried out is not limited to a type of the number of substrates to be simultaneously processed, a direction in which a substrate is held, types of a dilution gas and a purge gas, a cleaning method, shapes of a substrate processing chamber, a heating mechanism and a cooling mechanism and the like.

Further, according to the present disclosure, it is possible to not only perform a process of dry-etching one or both of a modification layer and a silicon-containing film which are formed on a substrate but also perform a process of removing (cleaning) the modification layer and the silicon-containing film deposited in the substrate processing chamber.

Furthermore, in the present embodiment, a pattern is conventionally miniaturized to realize a higher degree of integration, yet there is a problem unique to a miniaturized pattern as miniaturization advances. An example of this problem is that a pattern collapses due to surface tension of a liquid upon wet etching. For example, in a silicon (Si) removal process, pure water washing is performed after etching using tetramethylammonium hydroxide (TMAH) or the like, and drying is performed by performing substitution using isopropyl alcohol (IPA) of a lower surface tension than that of the pure water to prevent a pattern collapse due to the surface tension of the cleaning solution. However, as pattern miniaturization advances, pattern collapses cannot be prevented even by using this method. A means for solving this problem is dry etching of removing silicon by using an etching gas including iodine according to the present disclosure, and is applicable to future pattern miniaturization, too.

Further, in the present embodiment, upon manufacturing of a device of a 3D structure such as a NAND flash memory, conventional reactive ion etching which uses plasma has difficulty in highly selectively removing a polysilicon (Poly-Si) film with respect to films (e.g. a silicon oxide (SiO₂) film, a silicon nitride (SiN) film, a silicon oxynitride (SiON) film, a carbon (C) film and the like) other than the polysilicon. That is, upon etching of only the polysilicon (Poly-Si) film among layers of the polysilicon (Poly-Si) film and the silicon oxide (SiO₂) film exposed from a sidewall after a penetration groove is bored in a stacked structure of the polysilicon (Poly-Si) film and the silicon oxide (SiO₂) film, conventional reactive ion etching which uses plasma has significant difficulty due to a problem of a selectivity with respect to other films than the polysilicon and necessity of isotropic etching. Further, there is also a problem of a selectivity with respect to a hardmask film (e.g. carbon film). It is difficult to catch up with complication of a device structure due to such pattern miniaturization. A means for solving this problem is dry etching of removing silicon such as isotropic etching by using an etching gas according to the present disclosure without plasma, and is applicable to future pattern miniaturization, too. Particularly, by using an iodine-containing gas (gas including iodine) including iodine heptafluoride as an etching gas, it is possible to remove silicon while a selectivity with respect to films other than silicon is good thanks to a chemical property of the gas compared to an existing etching gas. Consequently, it is applicable to support complication of a device structure brought by future pattern miniaturization.

Further, the present disclosure is applicable not only to a semiconductor manufacturing apparatus but also to an apparatus such as an LCD manufacturing apparatus which processes a glass substrate. Furthermore, the present disclosure is applicable to various single substrate processing apparatuses such as multiple wafer type processing apparatuses, incline type apparatuses and cluster type apparatuses or horizontal type substrate processing apparatuses. The present disclosure is not limited to a semiconductor manufacturing apparatus such as a substrate processing apparatus according to the present embodiment which processes semiconductor wafers, and is applicable to substrate processing apparatuses such as LCD (Liquid Crystal Display) manufacturing apparatuses which process glass substrates and solar cell manufacturing apparatuses, and MEMS (Micro Electro Mechanical Systems) manufacturing apparatuses, too.

Hereinafter, preferred embodiments according to the present disclosure are supplementarily noted.

### Supplementary Note 1

According to an aspect of the present disclosure, there is provided a fine pattern-forming method which includes:

a core pattern-forming step of forming a core pattern of a predetermined line width at a substrate surface side;

a sidewall-forming step of forming a sidewall on the core pattern formed in the core pattern-forming step; and

a core pattern removing step of removing the core pattern in a state where the sidewall is left, by using an etching gas including fluorine after the sidewall-forming step, and

in which, in the core pattern removing step, a film deposited at a substrate back side in the core pattern-forming step is removed in parallel to the removal of the core pattern.

### Supplementary Note 2

There is provided the fine pattern-forming method of supplementary note 1, wherein, preferably, the core pattern-forming step includes an exposing/developing step and a dry etching step.

### Supplementary Note 3

There is provided the fine pattern-forming method of supplementary note 2, wherein, preferably, the substrate includes at a surface side of the substrate a hardmask film formed on a film which consists the core pattern,

an antireflection film formed on the hardmask film, and

a resist film formed on the antireflection film,

in the exposure/development step, a resist film is exposed and then developed to form a resist pattern of the predetermined line width, and,

in the dry etching step, the antireflection film and the hardmask film are etched by using the resist pattern as a mask to form the core pattern.

### Supplementary Note 4

There is provided the fine pattern-forming method of supplementary note 3, wherein, preferably, the substrate includes at a back side of the substrate a back side core material film which is a film formed of the same material as a material of the core pattern at the surface side of the substrate,

a back side hardmask film formed on the back side core material film, and

a back side antireflection film formed on the back side hardmask film, and,

in the core pattern removal step, the back side antireflection film, the back side hardmask film and the back side core material film are removed.

### Supplementary Note 5

There is provided the fine pattern-forming method of supplementary note 4, wherein, preferably, the core pattern removal step includes a first etching step of removing the back side antireflection film,

a second etching step of removing the back side hardmask film, and

a third etching step of removing the back side core material film.

### Supplementary Note 6

There is provided the fine pattern-forming method of supplementary note 5, wherein, preferably, in the first and second etching steps, IF₇ is used as the etching gas.

### Supplementary Note 7

There is provided the fine pattern-forming method of supplementary note 1, wherein, preferably, a film consisting the core pattern is silicon, and

a film consisting the sidewall is a silicon oxide film.

### Supplementary Note 8

There is provided the fine pattern-forming method of supplementary note 3, wherein, preferably, a material of the antireflection film is silicon, and a material of the hardmask film includes carbon.

### Supplementary Note 9

There is provided the fine pattern-forming method of supplementary note 1, wherein, preferably, a line width of the sidewall is narrower than a line width of the core pattern.

### Supplementary Note 10

There is provided the fine pattern-forming method of supplementary note 1, wherein, preferably, in the core pattern removal step, a temperature of the substrate is 30 to 50° C.

### Supplementary Note 11

Further, preferably, there is provided a semiconductor device manufacturing method which uses the fine pattern-forming method of supplementary note 1 through supplementary note 10.

### Supplementary Note 12

According to another aspect of the present disclosure, there is provided a semiconductor device manufacturing method which includes:

a core pattern-forming step of forming a core pattern of a predetermined line width at a substrate surface side;

a sidewall-forming step of forming a sidewall on the core pattern formed in the core pattern-forming step; and

a core pattern removing step of removing the core pattern in a state where the sidewall is left, by using an etching gas including fluorine after the sidewall-forming step, and

in which, in the core pattern removing step, a film deposited at a substrate back side in the core pattern-forming step is removed in parallel to the removal of the core pattern.

### Supplementary Note 13

According to still another aspect of the present disclosure, there is provided a substrate processing apparatus including:

a processing chamber including at a surface side a core pattern of a predetermined line width and a sidewall formed on the core pattern, and configured to house a substrate including at a back side a core material film consisted by the same material as that of the core pattern;

a gas supply unit configured to supply an etching gas to the processing chamber, the etching gas removing the core pattern in a state where the sidewall is left, and including fluorine;

an exhaust unit configured to exhaust an atmosphere in the processing chamber; and

a control unit configured to control the gas supply unit to supply the etching gas to the processing chamber to remove the core pattern and the remove the core material film.

### Supplementary Note 14

There are provided a program and a recording medium readably recording the program for causing a computer to execute:

a sequence of forming a core pattern of a predetermined line width at a substrate surface side;

a sequence of forming a sidewall on the core pattern; and

a sequence of removing the core pattern in a state where the sidewall is left, by using an etching gas including fluorine after the sidewall is formed, and removing a film deposited at a substrate back side when the sequence of forming the core pattern is executed.

### Supplementary Note 15

According to still another aspect of the disclosure, there is provided a fine pattern-forming method including:

a film-forming step of forming at least a silicon hardmask film, a carbon film, a silicon antireflection film and a resist film on a substrate;

a resist pattern-forming step of processing the resist film, and forming a resist pattern of a predetermined line width;

a carbon film pattern-forming step of forming a pattern of the carbon film by using the resist pattern;

a silicon hardmask pattern-forming step of forming a pattern of the silicon hardmask film by using the pattern of the carbon film; and

a silicon hardmask removal step of removing a first film, a second film and a third film when removing the pattern of the silicon hardmask film by using an etching gas including fluorine, the first film being formed of the same material as that of the silicon antireflection film, the second film being formed of the same material as that of the carbon film, the third film being formed of the same material as that of the silicon hardmask film, and the first film, the second film and the third film being deposited at aback side of the substrate in the film-forming step.

### Supplementary Note 16

There is provided the fine pattern-forming method of supplementary note 15, wherein, preferably, the silicon hardmask removal step includes:

a first etching step of removing the first film;

a second etching step of removing the second film after the first etching step; and

a third etching step of removing the third film after the second etching step.

### Supplementary Note 17

There is provided the fine pattern-forming method of supplementary note 16, wherein, preferably, in the first and third etching steps, IF₇ is used as the etching gas.

### Supplementary Note 18

Further, there is provided the fine pattern-forming method of supplementary note 15 through supplementary note 17, wherein, preferably, a film thickness of the silicon hardmask and a film thickness of the silicon antireflection film are the same.

### Supplementary Note 19

Further, there is provided the fine pattern-forming method of supplementary note 15 through supplementary note 18, wherein, preferably, in the film-forming step, a multilayer hardmask is formed before the formation of the silicon hardmask, and a film thickness of the carbon film and a film thickness of the multilayer hardmask are the same.

### Supplementary Note 20

Further, preferably, there is provided a semiconductor device manufacturing method which uses the fine pattern-forming method of supplementary note 15 through supplementary note 19.

### Supplementary Note 21

There is provided a fine pattern-forming method including:

a substrate loading step of loading a substrate into a processing chamber, the substrate having a first silicon film formed at a substrate surface side and having a second silicon film, a carbon film and a third silicon film formed in this order at a substrate back side;

an etching step of removing the first silicon film by using an etching gas including fluorine and, in parallel, removing the third silicon film, the carbon film and the second silicon film; and

a substrate loading step of unloading from the processing chamber the substrate having been subjected to the etching step.

### Supplementary Note 22

According to still another aspect of the present disclosure, there are provided a program and a recording medium readably recording the program for causing a computer to execute:

a sequence of forming at least a silicon hardmask film, a carbon film, a silicon antireflection film and a resist film on a substrate;

a resist pattern-forming sequence of processing the resist film, and forming a resist pattern of a predetermined line width;

a carbon film pattern-forming sequence of forming a pattern of the carbon film by using the resist pattern;

a silicon hardmask pattern-forming sequence of forming a pattern of the silicon hardmask film by using the pattern of the carbon film; and

a silicon hardmask removing sequence of removing a first film, a second film and a third film when removing the pattern of the silicon hardmask film by using an etching gas including fluorine, the first film being formed of the same material as that of the silicon antireflection film, the second film, being formed of the same material as that of the carbon film, the third film being formed of the same material as that of the silicon hardmask film, and the first film, the second film and the third film being deposited at a back side of the substrate.

### Supplementary Note 23

According to still another aspect of the present disclosure, there is provided a substrate processing apparatus including:

a processing chamber configured to house a substrate, the substrate having a first silicon film formed at a substrate surface side and having a second silicon film, a carbon film and a third silicon film formed in this order at a substrate back side;

a gas supply unit configured to supply an etching gas to the processing chamber, the etching gas removing the first silicon film and, in parallel, removing the third silicon film, the carbon film and the second silicon film; and an exhaust unit configured to exhaust an atmosphere in the processing chamber.

### Supplementary Note 24

According to sill another aspect of the present disclosure, there is provided a fine pattern-forming method including:

a substrate loading step of loading a substrate to a processing chamber, the substrate having a silicon film formed at a substrate surface side and in a groove section, and the groove section having a gate oxide film formed at a bottom section and having a gate electrode buried therein;

an etching step of removing the silicon film formed in the groove section by using an etching gas including fluorine without removing the gate oxide film, and removing at a substrate back side a first film formed of the same material as that of the silicon film; and

a substrate loading step of unloading from the processing chamber the substrate having been subjected to the etching step.

### Supplementary Note 25

There is provided the fine pattern-forming method of supplementary note 24 including a step of forming a metal-containing film in the groove section after the silicon film is removed in the etching step.

### Supplementary Note 26

There is provided the fine pattern-forming method of supplementary note 24 or supplementary note 25, wherein, preferably, a plurality of groove sections are provided in a channel length direction of the gate electrode, and

lengths of the plurality of groove sections in the channel length direction are different from each other.

### Supplementary Note 27

Further, preferably, there is provided a semiconductor device manufacturing method which uses the fine pattern-forming method of supplementary note 24 through supplementary note 26.

### Supplementary Note 28

According to still another aspect of the present disclosure, there are provided a program and a recording medium readably recording this program for causing a computer to execute an etching sequence of removing a silicon film from a substrate by using an etching gas including fluorine without removing the gate oxide film, and removing at a substrate back side a first film formed of the same material as that of the silicon film, the substrate having the silicon film formed at a substrate surface side and in a groove section, and the groove section having the gate oxide film formed at a bottom section and having a gate electrode buried therein.

### Supplementary Note 29

According to still another aspect of the present disclosure, there is provided a substrate processing apparatus including:

a processing chamber configured to house a substrate, the substrate having a silicon film formed at a substrate surface side and in a groove section, and the groove section having a gate oxide film formed at a bottom section and having a gate electrode buried therein;

a gas supply unit configured to supply an etching gas to the processing chamber, the etching gas removing the silicon film without removing the gate oxide film, removing at a substrate back side a first film formed of the same material as that of the silicon film, and including fluorine; and

an exhaust unit configured to exhaust an atmosphere in the processing chamber.

### Supplementary Note 30

According to still another aspect of the present disclosure, there is provided a fine pattern-forming method including:

a substrate loading step of loading a substrate to a processing chamber, the substrate having a silicon film formed at a substrate surface side and in a groove section, the silicon film including an impurity of a group III or a group V, and the groove section having a Si-Fin structure formed therein, having a gate oxide film formed at a bottom section and having a gate electrode buried therein;

an etching step of removing the silicon film formed in the groove section by using an etching gas including fluorine without removing the gate oxide film, and removing at a substrate back side a first film formed of the same material as that of the silicon film; and

a substrate loading step of unloading from the processing chamber the substrate having been subjected to the etching step.

### Supplementary Note 31

There is provided the fine pattern-forming method of supplementary note 30, wherein, preferably, a plurality of groove sections are provided in a channel length direction of the gate electrode, and

lengths of the plurality of groove sections in the channel length direction are different from each other.

### Supplementary Note 32

Further, preferably, there is provided a semiconductor device manufacturing method which uses the fine pattern-forming method of supplementary note 30 or supplementary note 31.

### Supplementary Note 33

According to still another aspect of the present disclosure, there are provided a program and a recording medium readably recording the program for causing a computer to execute an etching sequence of removing a silicon film from a substrate by using an etching gas including fluorine without removing the gate oxide film, and removing at a substrate back side a first film formed of the same material as that of the silicon film, the substrate having the silicon film formed at a substrate surface side and in a groove section, the silicon film including an impurity of a group III or a group V, and the groove section having a Si-Fin structure formed therein, having the gate oxide film formed at a bottom section and having a gate electrode buried therein.

### Supplementary Note 34

According to still another aspect of the present disclosure, there is provided a substrate processing apparatus including:

a processing chamber configured to house a substrate, the substrate having a silicon film formed at a substrate surface side and in a groove section, the silicon film including an impurity of a group III or a group V, and the groove section having a Si-Fin structure formed therein, having a gate oxide film formed at a bottom section and having a gate electrode buried therein;

a gas supply unit configured to supply an etching gas to the processing chamber, the etching gas removing the silicon film without removing the gate oxide film, removing at a substrate back side a first film formed of the same material as that of the silicon film, and including fluorine; and

an exhaust unit configured to exhaust an atmosphere in the processing chamber.

### Supplementary Note 35

According to still another aspect of the present disclosure, there is provided a semiconductor device manufacturing method including:

a film-forming step of depositing a multilayer hardmask film, a silicon hardmask film, a carbon film, a silicon antireflection film and a resist film on a substrate;

a resist pattern-forming step of processing the resist film, and forming a resist pattern of a predetermined line width;

a carbon film pattern-forming step of forming a pattern of the carbon film by using the resist pattern;

a silicon hardmask pattern-forming step of forming a pattern of the silicon hardmask film by using the pattern of the carbon film;

a silicon hardmask removal step of removing a first film, a second film and a third film when removing the pattern of the silicon hardmask film by using an etching gas including fluorine, the first film being formed of the same material as that of the silicon antireflection film, the second film being formed of the same material as that of the carbon film, the third film being formed of the same material as that of the silicon hardmask film, and the first film, the second film and the third film being deposited at a back side of the substrate in the film-forming step; and

a pattern-forming step of forming a predetermined pattern by using a pattern of the multilayer hardmask film.

### Supplementary Note 36

According to still another aspect of the present disclosure, there is provided a substrate processing apparatus including:

a processing chamber configured to house a substrate, the substrate having at least a silicon hardmask film, a carbon film, a silicon antireflection film and a resist film respectively deposited thereon;

a gas supply unit configured to supply an etching gas to the processing chamber, the etching gas removing a third film formed of the same material as that of the silicon hardmask film, and including fluorine;

an exhaust unit configured to exhaust an atmosphere in the processing chamber; and

a control unit configured to execute a resist pattern-forming step of processing the resist film, and forming a resist pattern of a predetermined line width,

a carbon film pattern-forming step of forming a pattern of the carbon film by using the resist pattern,

a silicon hardmask pattern-forming step of forming a pattern of the silicon hardmask film by using the pattern of the carbon film, and

a silicon hardmask removal step of removing the first film, the second film and the third film deposited at a back surface side of the substrate when removing the pattern of the silicon hardmask film.

### Supplementary Note 37

According to still another aspect of the present disclosure, there is provided a recording medium readably recording a program for causing a computer to execute:

a sequence of forming a silicon hardmask film, a carbon film, a silicon antireflection film and a resist film at least on a substrate;

a resist pattern-forming sequence of processing the resist film, and forming a resist pattern of a predetermined line width;

a carbon film pattern-forming sequence of forming a pattern of the carbon film by using the resist pattern;

a silicon hardmask pattern-forming sequence of forming a pattern of the silicon hardmask film by using the pattern of the carbon film; and

a silicon hardmask removing sequence of removing a first film, a second film and a third film when removing the pattern of the silicon hardmask film by using an etching gas including fluorine, the first film being formed of the same material as that of the silicon antireflection film, the second film being formed of the same material as that of the carbon film, the third film being formed of the same material as that of the silicon hardmask film, and the first film, the second film and the third film being deposited at a back side of the substrate.

### Supplementary Note 37

According to still another aspect of the present disclosure, there is provided a semiconductor device manufacturing method including:

a step of forming a gate electrode by burying a silicon film at a substrate surface side and in a groove section, the groove section having a gate oxide film formed at a bottom section; and

an etching step of removing the silicon film formed in the groove section by placing an etching gas including fluorine in contact with the substrate without removing the gate oxide film, and removing at a substrate back side a first film formed of the same material as that of the silicon film.

### Supplementary Note 37

According to still another aspect of the present disclosure, there is provided a semiconductor device manufacturing method including:

a step of burying a silicon film in a groove section and forming a gate electrode, the silicon film including an impurity of a group III or a group V, and the groove section having a Si-Fin structure formed on a substrate surface and having a gate oxide film formed at a bottom section; and

an etching step of removing the silicon film formed in the groove section by using an etching gas including fluorine without removing the gate oxide film, and removing at a substrate back side a first film formed of the same material as that of the silicon film.

### Supplementary Note 38

According to still another aspect of the present disclosure, there is provided a semiconductor device manufacturing method including:

a step of forming fine patterns of a film whose main component is silicon;

a step of forming an oxide film on a substrate and forming a second groove, the substrate including a first groove formed between the fine patterns;

a step of forming on the oxide film the film whose main component is the silicon; and

a step of supplying an etching gas including an halogen element to the film whose main component is the silicon, and removing the film which is other than the film whose main component is the silicon on the second groove, and whose main component is the silicon.

### Supplementary Note 39

There is provided the semiconductor device manufacturing method of supplementary note 38, wherein, preferably, in the step of supplying the etching gas, the etching gas is supplied after the substrate is supported by a supporting unit.

### Supplementary Note 40

There is provided the semiconductor device manufacturing method of supplementary note 38, wherein, preferably, in the step of supplying the etching gas, the substrate is supported by a supporting unit while the etching gas is supplied.

### Supplementary Note 41

There is provided the semiconductor device manufacturing method of any one of supplementary note 38 through supplementary note 40 including a step of removing a natural oxide film formed on the film whose main component is the silicon before the step of supplying the etching gas.

### Supplementary Note 42

There is provided the semiconductor device manufacturing method of any one of supplementary note 38 through supplementary note 41, wherein, preferably, the etching gas is an iodine-containing gas including iodine.

### Supplementary Note 43

According to still another aspect of the present disclosure, there are provided a program and a recording medium readably recording the program for causing a computer to execute:

a sequence of forming fine patterns of a film whose main component is silicon;

a sequence of forming an oxide film on a substrate and forming a second groove, the substrate including a first groove formed between the fine patterns;

a sequence of forming on the oxide film the film whose main component is the silicon; and

a sequence of supplying an etching gas including fluorine to the film whose main component is the silicon, and removing the film which is other than the film whose main component is the silicon on the second groove, and whose main component is the silicon.

### Supplementary Note 44

There are provided the program and the recording medium readably recording the program of supplementary note 43, wherein, preferably, in the sequence of supplying the etching gas, the etching gas is supplied after the substrate is supported by a supporting unit.

### Supplementary Note 45

There are provided the program and the recording medium readably recording the program of supplementary note 43, wherein, preferably, in the sequence of supplying the etching gas, the substrate is supported by a supporting unit while the etching gas is supplied.

### Supplementary Note 46

There are provided the program and the recording medium readably recording the program of any one of supplementary note 43 through supplementary note 45 including a sequence of removing a natural oxide film formed on the film whose main component is the silicon before the sequence of supplying the etching gas.

### Supplementary Note 47

There are provided the program and the recording medium readably recording the program of any one of supplementary note 43 through supplementary note 46, wherein, preferably, the etching gas is a gas (iodine-containing gas) including iodine.

### Supplementary Note 48

According to still another aspect of the present disclosure, there is provided a semiconductor device manufacturing method to execute:

a sequence of forming fine patterns of a film whose main component is silicon;

a step of forming an oxide film on a substrate and forming a second groove, the substrate having a first groove formed thereon, and the first groove being consisted by the fine patterns;

a step of forming on the oxide film the film whose main component is the silicon; and

a step of removing the film which is other than the film whose main component is the silicon on the second groove, and whose main component is the silicon.

### Supplementary Note 49

There is provided the semiconductor device manufacturing method of supplementary note 48, wherein, preferably, a width of the second groove is configured to be shorter than a width of the first groove.

### Supplementary Note 50

According to still another aspect of the present disclosure, there is provided a substrate processing apparatus including:

a sequence of forming fine patterns of a film whose main component is silicon;

a processing chamber configured to hold a substrate including a first groove consisted by fine patterns;

an oxide film raw material supply unit configured to supply an oxide film raw material to the substrate;

a silicon raw material supply unit configured to supply a silicon raw material to the substrate;

a remover supply unit configured to supply an etching gas including fluorine, to the substrate; and

a control unit configured to control the oxide film raw material supply unit, the silicon raw material supply unit and the remover supply unit to supply the oxide film raw material, the silicon raw material and the halogen element in order.

### Supplementary Note 51

According to still another aspect, there is provided a substrate processing apparatus including:

a processing chamber configured to hold a substrate including a first groove formed between protrusions whose main component is silicon;

an oxide film raw material supply unit configured to supply an oxide film raw material to the substrate;

a silicon raw material supply unit configured to supply a silicon raw material to the substrate;

a remover supply unit configured to supply an etching gas including fluorine, to the substrate; and

a control unit configured to control the oxide film raw material supply unit, the silicon raw material supply unit and the remover supply unit to perform in order a step of supplying the oxide film raw material to the substrate and forming a second groove on the substrate,

a step of supplying the silicon raw material to the substrate and forming a film whose main component is silicon, and

a step of supplying the etching gas to the film whose main component is the silicon, and removing the film which is other than the film whose main component is the silicon on the second groove, and whose main component is the silicon.

### Supplementary Note 52

There is provided the substrate processing apparatus of supplementary note 51, wherein, preferably, the control unit controls the supporting unit and the gas supply unit to supply the etching gas after the substrate is supported by the supporting unit

### Supplementary Note 53

There is provided the substrate processing apparatus of supplementary note 51, wherein, preferably, the control unit controls the supporting unit and the gas supply unit to support the substrate supporting unit while the etching gas is supplied to the substrate

### Supplementary Note 54

There is provided the substrate processing apparatus of any one of supplementary note 51 through supplementary note 53 which preferably includes a remover supply unit configured to supply a natural oxide film remover to the substrate, and

in which the gas supply unit and the remover supply unit are controlled to supply the remover before the etching gas is supplied.

### Supplementary Note 55

According to still another aspect, there is provided a substrate processing apparatus including:

a processing chamber configured to hold a substrate, the substrate having a protrusion whose main component is silicon formed thereon;

an oxide film raw material supply unit configured to supply an oxide film raw material to the substrate;

a silicon raw material supply unit configured to supply a silicon raw material to the substrate;

a remover supply unit configured to supply an etching gas including fluorine, to the substrate; and

a control unit configured to control the oxide film raw material supply unit, the silicon raw material supply unit and the remover supply unit to supply the oxide film raw material, the silicon raw material and the etching gas including fluorine in order.

### Supplementary Note 56

According to still another aspect, there is provided a semiconductor device manufacturing method including:

a step of loading a substrate to a processing chamber, the substrate having a first groove, a second groove and a film formed thereon, the first groove being consisted by a protrusion whose main component is silicon, the second groove being formed in the first groove and via an oxide film, and the film whose main component is the silicon being formed in the second groove; and

a step of supplying an etching gas including fluorine to the film, and removing the film other than the film on the second groove.

This application claims the benefit of Japanese Patent Application No. 2013-219584 filed on Oct. 22, 2013, Japanese Patent Application No. 2013-248054 filed on Nov. 29, 2013, and Japanese Patent Application No. 2014-093751 filed on Apr. 30, 2014, in the Japan Patent Office, the disclosure of which are incorporated herein in its entirely by reference.

### INDUSTRIAL USE OF THE PRESENT DISCLOSURE

The present disclosure is applied to an etching process which is one process of a next-generation semiconductor device manufacturing process.

### EXPLANATION OF REFERENCE NUMERALS

1 RESIST PATTERN
2 Si FILM (ANTIREFLECTION FILM)
3 CHM FILM
4 ETCHING TARGET FILM (Si FILM)
5 Si₃N₄ FILM
6 SiO₂ FILM
7 Si₃N₄ FILM
8 SiO₂ FILM
9 Si SUBSTRATE
10 SiO₂ FILM
11a, 11b DUMMY POLYSILICON ELECTRODE
11c POLYSILICON FILM
11d PHOSPHORATED POLYSILICON ELECTRODE
11e PHOSPHORATED POLYSILICON
12 SIDEWALL SPACER
13 ETCHING STOP LAYER
14 PMD (PreMetalDielectric)
15a GATE OXIDE FILM
15b OXIDE FILM
16 Si-Fin
17 STI (ShallowTrenchIsolation)
18 SOURCE/DRAIN EPITAXIAL LAYER
19 SILICON SUBSTRATE
20 SUBSTRATE PROCESSING APPARATUS
21 GROOVE
25 MULTILAYER HARDMASK FILM
26 PATTERNING TARGET LAYER
27 SiO₂ FILM
28 Si FILM
29 Si₃N₄ FILM
35 SiO₂ FILM
36 Si FILM (ETCHING TARGET FILM)
37 SiO₂ FILM
38 Si FILM
39 CHM FILM
43 FIRST GROOVE
44 SECOND GROOVE
45 THIRD GROOVE
60 WAFER
61 Si₃N₄ FILM
62 TiN FILM (TiN ELECTRODE)
63 Si₃N₄ FILM (ELECTRODE COLLAPSE PREVENTION SUPPORTING UNIT)
64 SILICON-CONTAINING FILM
65a MODIFICATION LAYER
65b INTERFACE MODIFICATION LAYER
66 BURIED FILM
67 Si HARDMASK FILM
100 EFEM
110 FOUP
120 LOAD PORT
130 AIR CONVEYANCE ROBOT
131 TWEEZER
200 LOAD LOCK CHAMBER UNIT
210 BUFFER UNIT
211 BOAT
212 INDEX ASSEMBLY
220 BUFFER UNIT
221 BOAT
222 INDEX ASSEMBLY
250, 260 LOAD LOCK CHAMBER
300 TRANSFER MODULE UNIT
310 TRANSFER MODULE
311 to 314 GATE VALVE
320 VACUUM CONVEYANCE ROBOT
321 FINGER
400 PROCESS CHAMBER UNIT
410 FIRST PROCESSING UNIT
411 SUSCEPTOR TABLE
413 LIFTER PIN
414 SUPPORTING UNIT
430 GAS BUFFER CHAMBER
431 PROCESSING CONTAINER
432 RESONANCE COIL
433 GAS INTRODUCTION PORT
445 PROCESSING CHAMBER
446 SIDEWALL
448 BASE PLATE
453 O RING
454 TOP PLATE
454a CAP UNIT
454b SUPPORTING UNIT
458 BAFFLE RING
459 SUSCEPTOR
461 COLUMN
463 HEATER
464 SUSCEPTOR COOLANT FLOW PATH
465 EXHAUST PLATE
467 GUIDE SHAFT
469 BOTTOM PLATE
471 ELEVATION PLATE
472 ELEVATION SHAFT
473 ELEVATION DRIVING UNIT
474 FIRST EXHAUST CHAMBER
475 EXHAUST COMMUNICATION HOLE
476 SECOND EXHAUST CHAMBER
479 PRESSURE ADJUSTMENT VALVE
480 EXHAUST PIPE
481 EXHAUST PUMP
482 FIRST GAS SUPPLY UNIT (FIRST GAS SUPPLY UNIT)
482a GAS SUPPLY PIPE
482b FIRST GAS SOURCE
482c, 482g MASS FLOW CONTROLLER
482d, 482h OPENING/CLOSING VALVE
482e INERT GAS SUPPLY PIPE
482f INERT GAS SOURCE
483 SECOND GAS SUPPLY UNIT (SECOND GAS SUPPLY UNIT)
483a GAS SUPPLY PIPE
483b SECOND GAS SOURCE
483c MASS FLOW CONTROLLER
483d OPENING/CLOSING VALVE
484 SHOWER PLATE
484a PLATE UNIT
484b HOLE UNIT
485 HEATER TEMPERATURE CONTROL UNIT
486 COOLANT FLOW RATE CONTROL UNIT
487 HEATER POWER SUPPLY LINE
488 TEMPERATURE DETECTING UNIT
489 EXTERNAL COOLANT FLOW PATH
491 COOLANT SUPPLY UNIT
492 COOLANT TEMPERATURE DETECTING UNIT
510 SECOND PROCESSING UNIT
511 SUSCEPTOR TABLE
513 LIFTER PIN
514 SUPPORTING UNIT
521 RESONANCE COIL
522 MOVABLE TAB
523 FIXED GROUND
524 MOVABLE TAB
525 HIGH FREQUENCY POWER SUPPLY
526 FREQUENCY ADAPTOR
527 RF SENSOR
530 PLASMA GENERATING CHAMBER
531 REACTION CONTAINER
532 OUTER SHIELD
533 GAS INTRODUCTION PORT
545 PROCESSING CHAMBER
546 SIDEWALL
554 TOP PLATE
558 BAFFLE RING
559 SUSCEPTOR
561 COLUMN
563 HEATER
565 EXHAUST PLATE
567 GUIDE SHAFT
569 BOTTOM PLATE
571 ELEVATION PLATE
572 ELEVATION SHAFT
573 ELEVATION DRIVING UNIT
574 FIRST EXHAUST CHAMBER
575 EXHAUST COMMUNICATION HOLE
576 SECOND EXHAUST CHAMBER
579 PRESSURE ADJUSTMENT VALVE
580 EXHAUST PIPE
581 EXHAUST PUMP
582 THIRD GAS SUPPLY UNIT (THIRD GAS SUPPLY UNIT)
582a GAS SUPPLY PIPE
582b THIRD GAS SOURCE
582c, 582g MASS FLOW CONTROLLER
582d, 582h OPENING/CLOSING VALVE
582e INERT GAS SUPPLY PIPE
582f INERT GAS SOURCE
584 BAFFLE PLATE
600 CONTROLLER (CONTROL UNIT)
600a CPU
600b RAM
600c STORAGE DEVICE
600d I/O PORT
600e INTERNAL BUS
601 INPUT/OUTPUT DEVICE
602 EXTERNAL STORAGE DEVICE
610 SILICON OXIDE FILM REMOVAL DEVICE
630 MIXING CHAMBER

1. A fine pattern-forming method comprising:
a core pattern-forming step of forming a core pattern of a predetermined line width at a substrate surface side;
a sidewall-forming step of forming a sidewall on the core pattern formed in the core pattern-forming step; and
a core pattern removing step of removing the core pattern in a state where the sidewall remains, by using an etching gas including fluorine after the sidewall-forming step,
wherein, in the core pattern removing step, a film deposited at a substrate back side in the core pattern-forming step is removed in parallel to the removal of the core pattern.

2. A semiconductor device manufacturing method comprising:
a core pattern-forming step of forming a core pattern of a predetermined line width at a substrate surface side;
a sidewall-forming step of forming a sidewall on the core pattern formed in the core pattern-forming step; and
a core pattern removing step of removing the core pattern in a state where the sidewall remains, by using an etching gas including fluorine after the sidewall-forming step,
wherein, in the core pattern removing step, a film deposited at a back side of a substrate in the core pattern-forming step is removed in parallel to the removal of the core pattern.

3. A substrate processing apparatus comprising:
a processing chamber including at a surface side a core pattern of a predetermined line width and a sidewall formed on the core pattern, and configured to hold a substrate including at a back side a core material film of a same material as that of the core pattern;
a gas supply unit configured to supply an etching gas to the processing chamber, the etching gas removing the core pattern in a state where the sidewall remains, and including fluorine;
an exhaust unit configured to exhaust an atmosphere in the processing chamber; and
a controller configured to control the gas supply unit to supply the etching gas to the processing chamber to remove the core pattern and to remove the core material film.

4-20. (canceled)
